(19) United States
(12) Patent Application Publication
(10) Pub. No.: US 2025/0362609 A1
(43) Pub. Date: Nov. 27, 2025

(54) SILICON-CONTAINING RESIST UNDERLAYER FILM-FORMING COMPOSITION CONTAINING POLYFUNCTIONAL SULFONIC ACID

(71) Applicant: NISSAN CHEMICAL CORPORATION, Tokyo (JP)

(72) Inventors: Satoshi TAKEDA, Toyama (JP); Wataru SHIBAYAMA, Toyama (JP)

(73) Assignee: NISSAN CHEMICAL CORPORATION, Tokyo (JP)

(21) Appl. No.: 18/994,265

(22) PCT Filed: Jul. 19, 2023
(86) PCT No.: PCT/JP2023/026333

§ 371 Date: Jan. 14, 2025

(30) Foreign Application Priority Data
Jul. 20, 2022 (JP) 2022-115520

(51) Int. Cl. G03F 7/11; C08G 77/08; C08K 3/24; C08K 5/41; C09D 7/20; C09D 7/61; C09D 7/63; C09D 183/06; C09D 183/08

(52) U.S. Cl. CPC G03F 7/11; C08G 77/08; C08K 3/24; C08K 5/41; C09D 7/20; C09D 7/61; C09D 7/63; C09D 183/06; C09D 183/08

(57) ABSTRACT

A silicon-containing resist underlayer film-forming composition, containing: a component [A]: a polysiloxane; a component [B]: sulfuric acid, a polyfunctional sulfonic acid, or a salt thereof; and a component [C]: a solvent.

### TECHNICAL FIELD

The present invention relates to a silicon-containing resist underlayer film-forming composition containing a polyfunctional sulfonic acid.

### BACKGROUND ART

Conventionally, microfabrication by lithography using a photoresist has been performed in the production of a semiconductor device. The microfabrication is a processing method of forming microrelief corresponding to a pattern on a substrate surface by forming a thin film of a photoresist on a semiconductor substrate such as a silicon wafer, irradiating the thin film with an active ray such as an ultraviolet ray through a mask pattern on which a semiconductor device pattern is drawn, developing the thin film, and etching the substrate using the obtained photoresist pattern as a protective film.

While the degree of integration of semiconductor devices has been increased, the wavelength of an active ray to be used also tends to be shortened from a KrF excimer laser (248 nm) to an ArF excimer laser (193 nm), and furthermore, an exposure technique using an extreme ultraviolet (EUV) or an electron beam has been studied. With the shortening of the wavelength of an active ray, the influence of reflection of the active ray from the semiconductor substrate becomes a major problem, and a method for providing a resist underlayer film called an antireflection film (Bottom Anti-Reflective Coating, BARC) between a photoresist and a substrate to be processed has been widely applied. As such a resist underlayer film, for example, an underlayer film containing silicon or the like has been proposed (Patent Literature 1 and the like).

With the miniaturization of a resist pattern in the most advanced semiconductor devices in recent years, the demand for thinning a resist has become more remarkable. In particular, in a three-layer process including a resist film, a silicon-containing resist underlayer film, and an organic underlayer film, good lithographic characteristics of a resist on the silicon-containing resist underlayer film have been required.

For further fine patterning of the above-described resist, development of lithography technology using a metal oxide resist (MOR) having excellent etching resistance as compared with a conventional chemically amplified resist has been actively conducted in recent years. For further miniaturization in the future, it is essential to reduce the film thickness of the resist film, but this metal oxide resist (MOR) (hereinafter also referred to as a “metal-containing resist”) has sufficient etching resistance to perform fine patterning even on a thin film, and thus is expected in recent years as a material to be used for next-generation EUV lithography technology.

### CITATION LIST

### Patent Literature

Patent Literature 1: JP 2007-163846 A

### SUMMARY OF INVENTION

### Technical Problem

In semiconductor device processing, in order to improve productivity, an increase in sensitivity of a resist has been required as one of the methods for shortening an exposure time. In particular, in semiconductor device processing using the most advanced EUV lithography technology, since the EUV exposure time affects productivity, this demand is strong.

The present invention has been made in view of such circumstances, and an object of the present invention is to provide a silicon-containing resist underlayer film-forming composition capable of increasing the sensitivity of a resist.

### Solution to Problem

As a result of intensive studies to solve the above-mentioned problems, the present inventors found that the above-mentioned problems can be solved, and completed the present invention having the following gist.

That is, the present invention includes the following aspects.

[1] A silicon-containing resist underlayer film-forming composition, containing:
a component [A]: a polysiloxane;
a component [B]: sulfuric acid, a polyfunctional sulfonic acid, or a salt thereof; and
a component [C]: a solvent.

[2] The silicon-containing resist underlayer film-forming composition according to [1], wherein the polyfunctional sulfonic acid is a compound represented by formula (A) below:

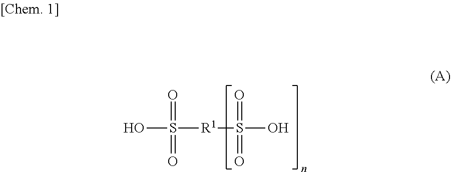

wherein n represents an integer of 1 to 3, and R¹ represents an n+1-valent organic group having 1 to 15 carbon atoms.

[3] The silicon-containing resist underlayer film-forming composition according to [1] or [2], wherein the salt in the component [B] is any of an ammonium salt, an imidazolium salt, a pyridinium salt, a sulfonium salt, a phosphonium salt, and an iodonium salt.

[4] The silicon-containing resist underlayer film-forming composition according to any one of [1] to [3], wherein the polysiloxane as the component [A] is a polysiloxane-modified product in which some silanol groups are alcohol-modified or acetal-protected.

[5] The silicon-containing resist underlayer film-forming composition according to any one of [1] to [4], wherein the component [C] contains an alcohol-based solvent.

[6] The silicon-containing resist underlayer film-forming composition according to [5], wherein the component [C] contains a propylene glycol monoalkyl ether.

[7] The silicon-containing resist underlayer film-forming composition according to any one of [1] to [6], further containing a component [D]: a curing catalyst.

[8] The silicon-containing resist underlayer film-forming composition according to any one of [1] to [7], further containing a component [E]: nitric acid.

[9] The silicon-containing resist underlayer film-forming composition according to any one of [1] to [8], wherein the component [C] contains water.

[10] The silicon-containing resist underlayer film-forming composition according to any one of [1] to [9], which is for forming a resist underlayer film for use in EUV lithography.

[11] A silicon-containing resist underlayer film that is a cured product of the silicon-containing resist underlayer film-forming composition according to any one of [1] to [10].

[12] A semiconductor processing substrate, including:
a semiconductor substrate; and
the silicon-containing resist underlayer film according to [11].

[13] A method for producing a semiconductor element, the method including steps of:
forming an organic underlayer film on a substrate;
forming a resist underlayer film on the organic underlayer film using the silicon-containing resist underlayer film-forming composition according to any one of [1] to [10]; and
forming a metal-containing resist film on the resist underlayer film.

[14] The method for producing a semiconductor element according to [13], wherein
the metal-containing resist film is formed from a metal-containing resist for use in EUV lithography.

[15] The method for producing a semiconductor element according to [13] or [14], wherein
in the step of forming a resist underlayer film, a silicon-containing resist underlayer film-forming composition filtered through a nylon filter is used.

[16] A pattern forming method, including steps of:
forming an organic underlayer film on a semiconductor substrate;
forming a resist underlayer film on the organic underlayer film by applying and baking the silicon-containing resist underlayer film-forming composition according to any one of [1] to [10];
forming a metal-containing resist film on the resist underlayer film;
exposing and developing the metal-containing resist film to obtain a resist pattern;
etching the resist underlayer film using the resist pattern as a mask; and
etching the organic underlayer film using the patterned resist underlayer film as a mask.

[17] The pattern forming method according to [16], further including:
a step of removing the resist underlayer film by a wet method using a chemical liquid after the step of etching the organic underlayer film.

[18] The pattern forming method according to [16] or [14], wherein
the metal-containing resist film is formed from a metal-containing resist for use in EUV lithography.

### Advantageous Effects of Invention

According to the present invention, it is possible to provide a silicon-containing resist underlayer film-forming composition capable of increasing the sensitivity of a resist.

In addition, according to the present invention, it is possible to provide a silicon-containing resist underlayer film, a semiconductor processing substrate, a method for producing a semiconductor element, and a pattern forming method using the silicon-containing resist underlayer film-forming composition.

### DESCRIPTION OF EMBODIMENTS

### (Silicon-Containing Resist Underlayer Film-Forming Composition)

The silicon-containing resist underlayer-forming composition of the present invention contains a polysiloxane as the component [A], sulfuric acid, a polyfunctional sulfonic acid, or a salt thereof as the component [B], and a solvent as the component [C], and further contains another component as necessary.

The present inventors have found that a resist underlayer film capable of increasing the sensitivity of a resist can be formed by incorporating sulfuric acid, a polyfunctional sulfonic acid, or a salt thereof as the component [B] in a silicon-containing resist underlayer-forming composition containing a polysiloxane.

### <Component [A]: Polysiloxane>

The polysiloxane as the component [A] is not particularly limited as long as it is a polymer having a siloxane bond.

The polysiloxane may include a modified polysiloxane in which some silanol groups are modified, for example, a polysiloxane modified product in which some silanol groups are alcohol-modified or acetal-protected.

In addition, the polysiloxane includes, as an example, a hydrolysis condensate of a hydrolyzable silane, and may include a modified polysiloxane in which at least some silanol groups of the hydrolysis condensate is alcohol-modified or acetal-protected. The hydrolyzable silane related to the hydrolysis condensate can include one type or two or more types of hydrolyzable silanes.

The polysiloxane may have a structure whose main chain is any of a cage type, a ladder type, a linear type, and a branched type. As the polysiloxane, a commercially available polysiloxane can be used.

In the present invention, the “hydrolysis condensate” of a hydrolyzable silane, that is, the product of hydrolysis condensation includes not only a polyorganosiloxane polymer that is a condensate in which the condensation is fully completed but also a polyorganosiloxane polymer that is a partial hydrolysis condensate in which the condensation is not fully completed. Such a partial hydrolysis condensate is also a polymer obtained by hydrolysis and condensation of a hydrolyzable silane similarly to a condensate in which the condensation is fully completed, but the reaction is partially stopped after hydrolysis and condensation does not occur, and therefore a Si—OH group remains. In addition to the hydrolysis condensate, an uncondensed hydrolysate (complete hydrolysate, partial hydrolysate) or a monomer (hydrolyzable silane) may remain in the silicon-containing resist underlayer film-forming composition.

In the present description, the “hydrolyzable silane” may also be simply referred to as “silane compound”.

Examples of the polysiloxane include a hydrolysis condensate of a hydrolyzable silane containing at least one type of hydrolyzable silane represented by the following formula (1).

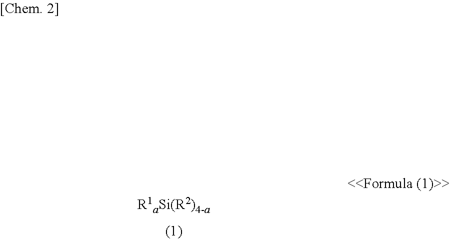

In formula (1), R¹'s are groups bonded to a silicon atom, and each independently represent an alkyl group which may be substituted, an aryl group which may be substituted, an aralkyl group which may be substituted, a halogenated alkyl group which may be substituted, a halogenated aryl group which may be substituted, a halogenated aralkyl group which may be substituted, an alkoxyalkyl group which may be substituted, an alkoxyaryl group which may be substituted, an alkoxyaralkyl group which may be substituted, or an alkenyl group which may be substituted, or represent an organic group having an epoxy group, an organic group having an acryloyl group, an organic group having a methacryloyl group, an organic group having a mercapto group, an organic group having an amino group, an organic group having an alkoxy group, an organic group having a sulfonyl group, or an organic group having a cyano group, or a combination of two or more thereof.

R²'s are groups or atoms bonded to a silicon atom, and each independently represent an alkoxy group, an aralkyloxy group, an acyloxy group, or a halogen atom.

a represents an integer of 0 to 3.

### <<<R¹>>>

The alkyl group may be linear, branched, or cyclic, and the number of carbon atoms thereof is not particularly limited, but is preferably 40 or less, more preferably 30 or less, still more preferably 20 or less, and even more preferably 10 or less.

Specific examples of the linear or branched alkyl group as the alkyl group include a methyl group, an ethyl group, a n-propyl group, an i-propyl group, a n-butyl group, an i-butyl group, a s-butyl group, a t-butyl group, a n-pentyl group, a 1-methyl-n-butyl group, a 2-methyl-n-butyl group, a 3-methyl-n-butyl group, a 1,1-dimethyl-n-propyl group, a 1,2-dimethyl-n-propyl group, a 2,2-dimethyl-n-propyl group, a 1-ethyl-n-propyl group, a n-hexyl group, a 1-methyl-n-pentyl group, a 2-methyl-n-pentyl group, a 3-methyl-n-pentyl group, a 4-methyl-n-pentyl group, a 1,1-dimethyl-n-butyl group, a 1,2-dimethyl-n-butyl group, a 1,3-dimethyl-n-butyl group, a 2,2-dimethyl-n-butyl group, a 2,3-dimethyl-n-butyl group, a 3,3-dimethyl-n-butyl group, a 1-ethyl-n-butyl group, a 2-ethyl-n-butyl group, a 1,1,2-trimethyl-n-propyl group, a 1,2,2-trimethyl-n-propyl group, a 1-ethyl-1-methyl-n-propyl group, and a 1-ethyl-2-methyl-n-propyl group.

In the present description, “i” means “iso”, “s” means “sec”, and “t” means “tert”.

Specific examples of the cyclic alkyl group include cycloalkyl groups such as a cyclopropyl group, a cyclobutyl group, a 1-methyl-cyclopropyl group, a 2-methyl-cyclopropyl group, a cyclopentyl group, a 1-methyl-cyclobutyl group, a 2-methyl-cyclobutyl group, a 3-methyl-cyclobutyl group, a 1,2-dimethyl-cyclopropyl group, a 2,3-dimethyl-cyclopropyl group, a 1-ethyl-cyclopropyl group, a 2-ethyl-cyclopropyl group, a cyclohexyl group, a 1-methyl-cyclopentyl group, a 2-methyl-cyclopentyl group, a 3-methyl-cyclopentyl group, a 1-ethyl-cyclobutyl group, a 2-ethyl-cyclobutyl group, a 3-ethyl-cyclobutyl group, a 1,2-dimethyl-cyclobutyl group, a 1,3-dimethyl-cyclobutyl group, a 2,2-dimethyl-cyclobutyl group, a 2,3-dimethyl-cyclobutyl group, a 2,4-dimethyl-cyclobutyl group, a 3,3-dimethyl-cyclobutyl group, a 1-n-propyl-cyclopropyl group, a 2-n-propyl-cyclopropyl group, a 1-i-propyl-cyclopropyl group, a 2-i-propyl-cyclopropyl group, a 1,2,2-trimethyl-cyclopropyl group, a 1,2,3-trimethyl-cyclopropyl group, a 2,2,3-trimethyl-cyclopropyl group, a 1-ethyl-2-methyl-cyclopropyl group, a 2-ethyl-1-methyl-cyclopropyl group, a 2-ethyl-2-methyl-cyclopropyl group, and a 2-ethyl-3-methyl-cyclopropyl group, and bridged cyclic cycloalkyl groups such as a bicyclobutyl group, a bicyclopentyl group, a bicyclohexyl group, a bicycloheptyl group, a bicyclooctyl group, a bicyclononyl group, and a bicyclodecyl group.

The aryl group may be any of a phenyl group, a monovalent group derived by removing one hydrogen atom from a condensed cyclic aromatic hydrocarbon compound, and a monovalent group derived by removing one hydrogen atom from a ring-linked aromatic hydrocarbon compound, and the number of carbon atoms thereof is not particularly limited, but is preferably 40 or less, more preferably 30 or less, and still more preferably 20 or less.

Examples of the aryl group include an aryl group having 6 to 20 carbon atoms, and examples thereof include a phenyl group, a 1-naphthyl group, a 2-naphthyl group, a 1-anthryl group, a 2-anthryl group, a 9-anthryl group, a 1-phenanthryl group, a 2-phenanthryl group, a 3-phenanthryl group, a 4-phenanthryl group, a 9-phenanthryl group, a 1-naphthacenyl group, a 2-naphthacenyl group, a 5-naphthacenyl group, a 2-chrysenyl group, a 1-pyrenyl group, a 2-pyrenyl group, a pentacenyl group, a benzopyrenyl group, a triphenylenyl group, a biphenyl-2-yl group (o-biphenylyl group), a biphenyl-3-yl group (m-biphenylyl group), a biphenyl-4-yl group (p-biphenylyl group), a p-terphenyl-4-yl group, a m-terphenyl-4-yl group, an o-terphenyl-4-yl group, a 1,1′-binaphthyl-2-yl group, and a 2,2′-binaphthyl-1-yl group, but are not limited thereto.

The aralkyl group is an alkyl group substituted with an aryl group, and specific examples of such an aryl group and an alkyl group include the same groups as described above. The number of carbon atoms in the aralkyl group is not particularly limited, but is preferably 40 or less, more preferably 30 or less, and still more preferably 20 or less.

Specific examples of the aralkyl group include a phenylmethyl group (benzyl group), a 2-phenylethylene group, a 3-phenyl-n-propyl group, a 4-phenyl-n-butyl group, a 5-phenyl-n-pentyl group, a 6-phenyl-n-hexyl group, a 7-phenyl-n-heptyl group, an 8-phenyl-n-octyl group, a 9-phenyl-n-nonyl group, and a 10-phenyl-n-decyl group, but are not limited thereto.

The halogenated alkyl group, the halogenated aryl group, and the halogenated aralkyl group are an alkyl group, an aryl group, and an aralkyl group substituted with one or more halogen atoms, respectively, and specific examples of such an alkyl group, an aryl group, and an aralkyl group include the same groups as described above.

Examples of the halogen atom include a fluorine atom, a chlorine atom, a bromine atom, and an iodine atom.

The number of carbon atoms in the halogenated alkyl group is not particularly limited, but is preferably 40 or less, more preferably 30 or less, still more preferably 20 or less, and even more preferably 10 or less.

Specific examples of the halogenated alkyl group include a monofluoromethyl group, a difluoromethyl group, a trifluoromethyl group, a bromodifluoromethyl group, a 2-chloroethyl group, a 2-bromoethyl group, a 1,1-difluoroethyl group, a 2,2,2-trifluoroethyl group, a 1,1,2,2-tetrafluoroethyl group, a 2-chloro-1,1,2-trifluoroethyl group, a pentafluoroethyl group, a 3-bromopropyl group, a 2,2,3,3-tetrafluoropropyl group, a 1,1,2,3,3,3-hexafluoropropyl group, a 1,1,1,3,3,3-hexafluoropropan-2-yl group, a 3-bromo-2-methylpropyl group, a 4-bromobutyl group, and a perfluoropentyl group, but are not limited thereto.

The number of carbon atoms in the halogenated aryl group is not particularly limited, but is preferably 40 or less, more preferably 30 or less, and still more preferably 20 or less.

Specific examples of the halogenated aryl group include a 2-fluorophenyl group, a 3-fluorophenyl group, a 4-fluorophenyl group, a 2,3-difluorophenyl group, a 2,4-difluorophenyl group, a 2,5-difluorophenyl group, a 2,6-difluorophenyl group, a 3,4-difluorophenyl group, a 3,5-difluorophenyl group, a 2,3,4-trifluorophenyl group, a 2,3,5-trifluorophenyl group, a 2,3,6-trifluorophenyl group, a 2,4,5-trifluorophenyl group, a 2,4,6-trifluorophenyl group, a 3,4,5-trifluorophenyl group, a 2,3,4,5-tetrafluorophenyl group, a 2,3,4,6-tetrafluorophenyl group, a 2,3,5,6-tetrafluorophenyl group, a pentafluorophenyl group, a 2-fluoro-1-naphthyl group, a 3-fluoro-1-naphthyl group, a 4-fluoro-1-naphthyl group, a 6-fluoro-1-naphthyl group, a 7-fluoro-1-naphthyl group, an 8-fluoro-1-naphthyl group, a 4,5-difluoro-1-naphthyl group, a 5,7-difluoro-1-naphthyl group, a 5,8-difluoro-1-naphthyl group, a 5,6,7,8-tetrafluoro-1-naphthyl group, a heptafluoro-1-naphthyl group, a 1-fluoro-2-naphthyl group, a 5-fluoro-2-naphthyl group, a 6-fluoro-2-naphthyl group, a 7-fluoro-2-naphthyl group, a 5,7-difluoro-2-naphthyl group, and a heptafluoro-2-naphthyl group, and further include groups obtained by optionally substituting a fluorine atom (fluoro group) in these groups with a chlorine atom (chloro group), a bromine atom (bromo group), or an iodine atom (iodine group), but are not limited thereto.

The number of carbon atoms in the halogenated aralkyl group is not particularly limited, but is preferably 40 or less, more preferably 30 or less, and still more preferably 20 or less.

Specific examples of the halogenated aralkyl group include a 2-fluorobenzyl group, a 3-fluorobenzyl group, a 4-fluorobenzyl group, a 2,3-difluorobenzyl group, a 2,4-difluorobenzyl group, a 2,5-difluorobenzyl group, a 2,6-difluorobenzyl group, a 3,4-difluorobenzyl group, a 3,5-difluorobenzyl group, a 2,3,4-trifluorobenzyl group, a 2,3,5-trifluorobenzyl group, a 2,3,6-trifluorobenzyl group, a 2,4,5-trifluorobenzyl group, a 2,4,6-trifluorobenzyl group, a 2,3,4,5-tetrafluorobenzyl group, a 2,3,4,6-tetrafluorobenzyl group, a 2,3,5,6-tetrafluorobenzyl group, and a 2,3,4,5,6-pentafluorobenzyl group, and further include groups obtained by optionally substituting a fluorine atom (fluoro group) in these groups with a chlorine atom (chloro group), a bromine atom (bromo group), or an iodine atom (iodine group), but are not limited thereto.

The alkoxyalkyl group, the alkoxyaryl group, and the alkoxyaralkyl group are an alkyl group, an aryl group, and an aralkyl group substituted with one or more alkoxy groups, respectively, and specific examples of such an alkyl group, an aryl group, and an aralkyl group include the same groups as described above.

Examples of the alkoxy group as a substituent include an alkoxy group having at least any linear, branched, or cyclic alkyl moiety having 1 to 20 carbon atoms.

Examples of the linear or branched alkoxy group include a methoxy group, an ethoxy group, a n-propoxy group, an i-propoxy group, a n-butoxy group, an i-butoxy group, a s-butoxy group, a t-butoxy group, a n-pentyloxy group, a 1-methyl-n-butoxy group, a 2-methyl-n-butoxy group, a 3-methyl-n-butoxy group, a 1,1-dimethyl-n-propoxy group, a 1,2-dimethyl-n-propoxy group, a 2,2-dimethyl-n-propoxy group, a 1-ethyl-n-propoxy group, a n-hexyloxy group, a 1-methyl-n-pentyloxy group, a 2-methyl-n-pentyloxy group, a 3-methyl-n-pentyloxy group, a 4-methyl-n-pentyloxy group, a 1,1-dimethyl-n-butoxy group, a 1,2-dimethyl-n-butoxy group, a 1,3-dimethyl-n-butoxy group, a 2,2-dimethyl-n-butoxy group, a 2,3-dimethyl-n-butoxy group, a 3,3-dimethyl-n-butoxy group, a 1-ethyl-n-butoxy group, a 2-ethyl-n-butoxy group, a 1,1,2-trimethyl-n-propoxy group, a 1,2,2-trimethyl-n-propoxy group, a 1-ethyl-1-methyl-n-propoxy group, and a 1-ethyl-2-methyl-n-propoxy group.

Examples of the cyclic alkoxy group include a cyclopropoxy group, a cyclobutoxy group, a 1-methyl-cyclopropoxy group, a 2-methyl-cyclopropoxy group, a cyclopentyloxy group, a 1-methyl-cyclobutoxy group, a 2-methyl-cyclobutoxy group, a 3-methyl-cyclobutoxy group, a 1,2-dimethyl-cyclopropoxy group, a 2,3-dimethyl-cyclopropoxy group, a 1-ethyl-cyclopropoxy group, a 2-ethyl-cyclopropoxy group, a cyclohexyloxy group, a 1-methyl-cyclopentyloxy group, a 2-methyl-cyclopentyloxy group, a 3-methyl-cyclopentyloxy group, a 1-ethyl-cyclobutoxy group, a 2-ethyl-cyclobutoxy group, a 3-ethyl-cyclobutoxy group, a 1,2-dimethyl-cyclobutoxy group, a 1,3-dimethyl-cyclobutoxy group, a 2,2-dimethyl-cyclobutoxy group, a 2,3-dimethyl-cyclobutoxy group, a 2,4-dimethyl-cyclobutoxy group, a 3,3-dimethyl-cyclobutoxy group, a 1-n-propyl-cyclopropoxy group, a 2-n-propyl-cyclopropoxy group, a 1-i-propyl-cyclopropoxy group, a 2-i-propyl-cyclopropoxy group, a 1,2,2-trimethyl-cyclopropoxy group, a 1,2,3-trimethyl-cyclopropoxy group, a 2,2,3-trimethyl-cyclopropoxy group, a 1-ethyl-2-methyl-cyclopropoxy group, a 2-ethyl-1-methyl-cyclopropoxy group, a 2-ethyl-2-methyl-cyclopropoxy group, and a 2-ethyl-3-methyl-cyclopropoxy group.

Specific examples of the alkoxyalkyl group include lower (about 5 or less carbon atoms) alkyloxy lower (about 5 or less carbon atoms) alkyl groups such as a methoxymethyl group, an ethoxymethyl group, a 1-ethoxyethyl group, a 2-ethoxyethyl group, and an ethoxymethyl group, but are not limited thereto.

Specific examples of the alkoxyaryl group include a 2-methoxyphenyl group, a 3-methoxyphenyl group, a 4-methoxyphenyl group, a 2-(1-ethoxy)phenyl group, a 3-(1-ethoxy)phenyl group, a 4-(1-ethoxy)phenyl group, a 2-(2-ethoxy)phenyl group, a 3-(2-ethoxy)phenyl group, a 4-(2-ethoxy)phenyl group, a 2-methoxynaphthalen-1-yl group, a 3-methoxynaphthalen-1-yl group, a 4-methoxynaphthalen-lyl-group, a 5-methoxynaphthalen-1 yl-group, a 6-methoxynaphthalen-1 yl-group, and a 7-methoxynaphthalen-1 yl-group, but are not limited thereto.

Specific examples of the alkoxyaralkyl group include a 3-(methoxyphenyl)benzyl group and a 4-(methoxyphenyl)benzyl group, but are not limited thereto.

The alkenyl group may be linear or branched, and the number of carbon atoms thereof is not particularly limited, but is preferably 40 or less, more preferably 30 or less, still more preferably 20 or less, and even more preferably 10 or less.

Specific examples of the alkenyl group include an ethenyl group (vinyl group), a 1-propenyl group, a 2-propenyl group, a 1-methyl-1-ethenyl group, a 1-butenyl group, a 2-butenyl group, a 3-butenyl group, a 2-methyl-1-propenyl group, a 2-methyl-2-propenyl group, a 1-ethylethenyl group, a 1-methyl-1-propenyl group, a 1-methyl-2-propenyl group, a 1-pentenyl group, a 2-pentenyl group, a 3-pentenyl group, a 4-pentenyl group, a 1-n-propylethenyl group, a 1-methyl-1-butenyl group, a 1-methyl-2-butenyl group, a 1-methyl-3-butenyl group, a 2-ethyl-2-propenyl group, a 2-methyl-1-butenyl group, 2-methyl-2-butenyl group, 2-methyl-3-butenyl group, 3-methyl-1-butenyl group, 3-methyl-2-butenyl group, 3-methyl-3-butenyl group, 1,1-dimethyl-2-propenyl group, 1-i-propylethenyl group, a 1,2-dimethyl-1-propenyl group, a 1,2-dimethyl-2-propenyl group, a 1-cyclopentenyl group, a 2-cyclopentenyl group, a 3-cyclopentenyl group, a 1-hexenyl group, a 2-hexenyl group, a 3-hexenyl group, a 4-hexenyl group, a 5-hexenyl group, a 1-methyl-1-pentenyl group, a 1-methyl-2-pentenyl group, a 1-methyl-3-pentenyl group, a 1-methyl-4-pentenyl group, a 1-n-butylethenyl group, a 2-methyl-1-pentenyl group, a 2-methyl-2-pentenyl group, a 2-methyl-3-pentenyl group, a 2-methyl-4-pentenyl group, a 2-n-propyl-2-propenyl group, a 3-methyl-1-pentenyl group, a 3-methyl-2-pentenyl group, a 3-methyl-3-pentenyl group, a 3-methyl-4-pentenyl group, a 3-ethyl-3-butenyl group, a 4-methyl-1-pentenyl group, a 4-methyl-2-pentenyl group, a 4-methyl-3-pentenyl group, a 4-methyl-4-pentenyl group, a 1,1-dimethyl-2-butenyl group, a 1,1-dimethyl-3-butenyl group, a 1,2-dimethyl-1-butenyl group, a 1,2-dimethyl-2-butenyl group, a 1,2-dimethyl-3-butenyl group, a 1-methyl-2-ethyl-2-propenyl group, a 1-s-butylethenyl group, a 1,3-dimethyl-1-butenyl group, a 1,3-dimethyl-2-butenyl group, a 1,3-dimethyl-3-butenyl group, a 1-i-butylethenyl group, a 2,2-dimethyl-3-butenyl group, a 2,3-dimethyl-1-butenyl group, a 2,3-dimethyl-2-butenyl group, a 2,3-dimethyl-3-butenyl group, a 2-i-propyl-2-propenyl group, a 3,3-dimethyl-1-butenyl group, a 1-ethyl-1-butenyl group, a 1-ethyl-2-butenyl group, a 1-ethyl-3-butenyl group, a 1-n-propyl-1-propenyl group, a 1-n-propyl-2-propenyl group, a 2-ethyl-1-butenyl group, a 2-ethyl-2-butenyl group, a 2-ethyl-3-butenyl group, a 1,1,2-trimethyl-2-propenyl group, a 1-t-butylethenyl group, a 1-methyl-1-ethyl-2-propenyl group, a 1-ethyl-2-methyl-1-propenyl group, a 1-ethyl-2-methyl-2-propenyl group, a 1-i-propyl-1-propenyl group, a 1-i-propyl-2-propenyl group, a 1-methyl-2-cyclopentenyl group, a 1-methyl-3-cyclopentenyl group, a 2-methyl-1-cyclopentenyl group, a 2-methyl-2-cyclopentenyl group, a 2-methyl-3-cyclopentenyl group, a 2-methyl-4-cyclopentenyl group, a 2-methyl-5-cyclopentenyl group, a 2-methylene-cyclopentyl group, a 3-methyl-1-cyclopentenyl group, a 3-methyl-2-cyclopentenyl group, a 3-methyl-3-cyclopentenyl group, a 3-methyl-4-cyclopentenyl group, a 3-methyl-5-cyclopentenyl group, a 3-methylene-cyclopentyl group, a 1-cyclohexenyl group, a 2-cyclohexenyl group, and a 3-cyclohexenyl group, and examples thereof also include a bridged cyclic alkenyl group such as a bicycloheptenyl group (norbornyl group).

Examples of the substituent in the alkyl group, the aryl group, the aralkyl group, the halogenated alkyl group, the halogenated aryl group, the halogenated aralkyl group, the alkoxyalkyl group, the alkoxyaryl group, the alkoxyaralkyl group, and the alkenyl group include an alkyl group, an aryl group, an aralkyl group, a halogenated alkyl group, a halogenated aryl group, a halogenated aralkyl group, an alkoxyalkyl group, an aryloxy group, an alkoxyaryl group, an alkoxyaralkyl group, an alkenyl group, an alkoxy group, and an aralkyloxy group, and specific examples thereof and a suitable number of carbon atoms thereof include the same ones as described above or below.

The aryloxy group mentioned in the substituent is a group in which an aryl group is bonded via an oxygen atom (—O—), and specific examples of such an aryl group include the same groups as described above. The number of carbon atoms in the aryloxy group is not particularly limited, but is preferably 40 or less, more preferably 30 or less, and still more preferably 20 or less, and specific examples thereof include a phenoxy group and a naphthalen-2-yloxy group, but are not limited thereto.

When there are two or more substituents, the substituents may be bonded to each other to form a ring.

Examples of the organic group having an epoxy group include a glycidoxymethyl group, a glycidoxyethyl group, a glycidoxypropyl group, a glycidoxybutyl group, and an epoxycyclohexyl group.

Examples of the organic group having an acryloyl group include an acryloyloxymethyl group, an acryloyloxyethyl group, and an acryloyloxypropyl group.

Examples of the organic group having a methacryloyl group include a methacryloyloxymethyl group, a methacryloyloxyethyl group, and a methacryloyloxypropyl group.

Examples of the organic group having a mercapto group include a mercaptoethyl group, a mercaptobutyl group, a mercaptohexyl group, a mercaptooctyl group, and a mercaptophenyl group.

Examples of the organic group having an amino group include an amino group, an aminomethyl group, an aminoethyl group, an aminophenyl group, a dimethylaminoethyl group, and a dimethylaminopropyl group, but are not limited thereto. The organic group having an amino group will be described later in more detail.

Examples of the organic group having an alkoxy group include a methoxymethyl group and a methoxyethyl group, but are not limited thereto. However, a group in which an alkoxy group is directly bonded to a silicon atom is excluded.

Examples of the organic group having a sulfonyl group include a sulfonylalkyl group and a sulfonylaryl group, but are not limited thereto.

Examples of the organic group having a cyano group include a cyanoethyl group, a cyanopropyl group, a cyanophenyl group, and a thiocyanate group.

Examples of the organic group having an amino group include an organic group having at least any of a primary amino group, a secondary amino group, and a tertiary amino group. A hydrolysis condensate in which a hydrolyzable silane having a tertiary amino group is hydrolyzed with a strong acid to form a counter cation having a tertiary ammonium group can be preferably used. The organic group can contain a heteroatom such as an oxygen atom or a sulfur atom in addition to the nitrogen atom forming the amino group.

Preferable examples of the organic group having an amino group include a group represented by the following formula (A1).

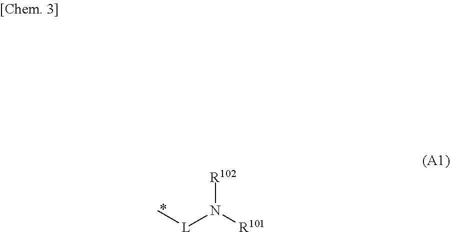

In formula (A1), R¹⁰¹ and R¹⁰² each independently represent a hydrogen atom or a hydrocarbon group, and L's each independently represent an alkylene group which may be substituted. * represents a bond.

Examples of the hydrocarbon group include an alkyl group, an alkenyl group, and an aryl group, but are not limited thereto. Specific examples of the alkyl group, the alkenyl group, and the aryl group include the same groups as described above in R¹.

The alkylene group may be either linear or branched, and the number of carbon atoms thereof is usually 1 to 10 and preferably 1 to 5. Examples thereof include linear alkylene groups such as a methylene group, an ethylene group, a trimethylene group, a tetramethylene group, a pentamethylene group, a hexamethylene group, a heptamethylene group, an octamethylene group, a nonamethylene group, and a decamethylene group.

Examples of the organic group having an amino group include an amino group, an aminomethyl group, an aminoethyl group, an aminophenyl group, a dimethylaminoethyl group, and a dimethylaminopropyl group, but are not limited thereto.

### <<<R²>>>

Examples of the alkoxy group in R² include the alkoxy groups exemplified in the description of R¹.

Examples of the halogen atom in R² include the halogen atoms exemplified in the description of R¹.

The aralkyloxy group is a monovalent group derived by removing a hydrogen atom from a hydroxy group of an aralkyl alcohol, and specific examples of the aralkyl group in the aralkyloxy group include the same groups as described above.

The number of carbon atoms in the aralkyloxy group is not particularly limited, but can be set to, for example, 40 or less, preferably 30 or less, and more preferably 20 or less.

Specific examples of the aralkyloxy group include a phenylmethyloxy group (benzyloxy group), a 2-phenylethyleneoxy group, a 3-phenyl-n-propyloxy group, a 4-phenyl-n-butyloxy group, a 5-phenyl-n-pentyloxy group, a 6-phenyl-n-hexyloxy group, a 7-phenyl-n-heptyloxy group, an 8-phenyl-n-octyloxy group, a 9-phenyl-n-nonyloxy group, and a 10 phenyl-n-decyloxy group, but are not limited thereto.

The acyloxy group is a monovalent group derived by removing a hydrogen atom from a carboxyl group (—COOH) of a carboxylic acid compound, and typical examples thereof include an alkylcarbonyloxy group, an arylcarbonyloxy group, and an aralkylcarbonyloxy group derived by removing a hydrogen atom from a carboxyl group of an alkyl carboxylic acid, an aryl carboxylic acid, and an aralkyl carboxylic acid, but are not limited thereto. Specific examples of the alkyl group, the aryl group, and the aralkyl group in the alkyl carboxylic acid, the aryl carboxylic acid, and the aralkyl carboxylic acid include the same groups as described above.

Specific examples of the acyloxy group include an acyloxy group having 2 to 20 carbon atoms, and examples thereof include a methylcarbonyloxy group, an ethylcarbonyloxy group, a n-propylcarbonyloxy group, an i-propylcarbonyloxy group, a n-butylcarbonyloxy group, an i-butylcarbonyloxy group, a s-butylcarbonyloxy group, a t-butylcarbonyloxy group, a n-pentylcarbonyloxy group, a 1-methyl-n-butylcarbonyloxy group, a 2-methyl-n-butylcarbonyloxy group, a 3-methyl-n-butylcarbonyloxy group, a 1,1-dimethyl-n-propylcarbonyloxy group, a 1,2-dimethyl-n-propylcarbonyloxy group, a 2,2-dimethyl-n-propylcarbonyloxy group, a 1-ethyl-n-propylcarbonyloxy group, a n-hexylcarbonyloxy group, 1-methyl-n-pentylcarbonyloxy group, 2-methyl-n-pentylcarbonyloxy group, 3-methyl-n-pentylcarbonyloxy group, 4-methyl-n-pentylcarbonyloxy group, 1,1-dimethyl-n-butylcarbonyloxy group, 1,2-dimethyl-n-butylcarbonyloxy group, 1,3-dimethyl-n-butylcarbonyloxy group, 2,2-dimethyl-n-butylcarbonyloxy group, 2,3-dimethyl-n-butylcarbonyloxy group, 3,3-dimethyl-n-butylcarbonyloxy group, 1-ethyl-n-butylcarbonyloxy group, 2-ethyl-n-butylcarbonyloxy group, 1,1,2-trimethyl-n-propylcarbonyloxy group, 1,2,2-trimethyl-n-propylcarbonyloxy group, a 1-ethyl-1-methyl-n-propylcarbonyloxy group, a 1-ethyl-2-methyl-n-propylcarbonyloxy group, a phenylcarbonyloxy group, and a tosylcarbonyloxy group.

### <<<Specific Examples of Hydrolyzable Silane Represented by Formula (1)>>>

Specific examples of the hydrolyzable silane represented by formula (1) include tetramethoxysilane, tetrachlorosilane, tetraacetoxysilane, tetraethoxysilane, tetra-n-propoxysilane, tetra-i-propoxysilane, tetra-n-butoxysilane, methyltrimethoxysilane, methyltrichlorosilane, methyltriacetoxysilane, methyltriethoxysilane, methyltripropoxysilane, methyltributoxysilane, methyltriamyloxysilane, methyltriphenoxysilane, methyltribenzyloxysilane, methyltriphenethyloxysilane, glycidoxymethyltrimethoxysilane, glycidoxymethyltriethoxysilane, α-glycidoxyethyltrimethoxysilane, α-glycidoxyethyltriethoxysilane, β-glycidoxyethyltrimethoxysilane, β-glycidoxyethyltriethoxysilane, α-glycidoxypropyltrimethoxysilane, α-glycidoxypropyltriethoxysilane, β-glycidoxypropyltrimethoxysilane, β-glycidoxypropyltriethoxysilane, γ-glycidoxypropyltrimethoxysilane, γ-glycidoxypropyltriethoxysilane, γ-glycidoxypropyltripropoxysilane, γ-glycidoxypropyltributoxysilane, γ-glycidoxypropyltriphenoxysilane, α-glycidoxybutyltrimethoxysilane, α-glycidoxybutyltriethoxysilane, β-glycidoxybutyltriethoxysilane, γ-glycidoxybutyltrimethoxysilane, γ-glycidoxybutyltriethoxysilane, δ-glycidoxybutyltrimethoxysilane, δ-glycidoxybutyltriethoxysilane, (3,4-epoxycyclohexyl)methyltrimethoxysilane, (3,4-epoxycyclohexyl)methyltriethoxysilane, β-(3,4-epoxycyclohexyl)ethyltrimethoxysilane, β-(3,4-epoxycyclohexyl) ethyltriethoxysilane, β-(3,4-epoxycyclohexyl)ethyltripropoxysilane, β-(3,4-epoxycyclohexyl)ethyltributoxysilane, β-(3,4-epoxycyclohexyl)ethyltriphenoxysilane, γ-(3,4-epoxycyclohexyl)propyltrimethoxysilane, γ-(3,4-epoxycyclohexyl)propyltriethoxysilane, δ-(3,4-epoxycyclohexyl)butyltrimethoxysilane, δ-(3,4-epoxycyclohexyl)butyltriethoxysilane, glycidoxymethylmethyldimethoxysilane, glycidoxymethylmethyldiethoxysilane, α-glycidoxyethylmethyldimethoxysilane, α-glycidoxyethylmethyldiethoxysilane, β-glycidoxyethylmethyldimethoxysilane, β-glycidoxyethylethyldimethoxysilane, α-glycidoxypropylmethyldimethoxysilane, α-glycidoxypropylmethyldiethoxysilane, β-glycidoxypropylmethyldimethoxysilane, β-glycidoxypropylethyldimethoxysilane, γ-glycidoxypropylmethyldimethoxysilane, γ-glycidoxypropylmethyldiethoxysilane, γ-glycidoxypropylmethyldipropoxysilane, γ-glycidoxypropylmethyldibutoxysilane, γ-glycidoxypropylmethyldiphenoxysilane, γ-glycidoxypropylethyldimethoxysilane, γ-glycidoxypropylethyldiethoxysilane, γ-glycidoxypropylvinyldimethoxysilane, γ-glycidoxypropylvinyldiethoxysilane, ethyltrimethoxysilane, ethyltriethoxysilane, vinyltrimethoxysilane, vinyltriethoxysilane, vinyltrichlorosilane, vinyltriacetoxysilane, methylvinyldimethoxysilane, methylvinyldiethoxysilane, methylvinyldichlorosilane, methylvinyldiacetoxysilane, dimethylvinylmethoxysilane, dimethylvinylethoxysilane, dimethylvinylchlorosilane, dimethylvinylacetoxysilane, divinyldimethoxysilane, divinyldiethoxysilane, divinyldichlorosilane, divinyldiacetoxysilane, γ-glycidoxypropylvinyldimethoxysilane, γ-glycidoxypropylvinyldiethoxysilane, allyltrimethoxysilane, allyltriethoxysilane, allyltrichlorosilane, allyltriacetoxysilane, allylmethyldimethoxysilane, allylmethyldiethoxysilane, allylmethyldichlorosilane, allylmethyldiacetoxysilane, allyldimethylmethoxysilane, allyldimethylethoxysilane, allyldimethylchlorosilane, allyldimethylacetoxysilane, diallyldimethoxysilane, diallyldiethoxysilane, diallyldichlorosilane, diallyldiacetoxysilane, 3-allylaminopropyltrimethoxysilane, 3-allylaminopropyltriethoxysilane, p-styryltrimethoxysilane, phenyltrimethoxysilane, phenyltriethoxysilane, phenyltrichlorosilane, phenyltriacetoxysilane, phenylmethyldimethoxysilane, phenylmethyldiethoxysilane, phenylmethyldichlorosilane, phenylmethyldiacetoxysilane, phenyldimethylmethoxysilane, phenyldimethylethoxysilane, phenyldimethylchlorosilane, phenyldimethylacetoxysilane, diphenylmethylmethoxysilane, diphenylmethylethoxysilane, diphenylmethylchlorosilane, diphenylmethylacetoxysilane, diphenyldimethoxysilane, diphenyldiethoxysilane, diphenyldichlorosilane, diphenyldiacetoxysilane, triphenylmethoxysilane, triphenylethoxysilane, triphenylacetoxysilane, triphenylchlorosilane, 3-phenylaminopropyltrimethoxysilane, 3-phenylaminopropyltriethoxysilane, dimethoxymethyl-3-(3-phenoxypropylthiopropyl)silane, triethoxy((2-methoxy-4-(methoxymethyl)phenoxy)methyl)silane, benzyltrimethoxysilane, benzyltriethoxysilane, benzylmethyldimethoxysilane, benzylmethyldiethoxysilane, benzyldimethylmethoxysilane, benzyldimethylethoxysilane, benzyldimethylchlorosilane, phenethyltrimethoxysilane, phenethyltriethoxysilane, phenethyltrichlorosilane, phenethyltriacetoxysilane, phenethylmethyldimethoxysilane, phenethylmethyldiethoxysilane, phenetylmethyldichlorosilane, phenethylmethyldiacetoxysilane, methoxyphenyltrimethoxysilane, methoxyphenyltriethoxysilane, methoxyphenyltriacetoxysilane, methoxyphenyltrichlorosilane, methoxybenzyltrimethoxysilane, methoxybenzyltriethoxysilane, methoxybenzyltriacetoxysilane, methoxybenzyltrichlorosilane, methoxyphenethyltrimethoxysilane, methoxyphenetyltriethoxysilane, methoxyphenetyltriacetoxysilane, methoxyphenethyltrichlorosilane, ethoxyphenyltrimethoxysilane, ethoxyphenyltriethoxysilane, ethoxyphenyltriacetoxysilane, ethoxyphenyltrichlorosilane, ethoxybenzyltrimethoxysilane, ethoxybenzyltriethoxysilane, ethoxybenzyltriacetoxysilane, ethoxybenzyltrichlorosilane, i-propoxyphenyltrimethoxysilane, i-propoxyphenyltriethoxysilane, i-propoxyphenyltriacetoxysilane, i-propoxyphenyltrichlorosilane, i-propoxybenzyltrimethoxysilane, i-propoxybenzyltriethoxysilane, i-propoxybenzyltriacetoxysilane, i-propoxybenzyltrichlorosilane, t-butoxyphenyltrimethoxysilane, t-butoxyphenyltriethoxysilane, t-butoxyphenyltriacetoxysilane, t-butoxyphenyltrichlorosilane, t-butoxybenzyltrimethoxysilane, t-butoxybenzyltriethoxysilane, t-butoxybenzyltriacetoxysilane, t-butoxybenzyltrichlorosilane, methoxynaphthyltrimethoxysilane, methoxynaphthyltriethoxysilane, methoxynaphtyltriacetoxysilane, methoxynaphtyltrichlorosilane, ethoxynaphtyltrimethoxysilane, ethoxynaphthyltriethoxysilane, ethoxynaphthyltriacetoxysilane, ethoxynaphthyltrichlorosilane, γ-chloropropyltrimethoxysilane, γ-chloropropyltriethoxysilane, γ-chloropropyltriacetoxysilane, 3,3,3-trifluoropropyltrimethoxysilane, γ-methacryloxypropyltrimethoxysilane, γ-mercaptopropyltrimethoxysilane, γ-mercaptopropyltriethoxysilane, β-cyanoethyltriethoxysilane, thiocyanate propyltriethoxysilane, chloromethyltrimethoxysilane, chloromethyltriethoxysilane, triethoxysilylpropyldiallyl isocyanurate, bicyclo[2,2,1]heptenyltriethoxysilane, benzenesulfonylpropyltriethoxysilane, benzenesulfoneamidepropyltriethoxysilane, dimethylaminopropyltrimethoxysilane, dimethyldimethoxysilane, phenylmethyldimethoxysilane, dimethyldiethoxysilane, phenylmethyldiethoxysilane, γ-chloropropylmethyldimethoxysilane, γ-chloropropylmethyldiethoxysilane, dimethyldiacetoxysilane, γ-methacryloxypropylmethyldimethoxysilane, γ-methacryloxypropylmethyldiethoxysilane, γ-mercaptopropylmethyldimethoxysilane, γ-mercaptomethyldiethoxysilane, methylvinyldimethoxysilane, methylvinyldiethoxysilane, silanes represented by the following formulae (A-1) to (A-41), and silanes represented by the following formulae (1-1) to (1-290), but are not limited thereto.

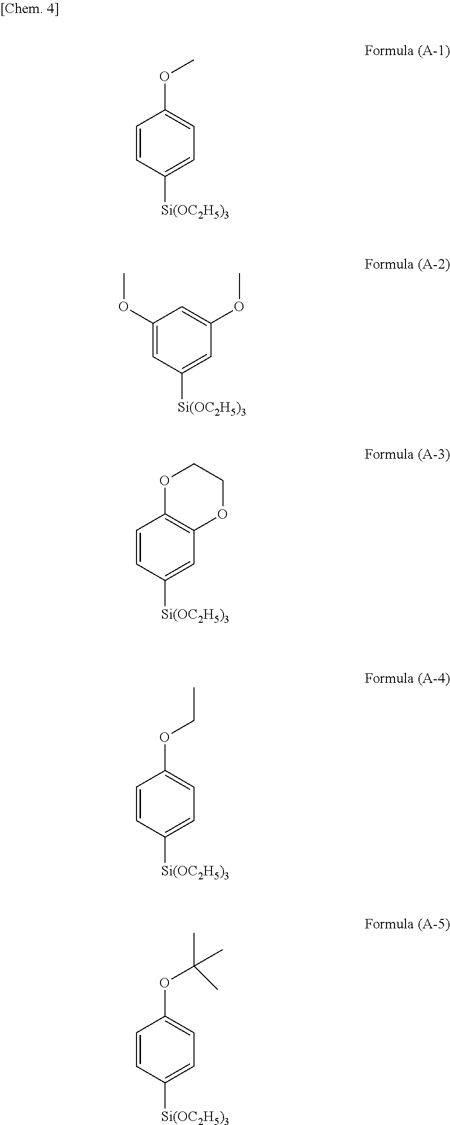

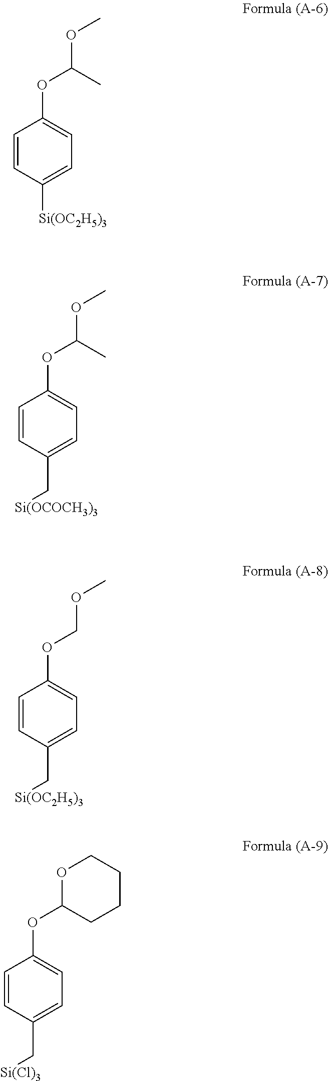

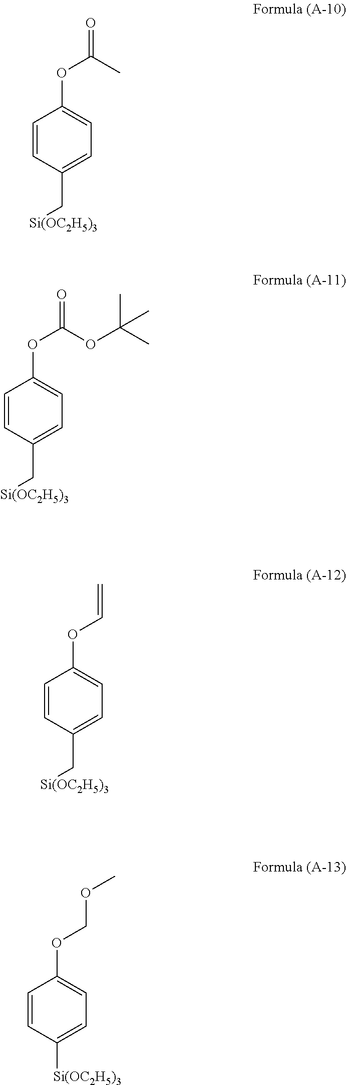

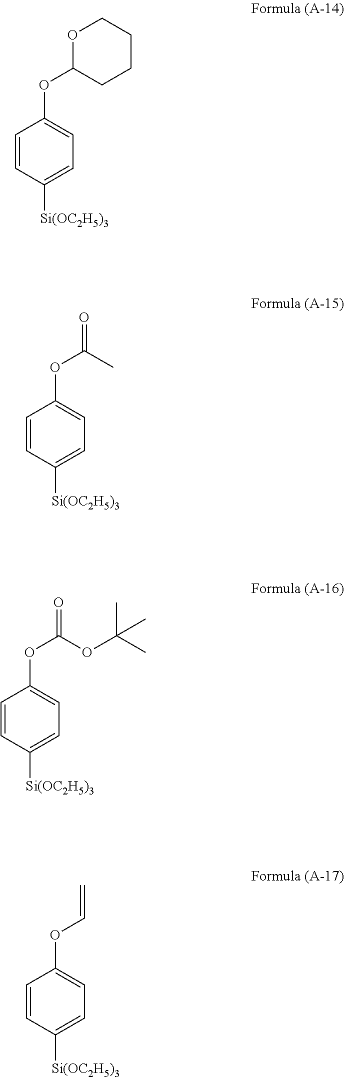

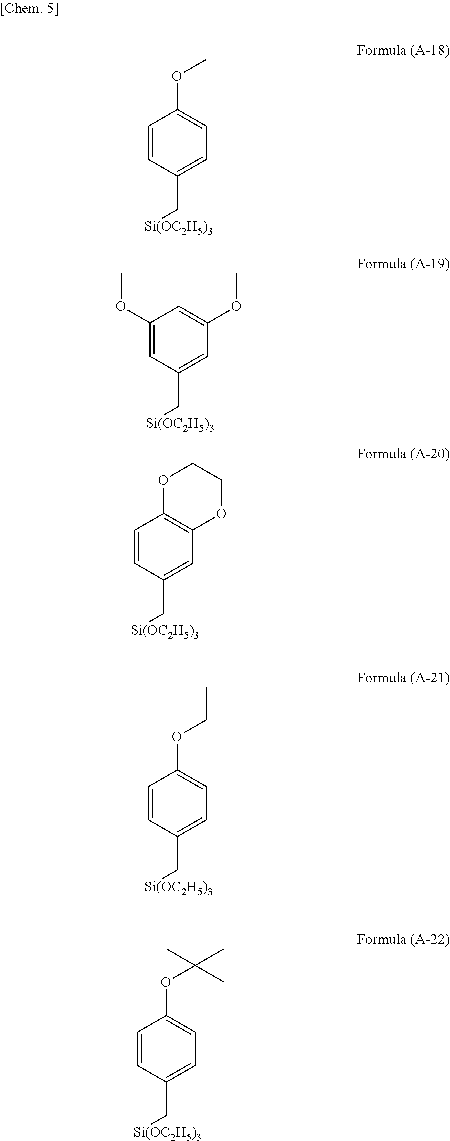

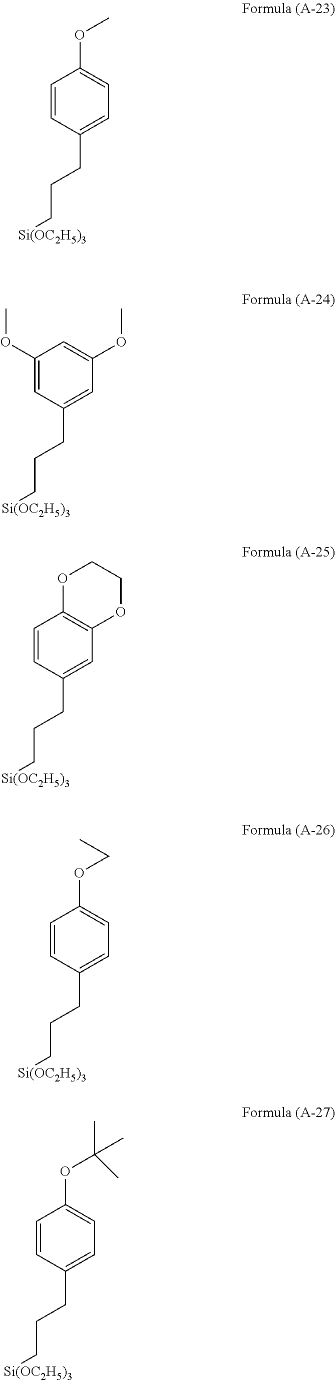

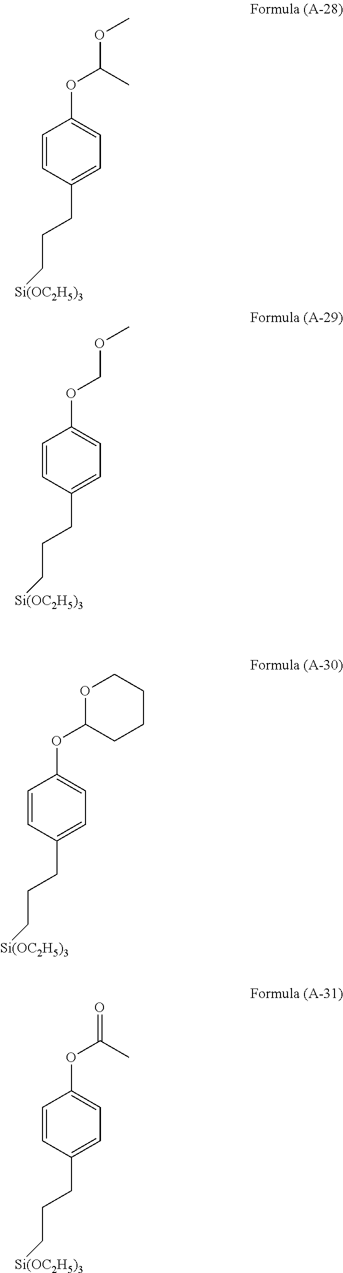

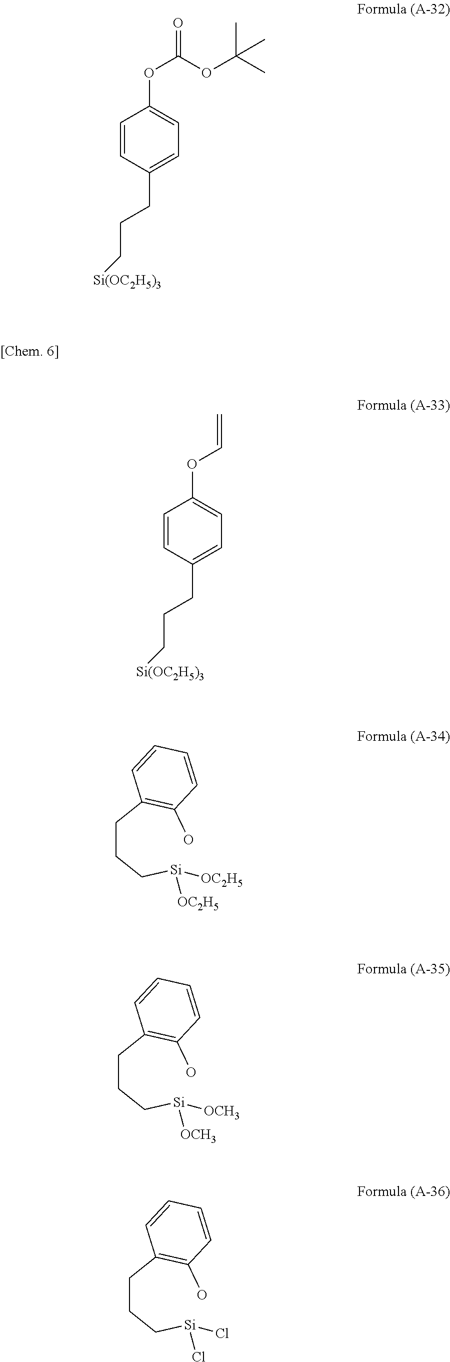

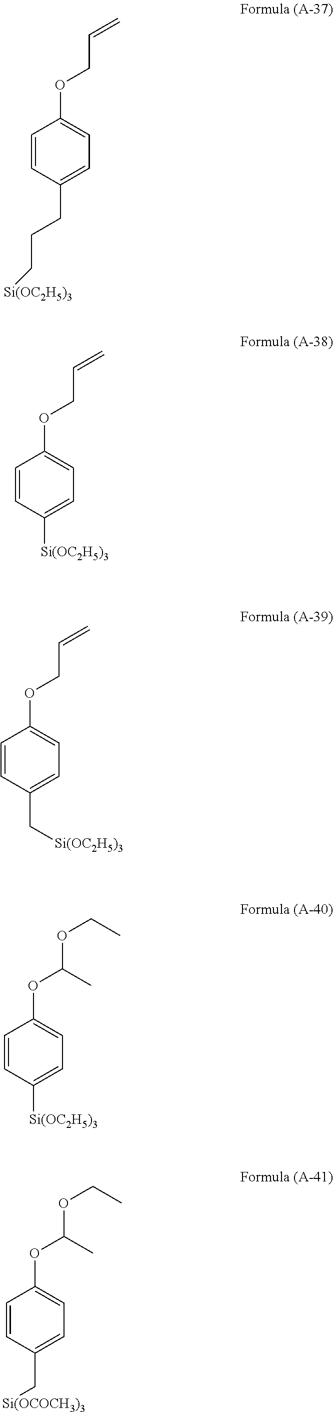

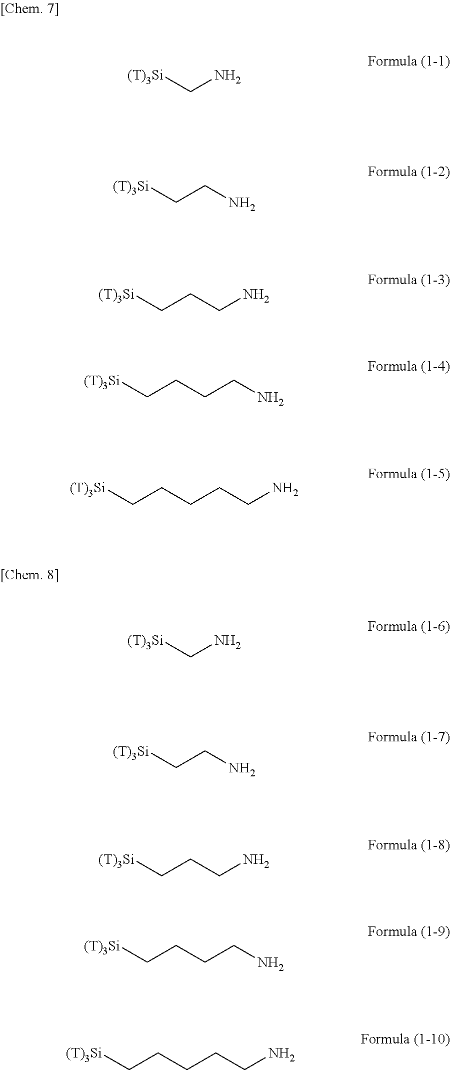

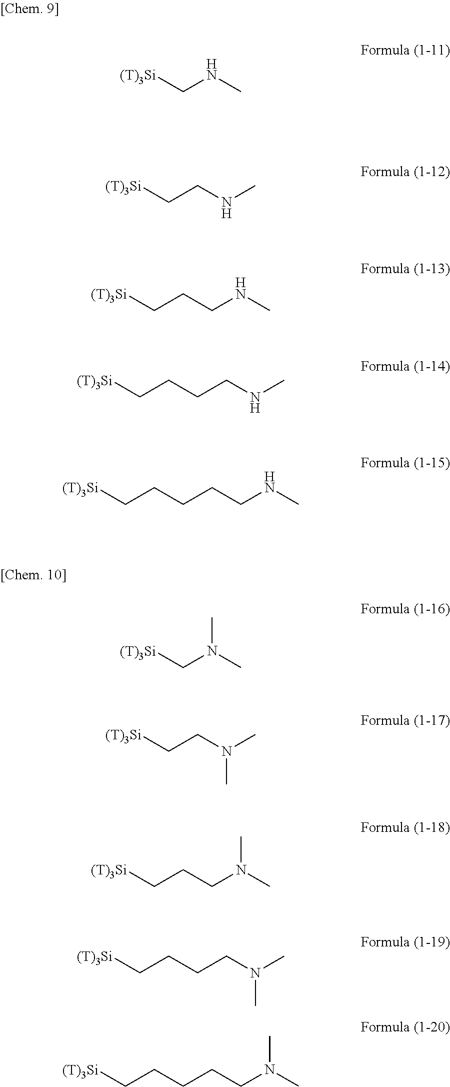

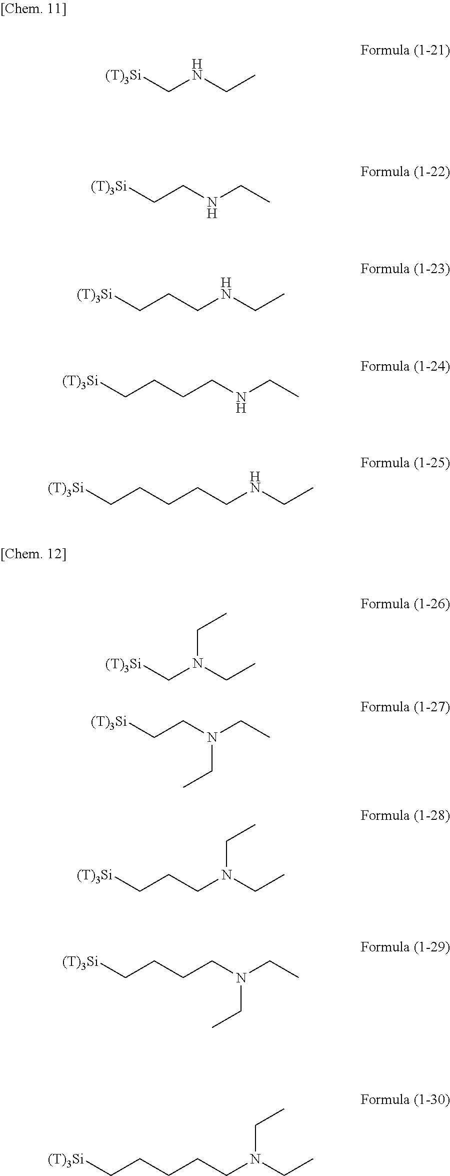

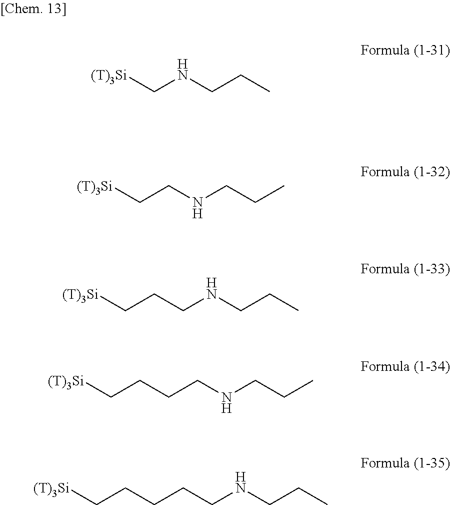

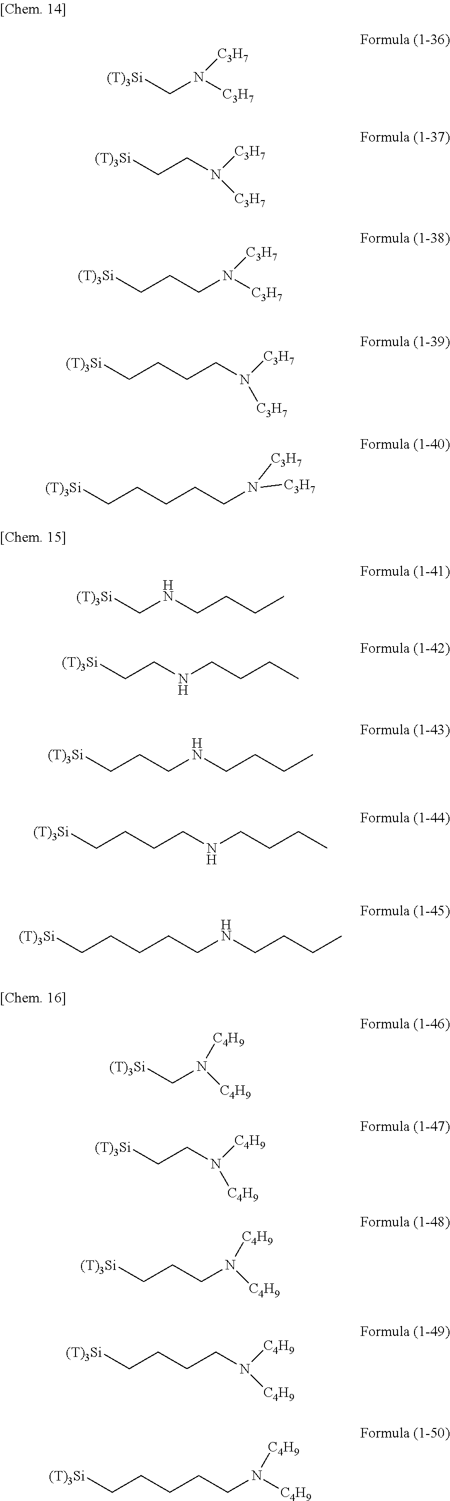

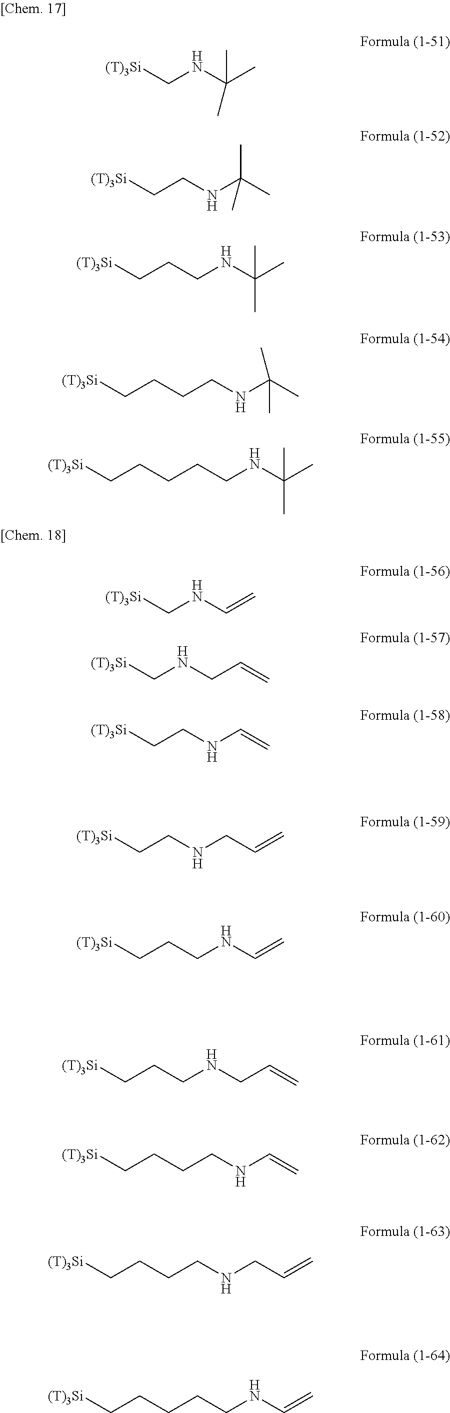

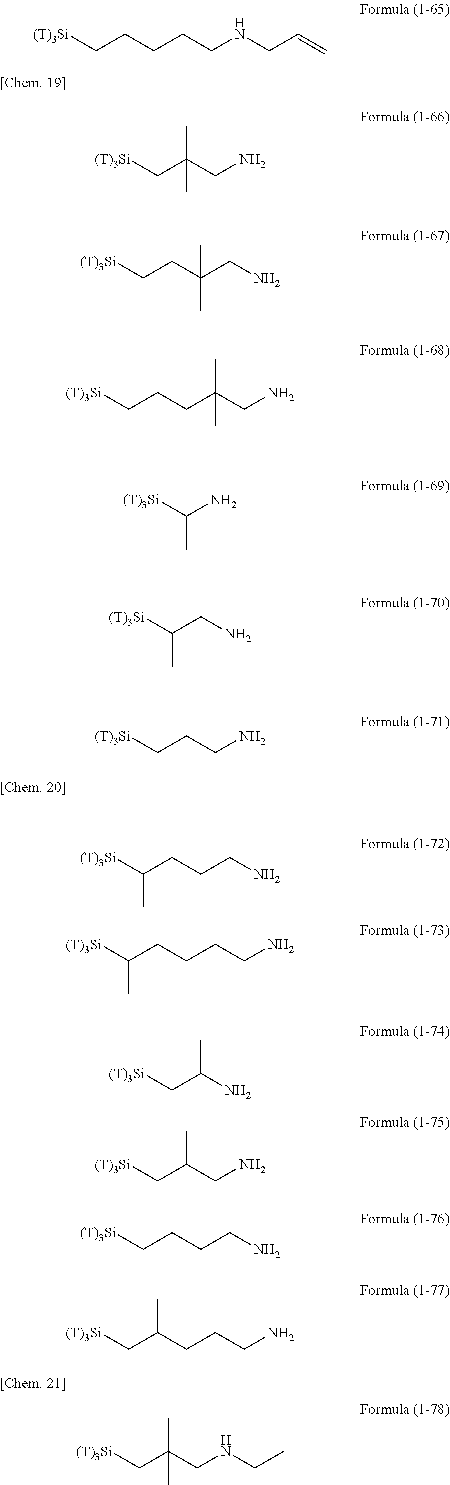

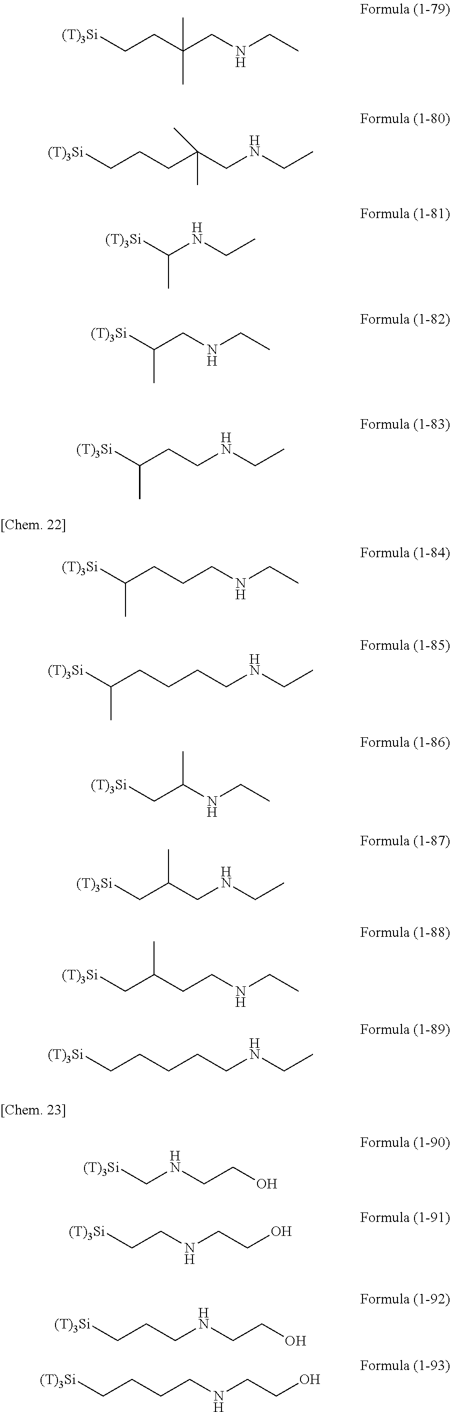

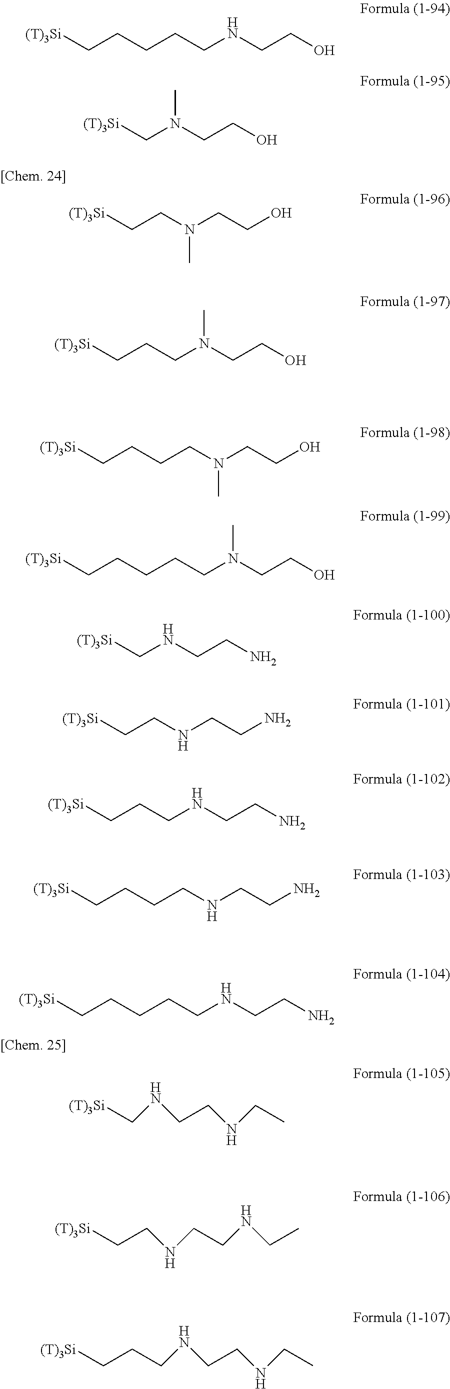

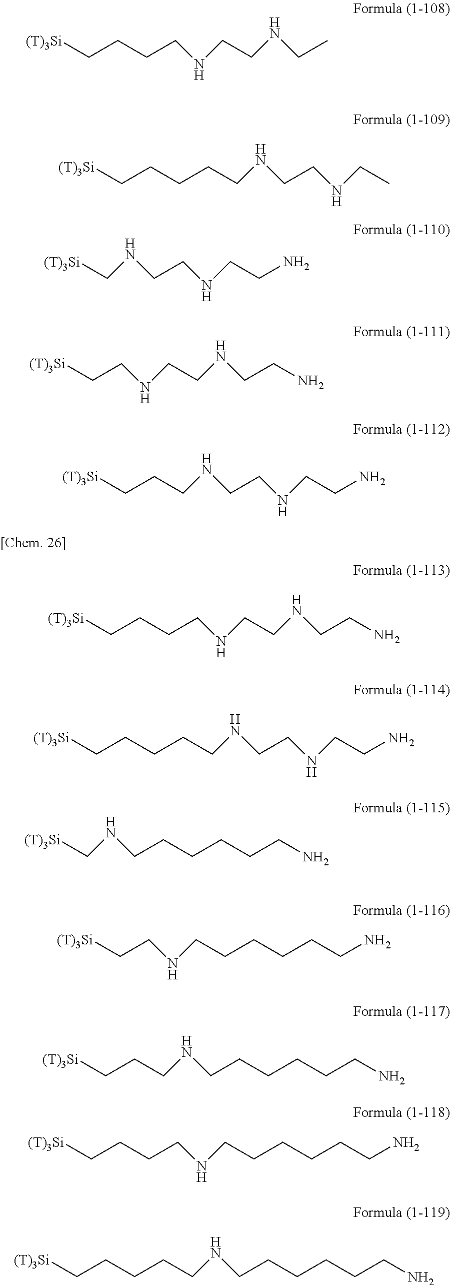

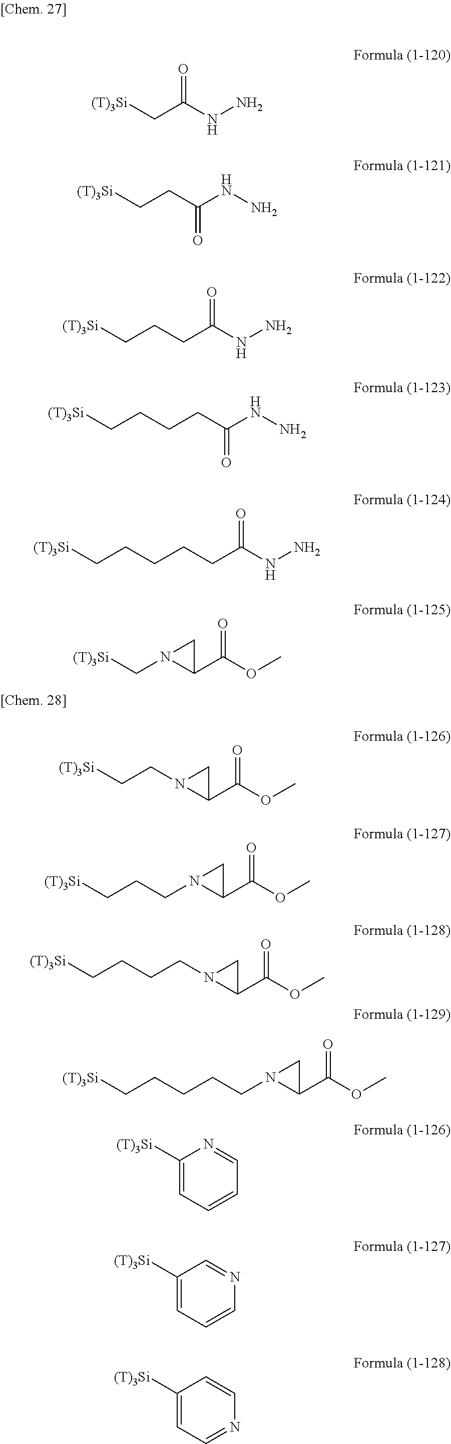

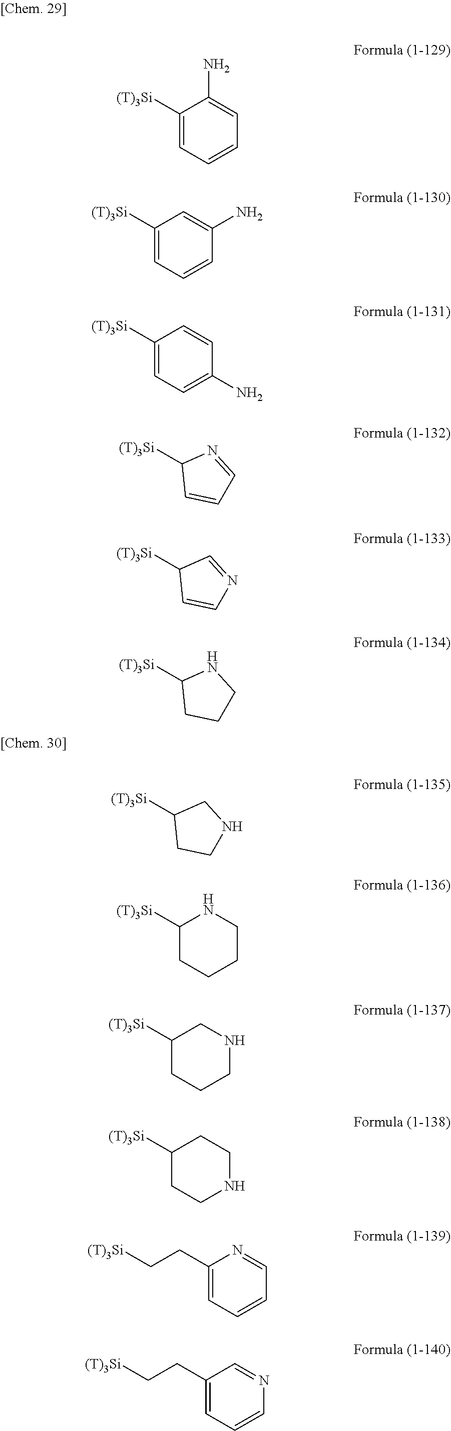

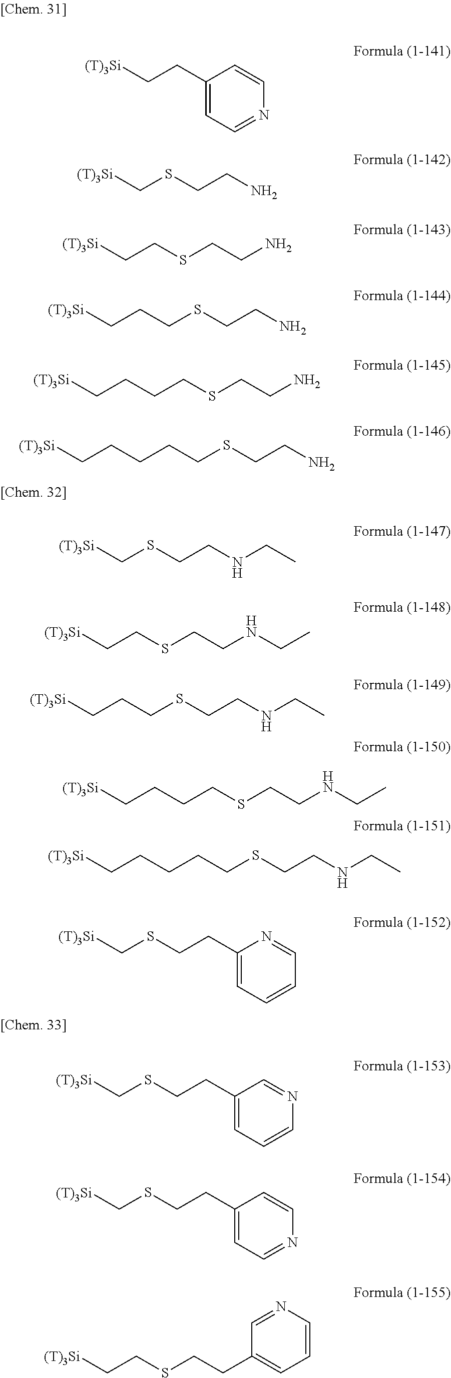

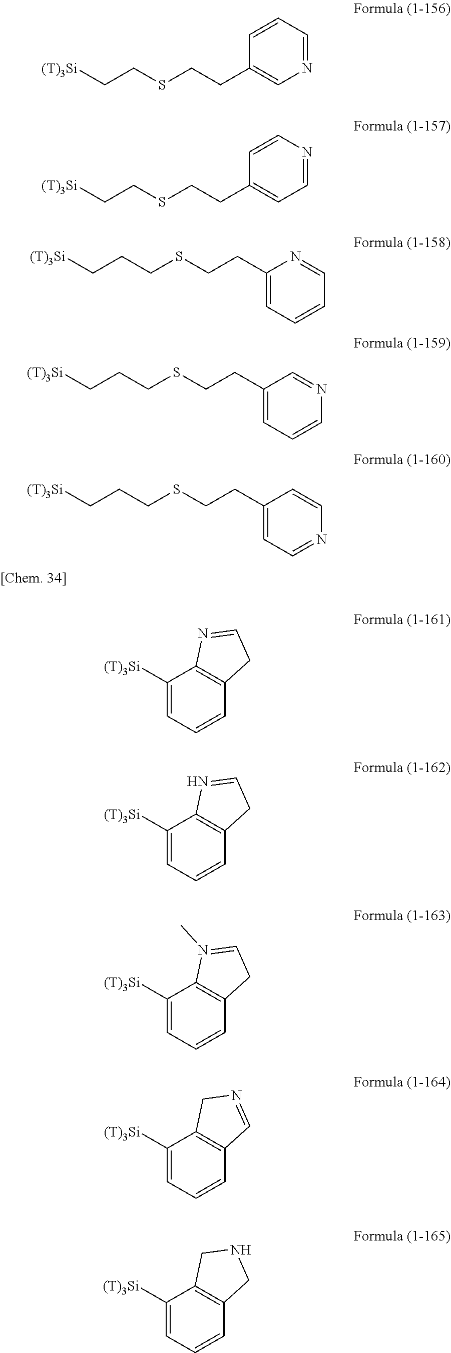

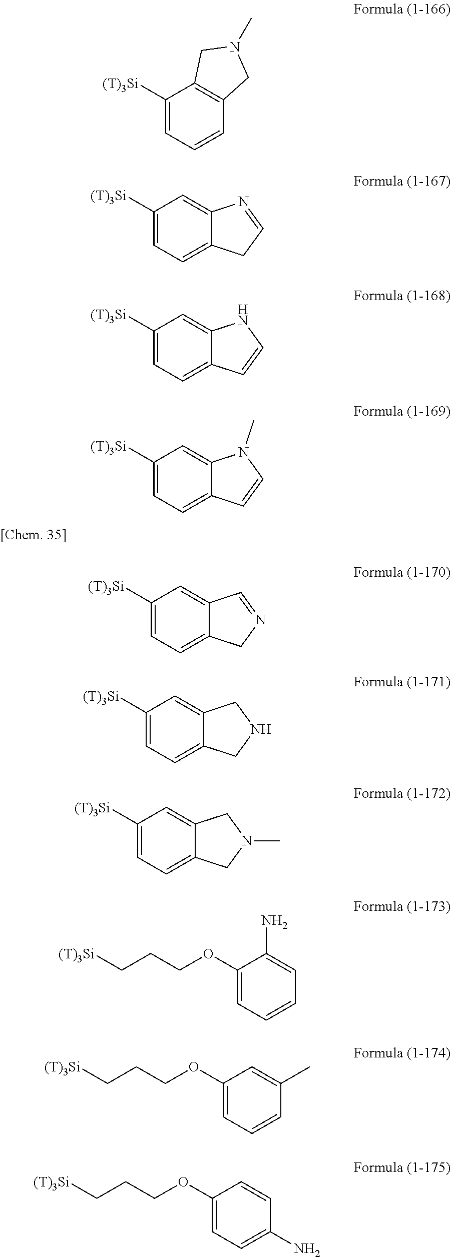

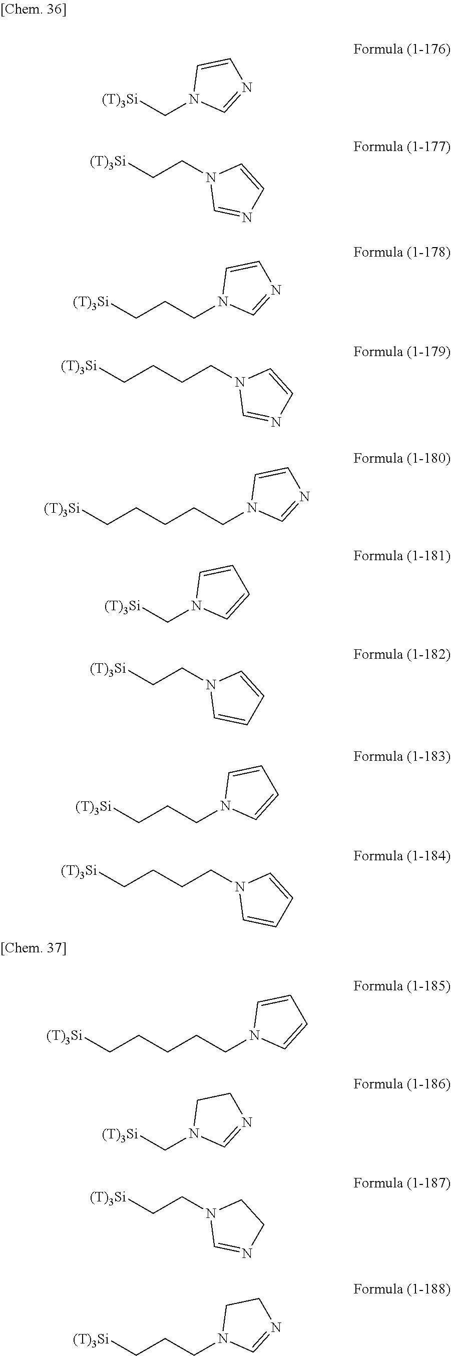

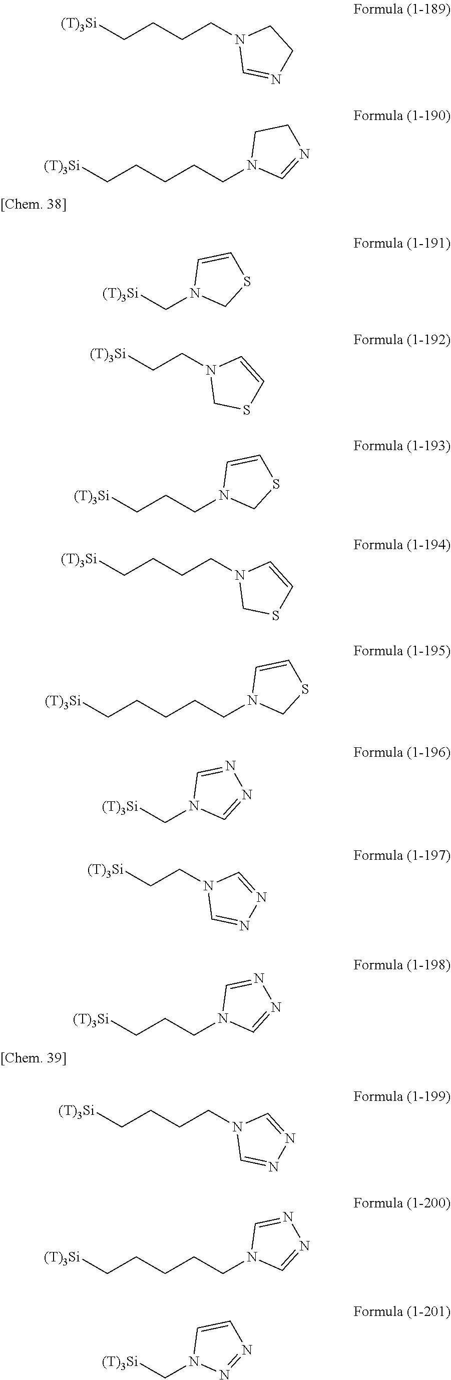

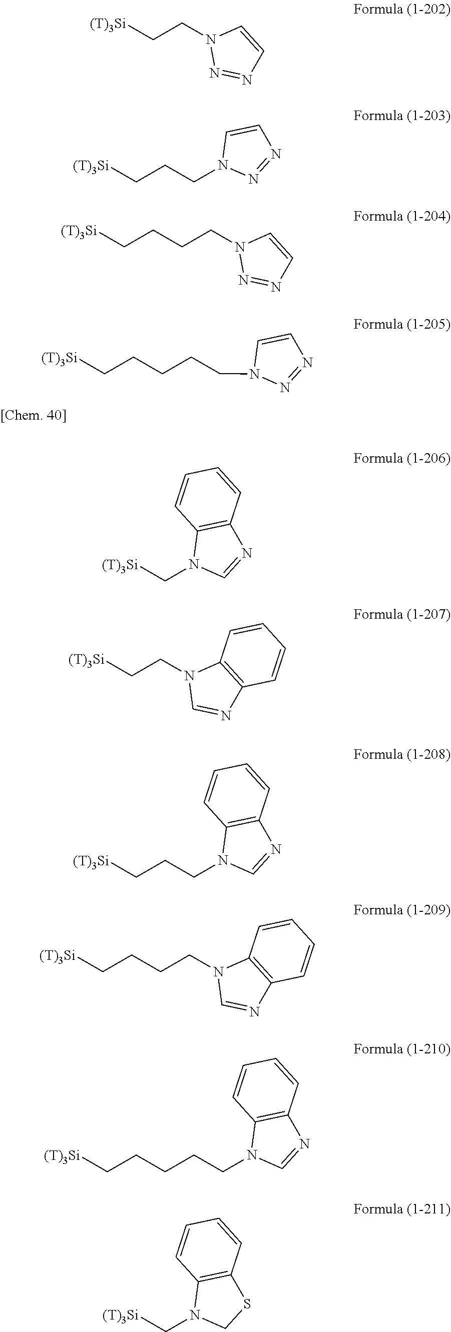

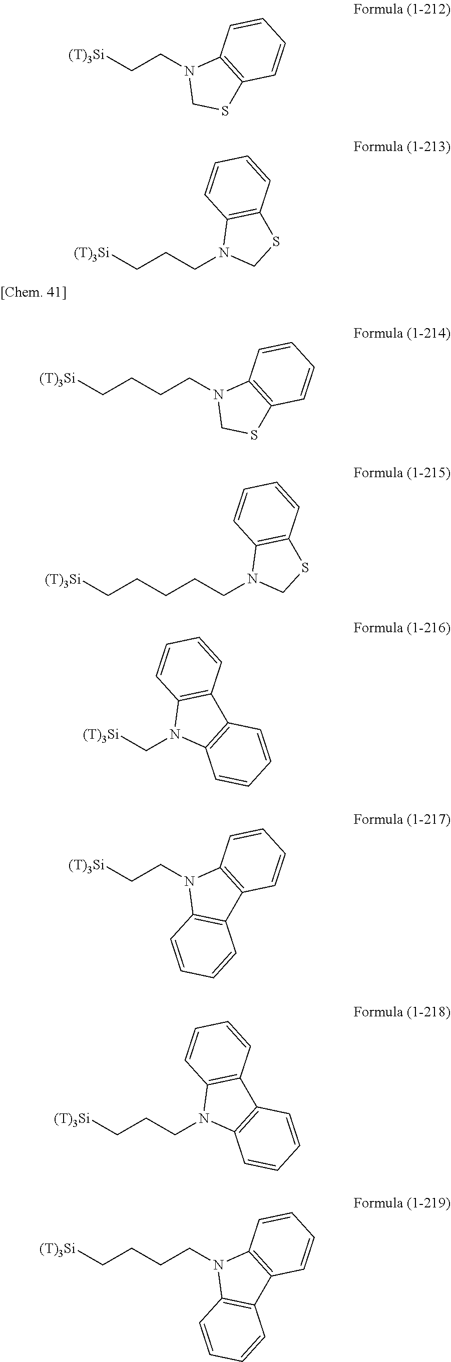

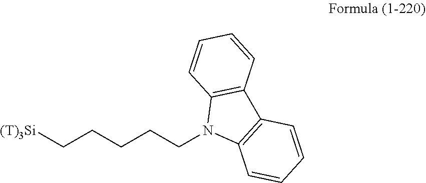

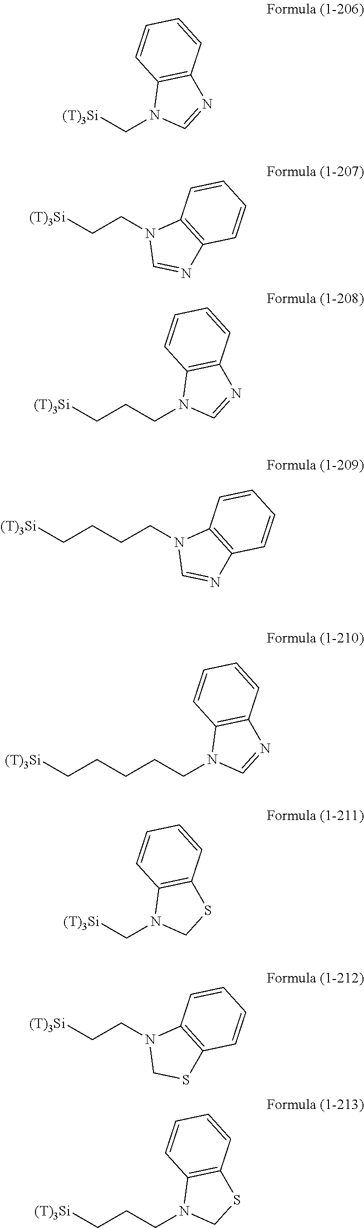

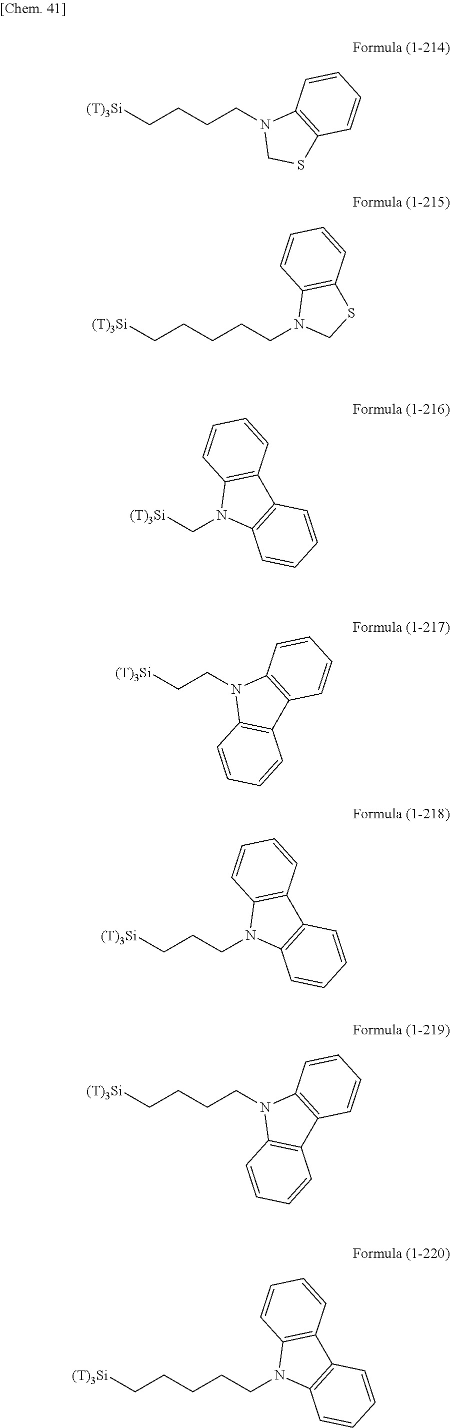

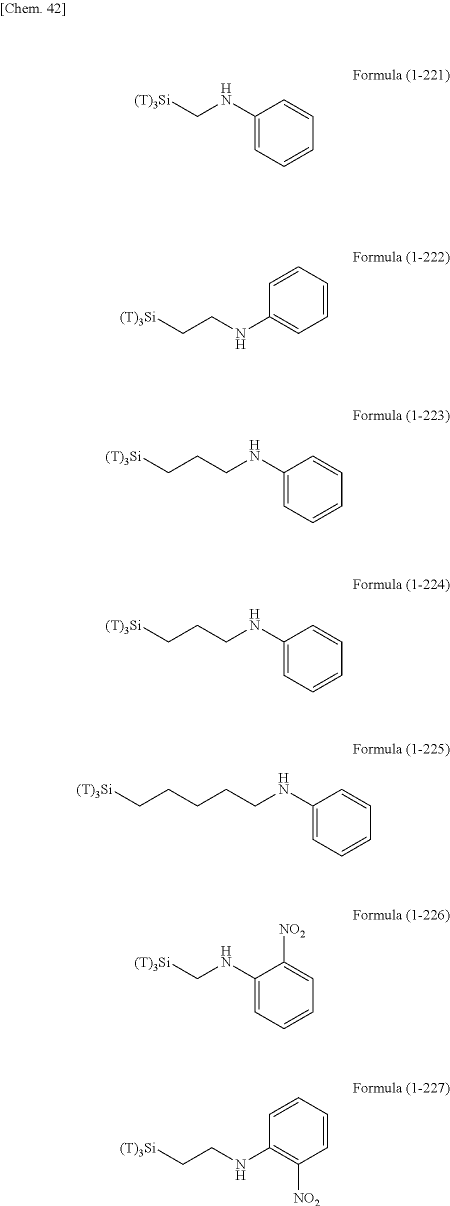

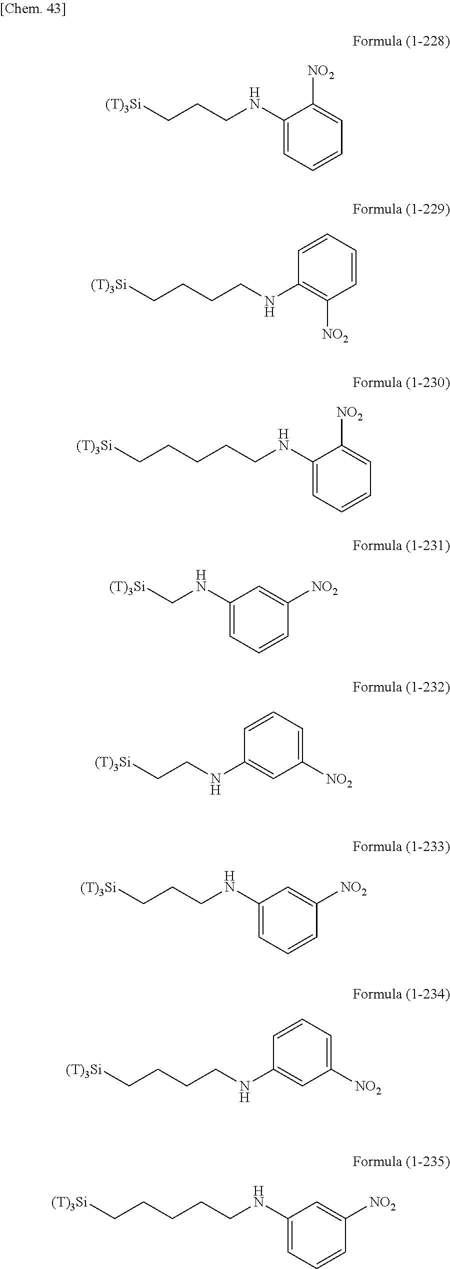

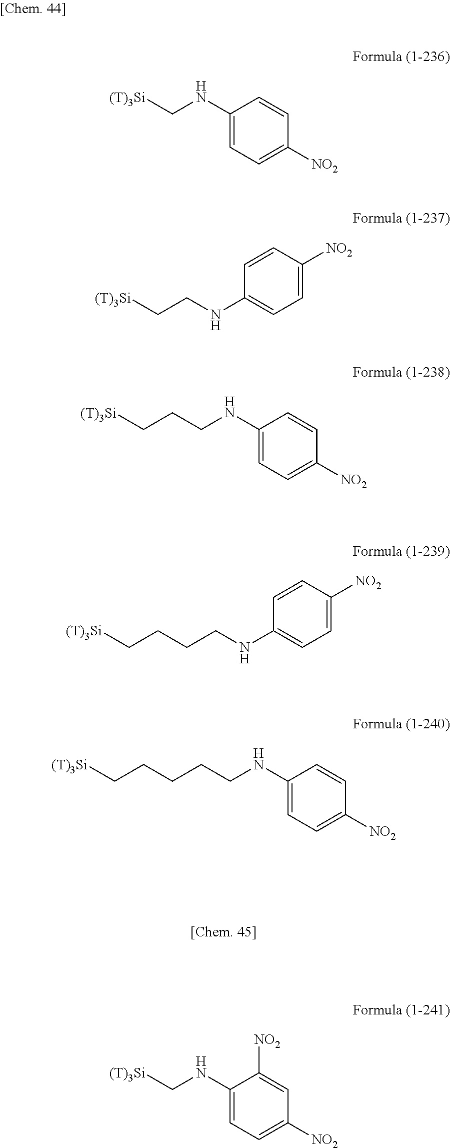

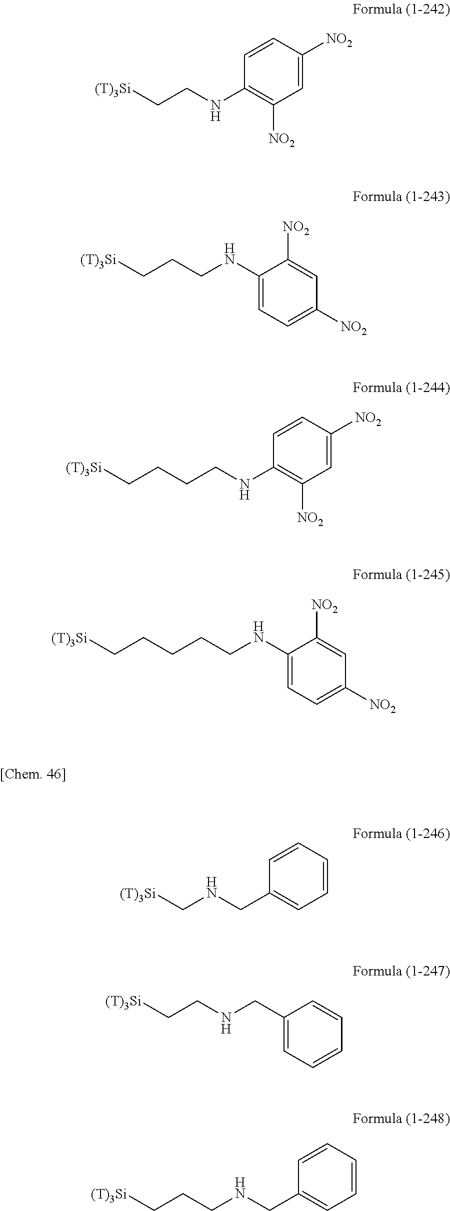

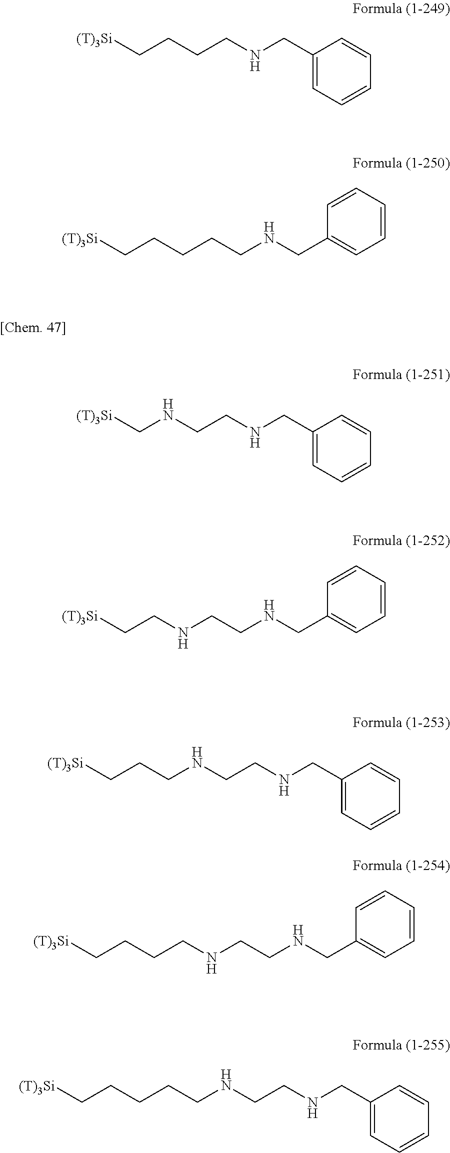

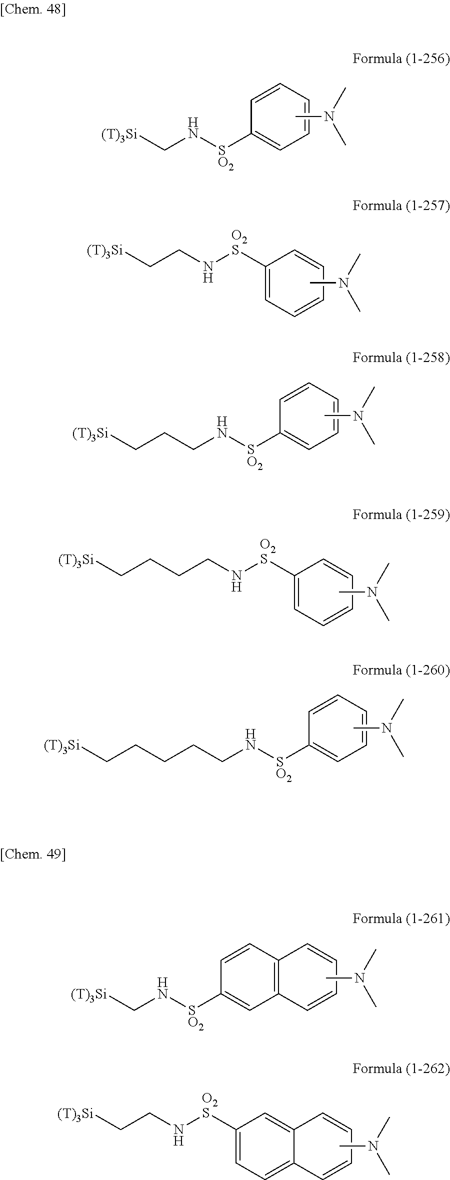

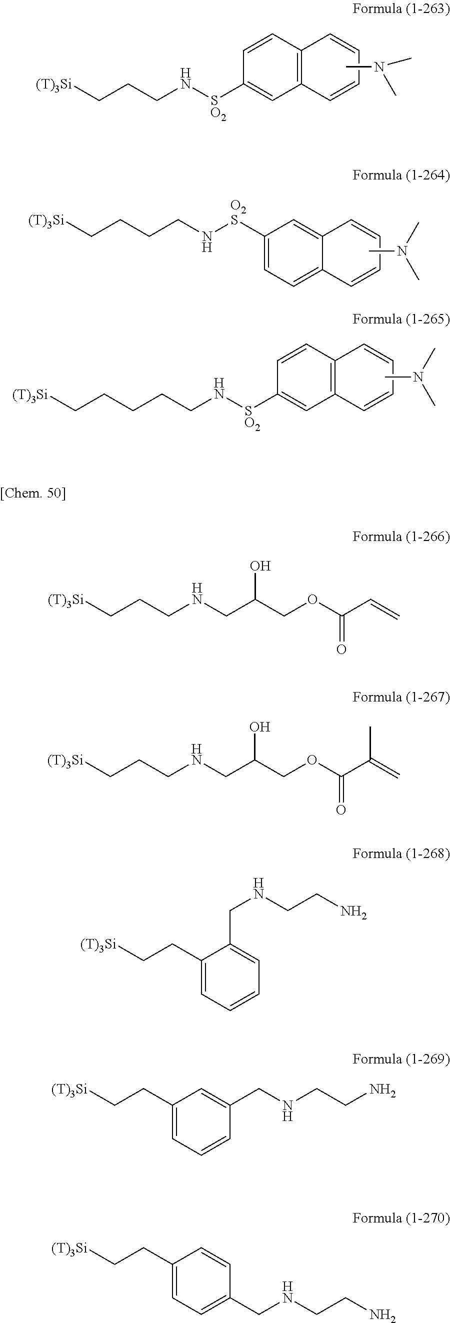

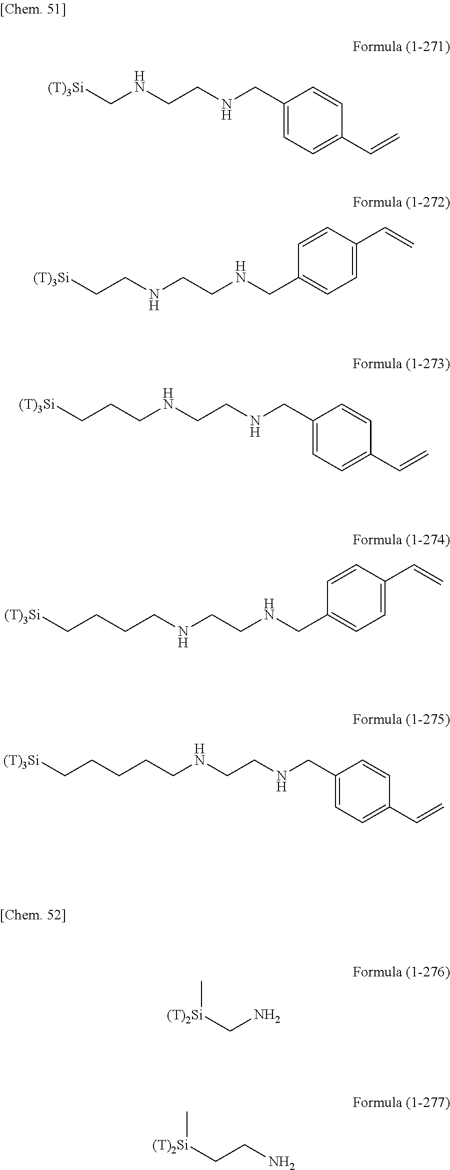

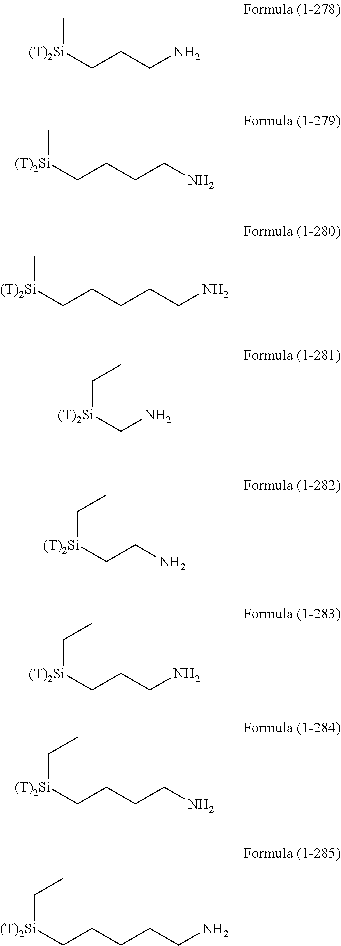

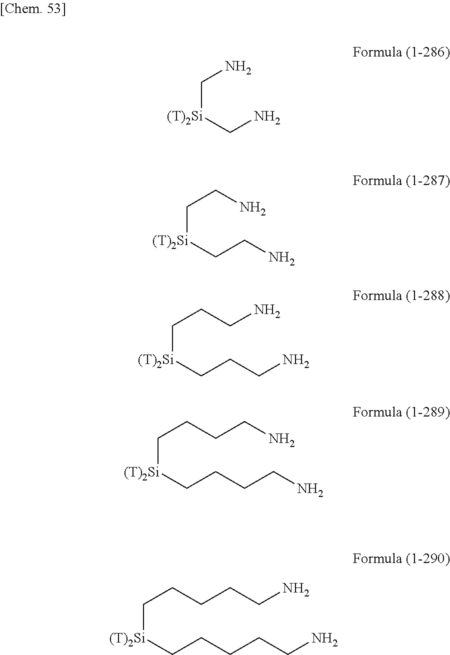

In formulae (1-1) to (1-290), T's independently represent an alkoxy group, an acyloxy group, or a halogen group, for example, and preferably represents a methoxy group or an ethoxy group.

Examples of the polysiloxane [A] include a hydrolysis condensate of a hydrolyzable silane including a hydrolyzable silane represented by the following formula (2) in addition to the hydrolyzable silane represented by formula (1) or in place of the hydrolyzable silane represented by formula (1).

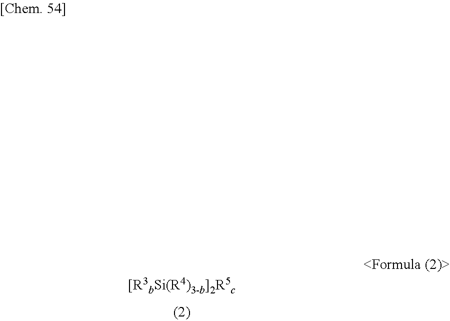

In formula (2), R³'s are groups bonded to a silicon atom, and each independently represent an alkyl group which may be substituted, an aryl group which may be substituted, an aralkyl group which may be substituted, a halogenated alkyl group which may be substituted, a halogenated aryl group which may be substituted, a halogenated aralkyl group which may be substituted, an alkoxyalkyl group which may be substituted, an alkoxyaryl group which may be substituted, an alkoxyaralkyl group which may be substituted, or an alkenyl group which may be substituted, or represent an organic group having an epoxy group, an organic group having an acryloyl group, an organic group having a methacryloyl group, an organic group having a mercapto group, an organic group having an amino group, an organic group having an alkoxy group, an organic group having a sulfonyl group, or an organic group having a cyano group, or a combination of two or more thereof.

R⁴'s are groups or atoms bonded to a silicon atom, and each independently represent an alkoxy group, an aralkyloxy group, an acyloxy group, or a halogen atom.

R⁵'s are groups bonded to a silicon atom, and each independently represent an alkylene group or an arylene group.

b represents 0 or 1, and c represents 0 or 1.

Specific examples of each group in R³ and a suitable number of carbon atoms thereof can include the groups and the number of carbon atoms described above for R¹.

Specific examples of each group and atom in R⁴ and a suitable number of carbon atoms thereof can include the groups and the atoms and the number of carbon atoms described above for R².

Specific examples of the alkylene group in R⁵ include alkylene groups such as linear alkylene groups such as a methylene group, an ethylene group, a trimethylene group, a tetramethylene group, a pentamethylene group, a hexamethylene group, a heptamethylene group, an octamethylene group, a nonamethylene group, and a decamethylene group, branched alkylene groups such as a 1-methyltrimethylene group, a 2-methyltrimethylene group, a 1,1-dimethylethylene group, a 1-methyltetramethylene group, a 2-methyltetramethylene group, a 1,1-dimethyltrimethylene group, a 1,2-dimethyltrimethylene group, a 2,2-dimethyltrimethylene group, and a 1-ethyltrimethylene group, and alkanetriyl groups such as a methanetriyl group, an ethane-1,1,2-triyl group, an ethane-1,2,2-triyl group, an ethane-2,2,2-triyl group, a propane-1,1,1-triyl group, a propane-1,1,2-triyl group, a propane-1,2,3-triyl group, a propane-1,2,2-triyl group, a propane-1,1,3-triyl group, a butane-1,1,1-triyl group, a butane-1,1,2-triyl group, a butane-1,1,3-triyl group, a butane-1,2,3-triyl group, a butane-1,2,4-triyl group, a butane-1,2,2-triyl group, a butane-2,2,3-triyl group, a 2-methylpropane-1,1,1-triyl group, a 2-methylpropane-1,1,2-triyl group, and a 2-methylpropane-1,1,3-triyl group, but are not limited thereto.

Specific examples of the arylene group in R⁵ include a 1,2-phenylene group, a 1,3-phenylene group, and a 1,4-phenylene group; groups derived by removing two hydrogen atoms on the aromatic ring of a fused ring aromatic hydrocarbon compound such as a 1,5-naphthalenediyl group, a 1,8-naphthalenediyl group, a 2,6-naphthalenediyl group, a 2,7-naphthalenediyl group, a 1,2-anthracenediyl group, a 1,3-anthracenediyl group, a 1,4-anthracenediyl group, a 1,5-anthracenediyl group, a 1,6-anthracenediyl group, a 1,7-anthracenediyl group, a 1,8-anthracenediyl group, a 2,3-anthracenediyl group, a 2,6-anthracenediyl group, a 2,7-anthracenediyl group, a 2,9-anthracenediyl group, a 2,10-anthracenediyl group, and a 9,10-anthracenediyl group; and a group derived by removing two hydrogen atoms on the aromatic rings of a ring-linked aromatic hydrocarbon compound such as a 4,4′-biphenyldiyl group and a 4,4″-p-terphenyldiyl group, but are not limited thereto.

b is preferably 0.

c is preferably 1.

Specific examples of the hydrolyzable silane represented by formula (2) include methylene bistrimethoxysilane, methylene bistrichlorosilane, methylene bistriacetoxysilane, ethylene bistriethoxysilane, ethylene bistrichlorosilane, ethylene bistriacetoxysilane, propylene bistriethoxysilane, butylene bistrimethoxysilane, phenylene bistrimethoxysilane, phenylene bistriethoxysilane, phenylene bismethyldiethoxysilane, phenylene bismethyldimethoxysilane, naphthylene bistrimethoxysilane, bistrimethoxydisilane, bistriethoxydisilane, bisethyldiethoxydisilane, and bismethyldimethoxydisilane, but are not limited thereto.

Examples of the polysiloxane [A] include a hydrolysis condensate of a hydrolyzable silane including other hydrolyzable silanes listed below, in addition to the hydrolyzable silane represented by formula (1) and/or the hydrolyzable silane represented by formula (2).

Examples of other hydrolyzable silanes include a silane compound having an onium group in the molecule, a silane compound having a sulfone group, a silane compound having a sulfonamide group, and a silane compound having a cyclic urea skeleton in the molecule, but are not limited thereto.

### <<Silane Compound (Hydrolyzable Organosilane) Having Onium Group in Molecule>>

The silane compound having an onium group in the molecule is expected to be able to effectively and efficiently promote the crosslinking reaction of the hydrolyzable silane.

A preferred example of the silane compound having an onium group in the molecule is represented by formula (3).

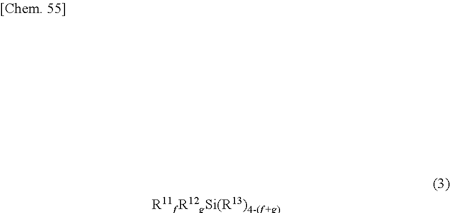

R¹¹ is a group bonded to a silicon atom, and represents an onium group or an organic group having the onium group.

R¹²'s are groups bonded to a silicon atom, and each independently represent an alkyl group which may be substituted, an aryl group which may be substituted, an aralkyl group which may be substituted, a halogenated alkyl group which may be substituted, a halogenated aryl group which may be substituted, a halogenated aralkyl group which may be substituted, an alkoxyalkyl group which may be substituted, an alkoxyaryl group which may be substituted, an alkoxyaralkyl group which may be substituted, or an alkenyl group which may be substituted, or represent an organic group having an epoxy group, an organic group having an acryloyl group, an organic group having a methacryloyl group, an organic group having a mercapto group, an organic group having an amino group, or an organic group having a cyano group, or a combination of two or more thereof.

R¹³'s are groups or atoms bonded to a silicon atom, and each independently represent an alkoxy group, an aralkyloxy group, an acyloxy group, or a halogen atom.

f represents 1 or 2, g represents 0 or 1, and 1≤f+g≤2 is satisfied.

Specific examples of the alkyl group, the aryl group, the aralkyl group, the halogenated alkyl group, the halogenated aryl group, the halogenated aralkyl group, the alkoxyalkyl group, the alkoxyaryl group, the alkoxyaralkyl group, the alkenyl group, the organic group having an epoxy group, the organic group having an acryloyl group, the organic group having a methacryloyl group, the organic group having a mercapto group, the organic group having an amino group, the organic group having a cyano group, the alkoxy group, the aralkyloxy group, the acyloxy group, and the halogen atom, and specific examples of the substituent in the alkyl group, the aryl group, the aralkyl group, the halogenated alkyl group, the halogenated aryl group, the halogenated aralkyl group, the alkoxyalkyl group, the alkoxyaryl group, the alkoxyaralkyl group, and the alkenyl group, and a suitable number of carbon atoms thereof include those described above for R¹ with respect to R¹², and those described above for R² with respect to R¹³.

More specifically, specific examples of the onium group include a cyclic ammonium group and a chain ammonium group, and a tertiary ammonium group or a quaternary ammonium group is preferable.

That is, suitable specific examples of the onium group or the organic group having the onium group include a cyclic ammonium group, a chain ammonium group, or an organic group having at least one of the cyclic ammonium group and the chain ammonium group, and a tertiary ammonium group, a quaternary ammonium group, or an organic group having at least one of the tertiary ammonium group and the quaternary ammonium group is preferable.

When the onium group is a cyclic ammonium group, a nitrogen atom forming the ammonium group also serves as an atom forming the ring. At this time, a nitrogen atom and a silicon atom forming the ring may be bonded directly or via a divalent linking group, or a carbon atom and a silicon atom forming the ring may be bonded directly or via a divalent linking group.

In an example of a preferred embodiment, R¹¹ which is a group bonded to a silicon atom is a heteroaromatic cyclic ammonium group represented by the following formula (S1).

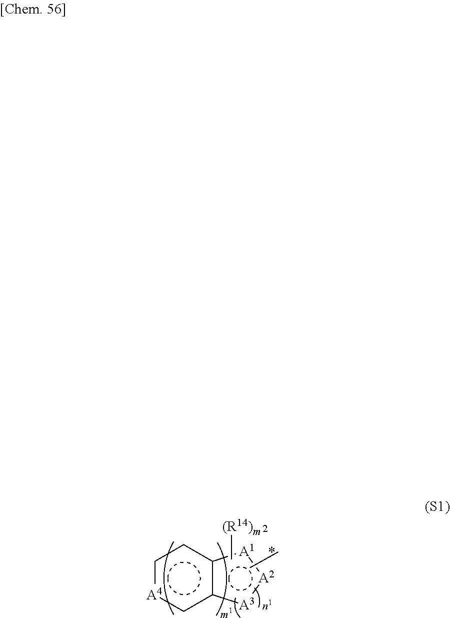

In formula (S1), A¹, A², A³, and A⁴ each independently represent a group represented by any one of the following formulae (J1) to (J3), and at least one of A¹ to A⁴ is a group represented by the following formula (J2), and it is determined whether a bond between each of A¹ to A⁴ and an atom adjacent to each of A¹ to A⁴ and forming the ring together is a single bond or a double bond such that the ring to be formed exhibits aromaticity according to which of A¹ to A⁴ the silicon atom in formula (3) is bonded. * represents a bond.

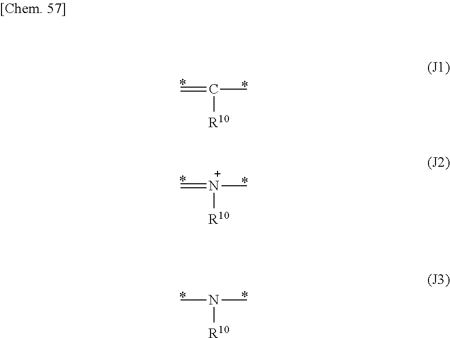

In formulae (J1) to (J3), R¹⁰'s each independently represent a single bond, a hydrogen atom, an alkyl group, an aryl group, an aralkyl group, a halogenated alkyl group, a halogenated aryl group, a halogenated aralkyl group, or an alkenyl group, and specific examples of the alkyl group, the aryl group, the aralkyl group, the halogenated alkyl group, the halogenated aryl group, the halogenated aralkyl group, and the alkenyl group, and a suitable number of carbon atoms thereof include the same ones as described above. * represents a bond.

In formula (S1), R¹⁴'s each independently represent an alkyl group, an aryl group, an aralkyl group, a halogenated alkyl group, a halogenated aryl group, a halogenated aralkyl group, an alkenyl group, or a hydroxy group, and when there are two or more R¹⁴'s, the two R¹⁴'s may be bonded to each other to form a ring, and the ring formed by the two R¹⁴'s may have a bridged ring structure, and in such a case, the cyclic ammonium group has an adamantane ring, a norbornene ring, a spiro ring, or the like.

Specific examples of such an alkyl group, an aryl group, an aralkyl group, a halogenated alkyl group, a halogenated aryl group, a halogenated aralkyl group, and an alkenyl group, and a suitable number of carbon atoms thereof include the same ones as described above.

In formula (S1), n¹ is an integer of 1 to 8, m¹ is 0 or 1, and m² is 0 or a positive integer from 1 to the maximum substitutable number of monocyclic or polycyclic rings.

When m¹ is 0, a (4+n¹)-membered ring containing A¹ to A⁴ is formed. That is, a 5-membered ring is formed when n¹ is 1, a 6-membered ring is formed when n¹ is 2, a 7-membered ring is formed when n¹ is 3, an 8-membered ring is formed when n¹ is 4, a 9-membered ring is formed when n¹ is 5, a 10-membered ring is formed when n¹ is 6, a 11-membered ring is formed when n¹ is 7, and a 12-membered ring is formed when n¹ is 8.

When m¹ is 1, a fused ring in which a (4+n¹)-membered ring containing A¹ to A³ and a 6-membered ring containing A⁴ are fused is formed.

A¹ to A⁴ may or may not have a hydrogen atom on the atom forming the ring depending on which of the formulae (J1) to (J3) they are, but when A¹ to A⁴ have a hydrogen atom on the atom forming the ring, the hydrogen atom may be replaced with R¹⁴. R¹⁴ may be substituted for a ring-forming atom other than the ring-forming atom in A¹ to A⁴. Under such circumstances, as described above, m² is 0 or is selected from integers from 1 to the maximum substitutable number of monocyclic or polycyclic rings.

The bond of the heteroaromatic cyclic ammonium group represented by formula (S1) is present at any carbon atom or nitrogen atom present in such a single ring or a condensed ring, and is directly bonded to a silicon atom, or a linking group is bonded to form an organic group having cyclic ammonium, which is bonded to a silicon atom.

Examples of such a linking group include an alkylene group, an arylene group, and an alkenylene group, but are not limited thereto.

Specific examples of the alkylene group and the arylene group and a suitable number of carbon atoms thereof include the same ones as described above.

The alkenylene group is a divalent group derived by further removing one hydrogen atom from the alkenyl group, and specific examples of such an alkenyl group include the same groups as described above. The number of carbon atoms in the alkenylene group is not particularly limited, but is preferably 40 or less, more preferably 30 or less, and still more preferably 20 or less.

Specific examples thereof include vinylene, 1-methylvinylene, propenylene, 1-butenylene, 2-butenylene, 1-pentenylene, and 2-pentenylene groups, but are not limited thereto.

Specific examples of the silane compound (hydrolyzable organosilane) represented by formula (3) having a heteroaromatic cyclic ammonium group represented by formula (S1) include silanes represented by the following formulae (I-1) to (I-50), but are not limited thereto.

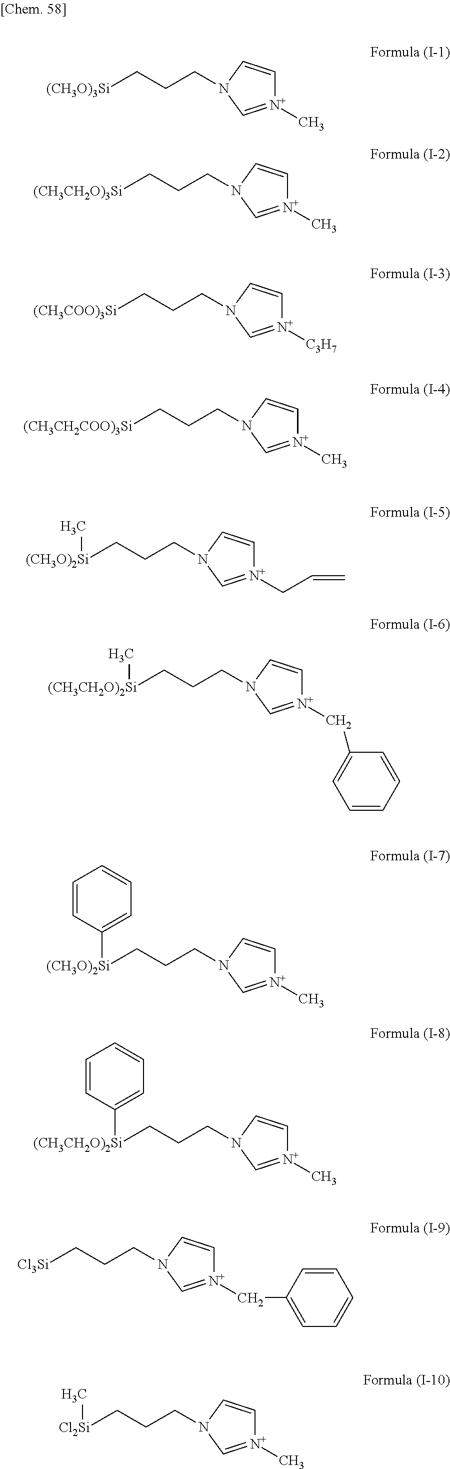

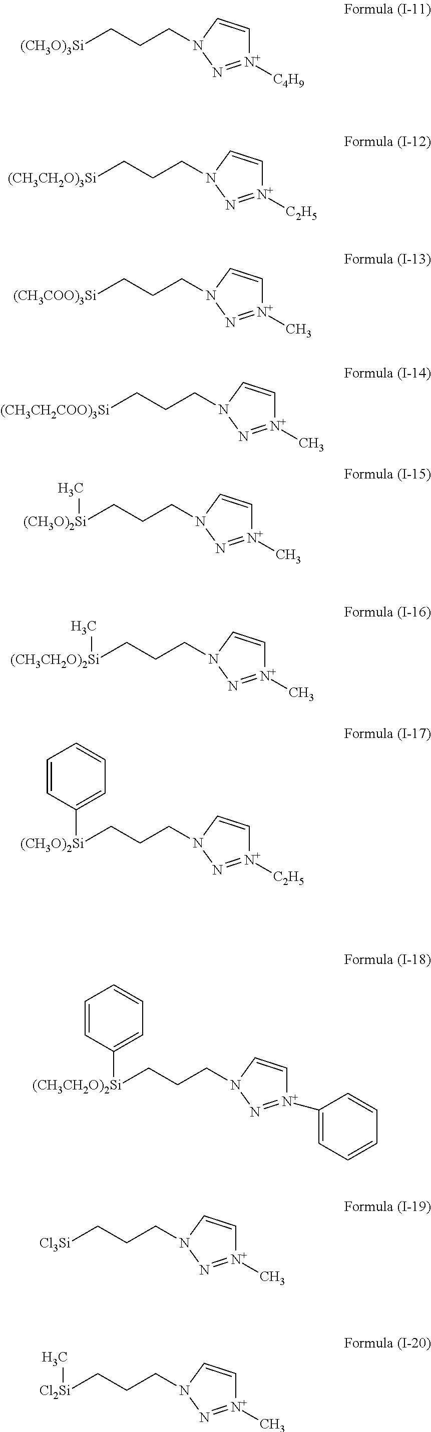

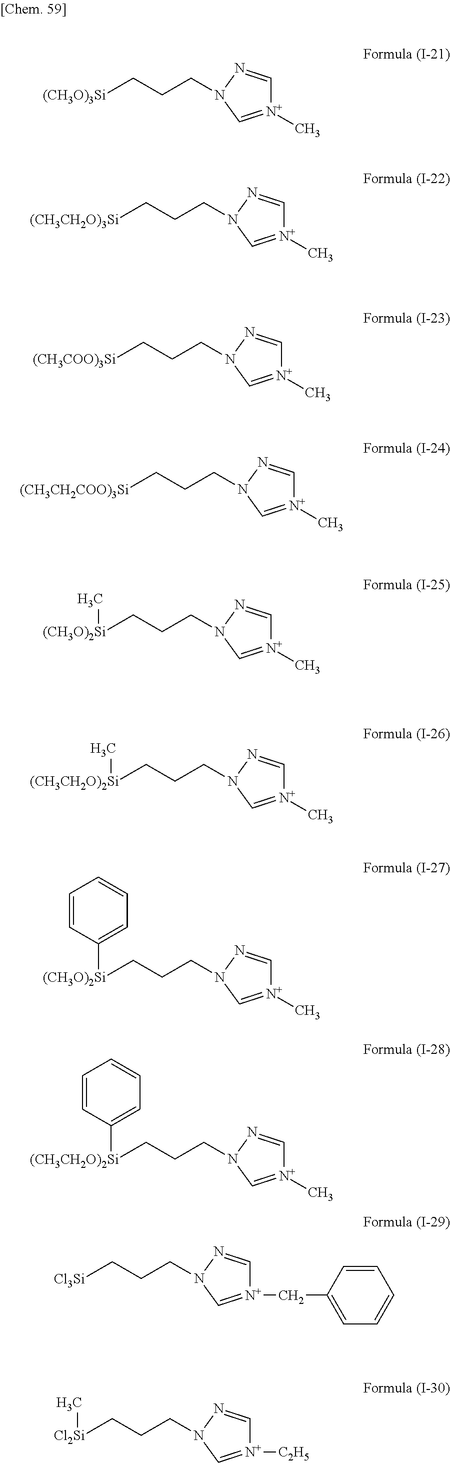

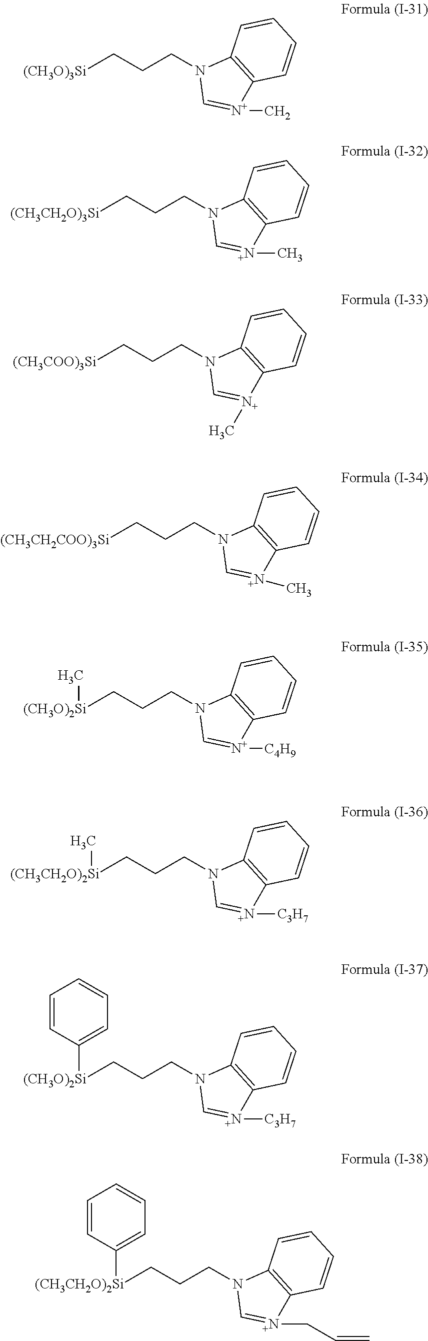

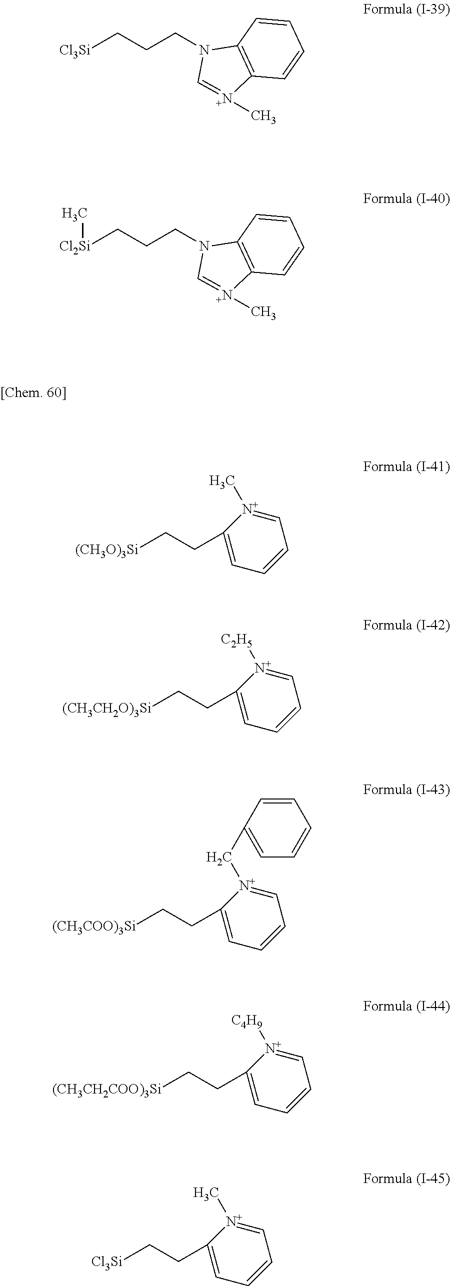

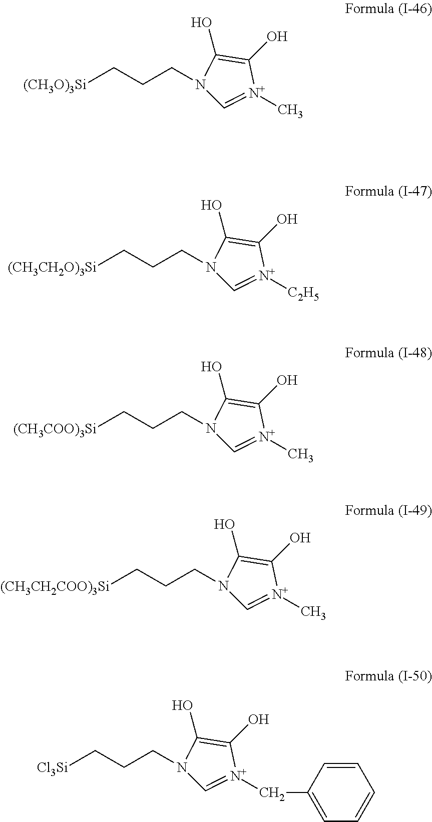

In another example, R¹¹ that is a group bonded to a silicon atom in formula (3) can be a heteroaliphatic cyclic ammonium group represented by the following formula (S2).

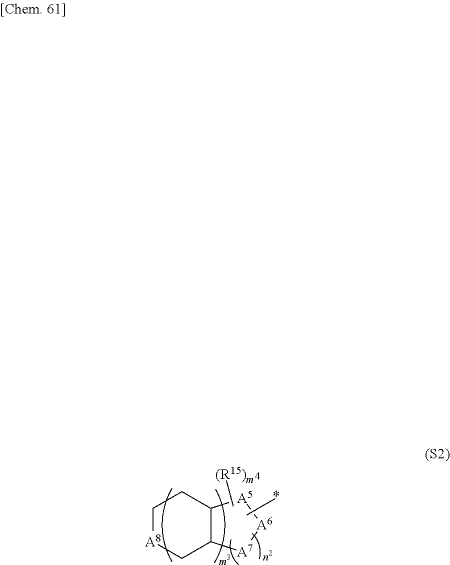

In formula (S2), A⁵, A⁶, A⁷, and A⁸ each independently represent a group represented by any one of the following formulae (J4) to (J6), and at least one of A⁵ to A⁸ represents a group represented by the following formula (J5). It is determined whether a bond between each of A⁵ to A⁸ and an atom adjacent to each of A⁵ to A⁸ and forming the ring together is a single bond or a double bond such that the ring to be formed exhibits non-aromaticity according to which of A⁵ to A⁸ the silicon atom in formula (3) is bonded. * represents a bond.

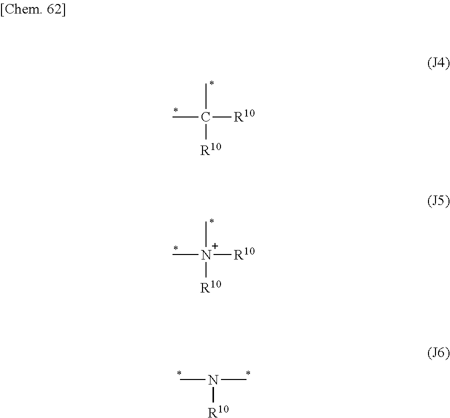

In formulae (J4) to (J6), R¹⁰'s each independently represent a single bond, a hydrogen atom, an alkyl group, an aryl group, an aralkyl group, a halogenated alkyl group, a halogenated aryl group, a halogenated aralkyl group or an alkenyl group, and specific examples of the alkyl group, the aryl group, the aralkyl group, the halogenated alkyl group, the halogenated aryl group, the halogenated aralkyl group, and the alkenyl group, and a suitable number of carbon atoms thereof include the same ones as described above. * represents a bond.

In formula (S2), R¹⁵'s each independently represent an alkyl group, an aryl group, an aralkyl group, a halogenated alkyl group, a halogenated aryl group, a halogenated aralkyl group, an alkenyl group, or a hydroxy group, and when there are two or more R¹⁵'s, the two R¹⁵'s may be bonded to each other to form a ring, and the ring formed by the two R¹⁵'s may have a bridged ring structure, and in such a case, the cyclic ammonium group has an adamantane ring, a norbornene ring, a spiro ring, or the like.

Specific examples of the alkyl group, the aryl group, the aralkyl group, the halogenated alkyl group, the halogenated aryl group, the halogenated aralkyl group, and the alkenyl group, and a suitable number of carbon atoms thereof include the same ones as described above.

In formula (S2), n² is an integer of 1 to 8, m³ is 0 or 1, and m⁴ is 0 or a positive integer from 1 to the maximum substitutable number of monocyclic or polycyclic rings.

When m³ is 0, a (4+n²)-membered ring containing A⁵ to A⁸ is formed. That is, a 5-membered ring is formed when n² is 1, a 6-membered ring is formed when n² is 2, a 7-membered ring is formed when n² is 3, an 8-membered ring is formed when n² is 4, a 9-membered ring is formed when n² is 5, a 10-membered ring is formed when n² is 6, a 11-membered ring is formed when n² is 7, and a 12-membered ring is formed when n² is 8.

When m³ is 1, a fused ring in which a (4+n²)-membered ring containing A⁵ to A⁷ and a 6-membered ring containing A⁸ are fused is formed.

A⁵ to A⁸ may or may not have a hydrogen atom on the atom forming the ring depending on which of the formulae (J4) to (J6) they are, but when A⁵ to A⁸ have a hydrogen atom on the atom forming the ring, the hydrogen atom may be replaced with R¹⁵. R¹⁵ may be substituted for a ring-forming atom other than the ring-forming atom in A⁵ to A⁸.

Under such circumstances, as described above, m⁴ is 0 or is selected from integers from 1 to the maximum substitutable number of monocyclic or polycyclic rings.

The bond of the heteroaliphatic cyclic ammonium group represented by formula (S2) is present at any carbon atom or nitrogen atom present in such a single ring or a condensed ring, and is directly bonded to a silicon atom, or a linking group is bonded to form an organic group having cyclic ammonium, which is bonded to a silicon atom.

Examples of such a linking group include an alkylene group, an arylene group, and an alkenylene group, and specific examples of the alkylene group, the arylene group, and the alkenylene group and a suitable number of carbon atoms thereof include the same ones as described above.

Specific examples of the silane compound (hydrolyzable organosilane) represented by formula (3) having a heteroaliphatic cyclic ammonium group represented by formula (S2) include silanes represented by the following formulae (II-1) to (II-30), but are not limited thereto.

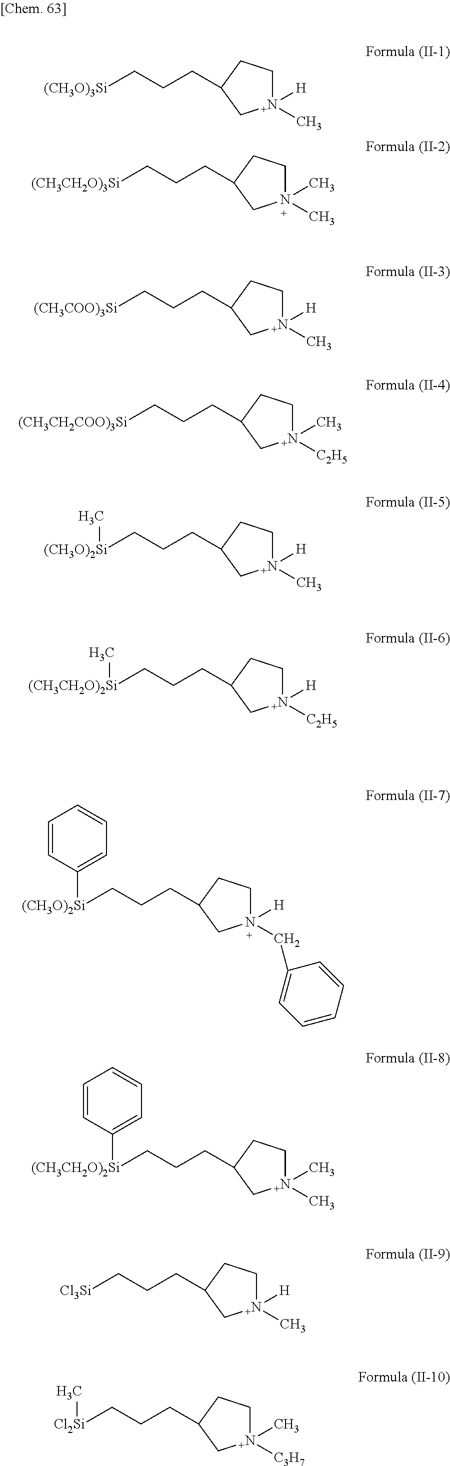

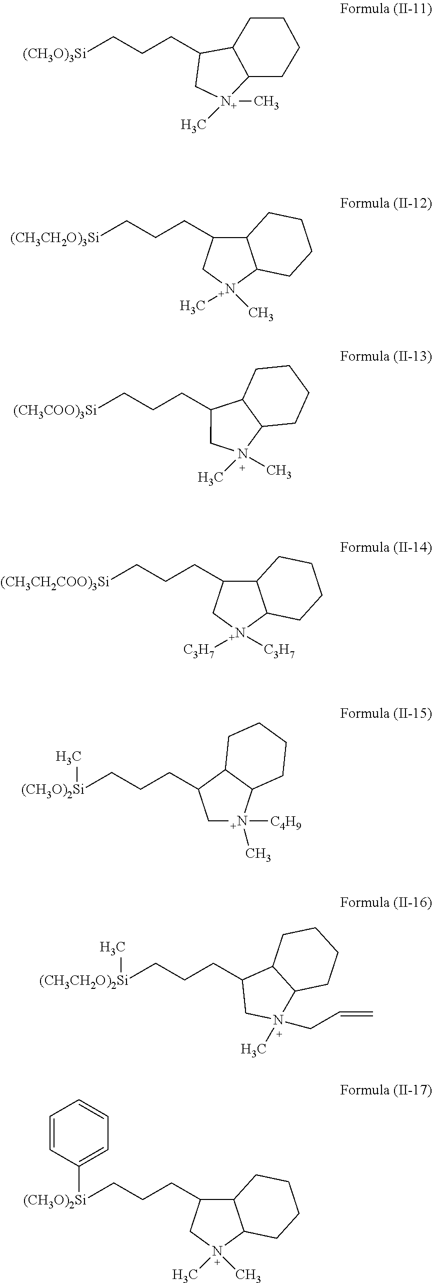

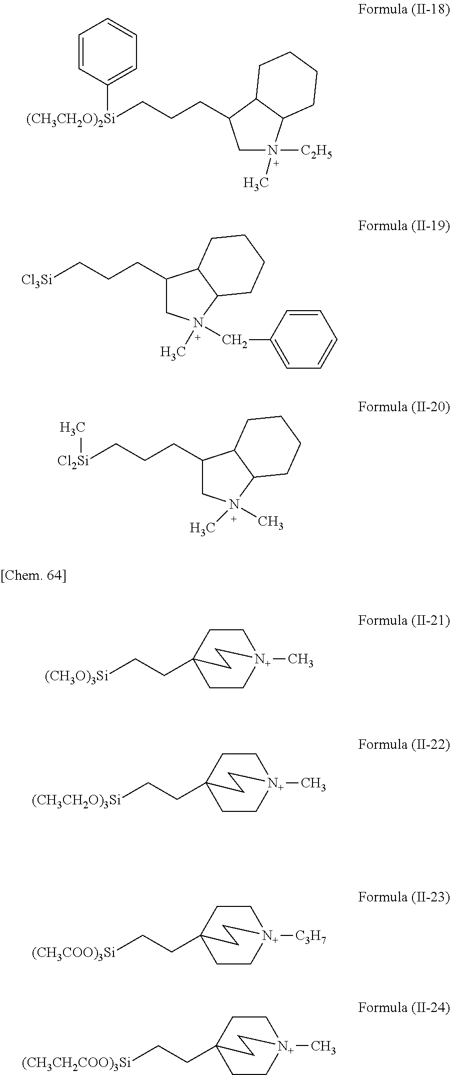

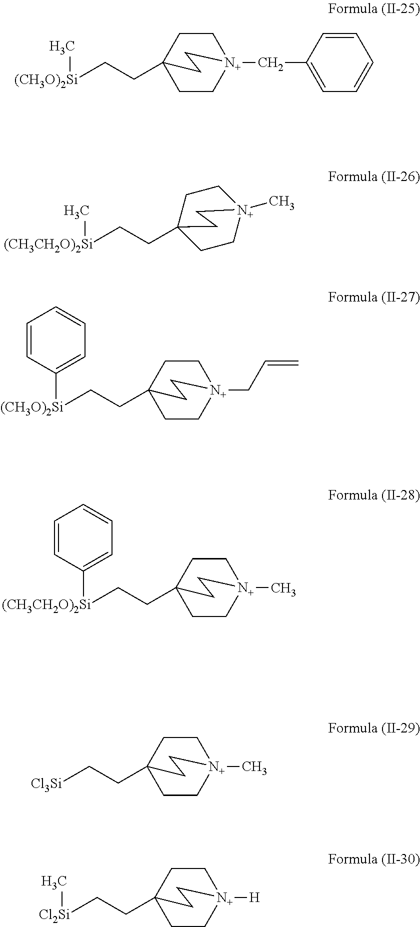

In another example, R¹¹ that is a group bonded to a silicon atom in formula (3) can be a chain ammonium group represented by the following formula (S3).

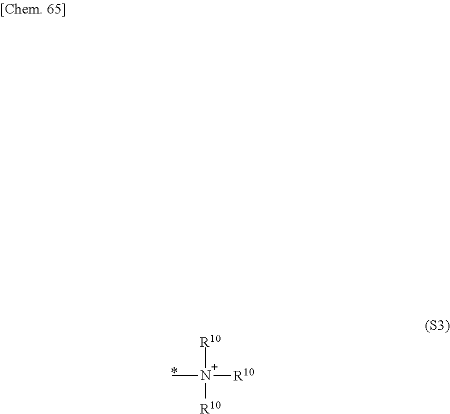

In formula (S3), R¹⁰'s each independently represent a hydrogen atom, an alkyl group, an aryl group, an aralkyl group, a halogenated alkyl group, a halogenated aryl group, a halogenated aralkyl group or an alkenyl group, and specific examples of the alkyl group, the aryl group, the aralkyl group, the halogenated alkyl group, the halogenated aryl group, the halogenated aralkyl group, and the alkenyl group, and a suitable number of carbon atoms thereof include the same ones as described above. * represents a bond.

The chain ammonium group represented by formula (S3) is directly bonded to a silicon atom, or a linking group is bonded to form an organic group having a chain ammonium group, which is bonded to a silicon atom.

Examples of such a linking group include an alkylene group, an arylene group, and an alkenylene group, and specific examples of the alkylene group, the arylene group, and the alkenylene group include the same groups as described above.

Specific examples of the silane compound (hydrolyzable organosilane) represented by formula (3) having a chain ammonium group represented by formula (S3) include silanes represented by the following formulae (III-1) to (III-28), but are not limited thereto.

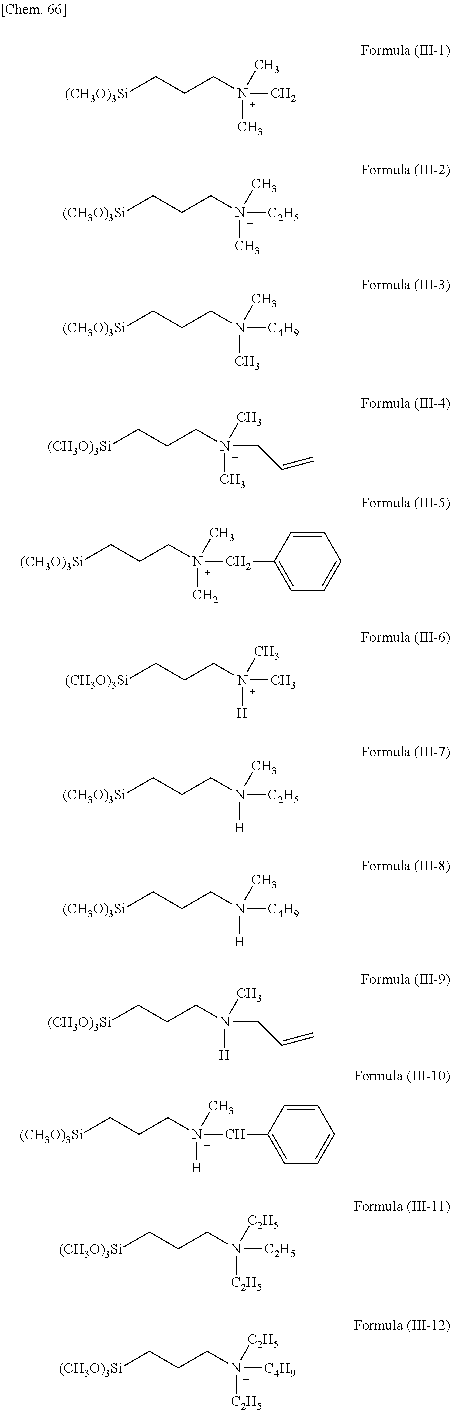

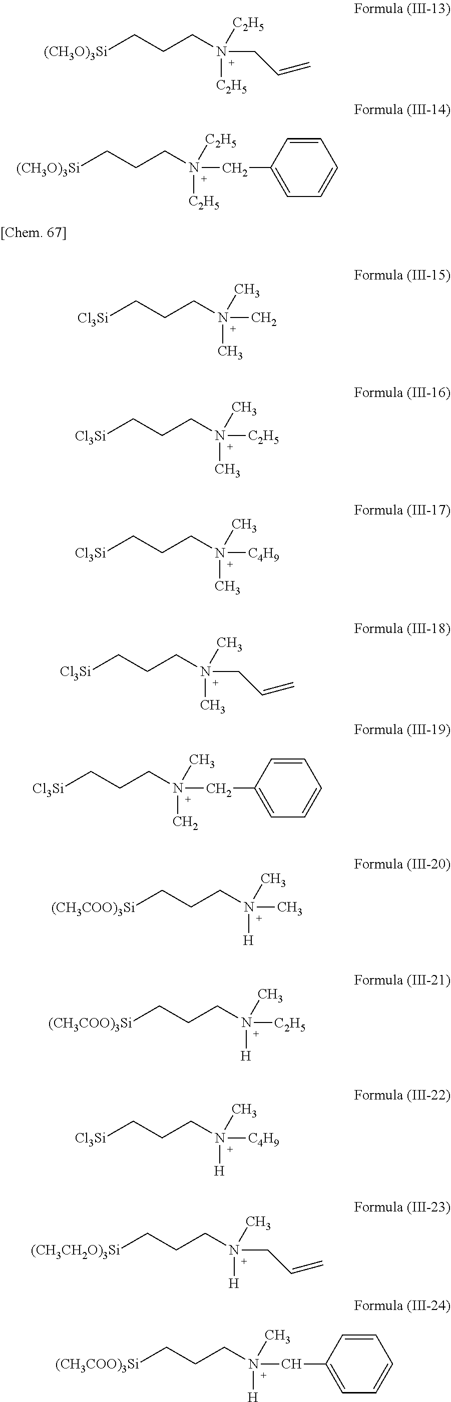

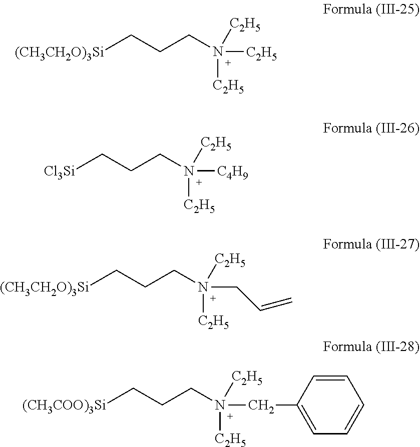

### <<Silane Compound (Hydrolyzable Organosilane) Having Sulfone Group or Sulfonamide Group>>

Examples of the silane compound having a sulfone group and the silane compound having a sulfonamide group include compounds represented by the following formulae (B-1) to (B-36), but are not limited thereto.

In the following formulae, Me represents a methyl group, and Et represents an ethyl group.

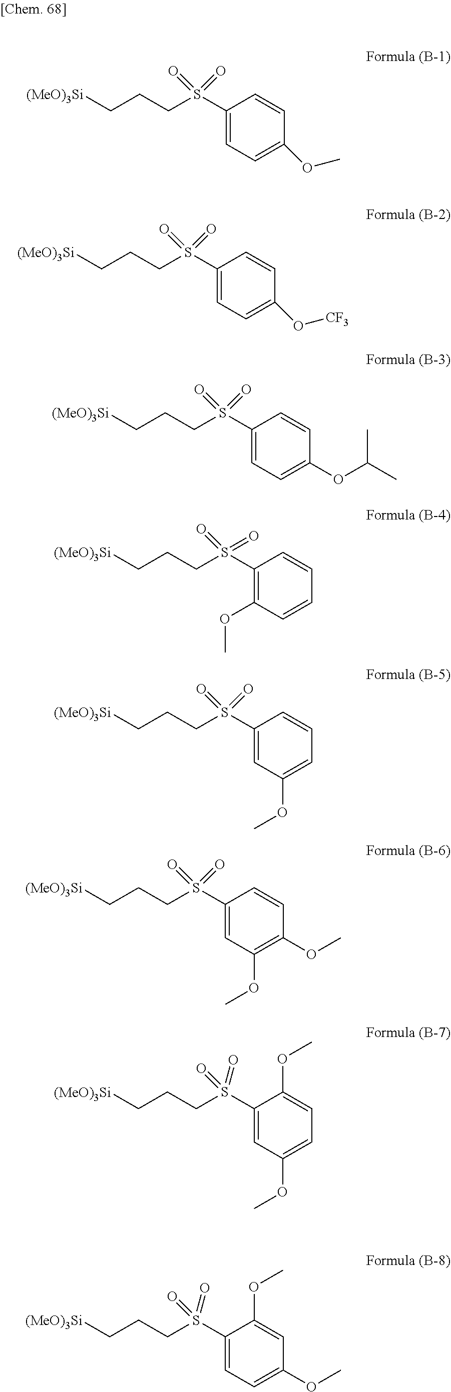

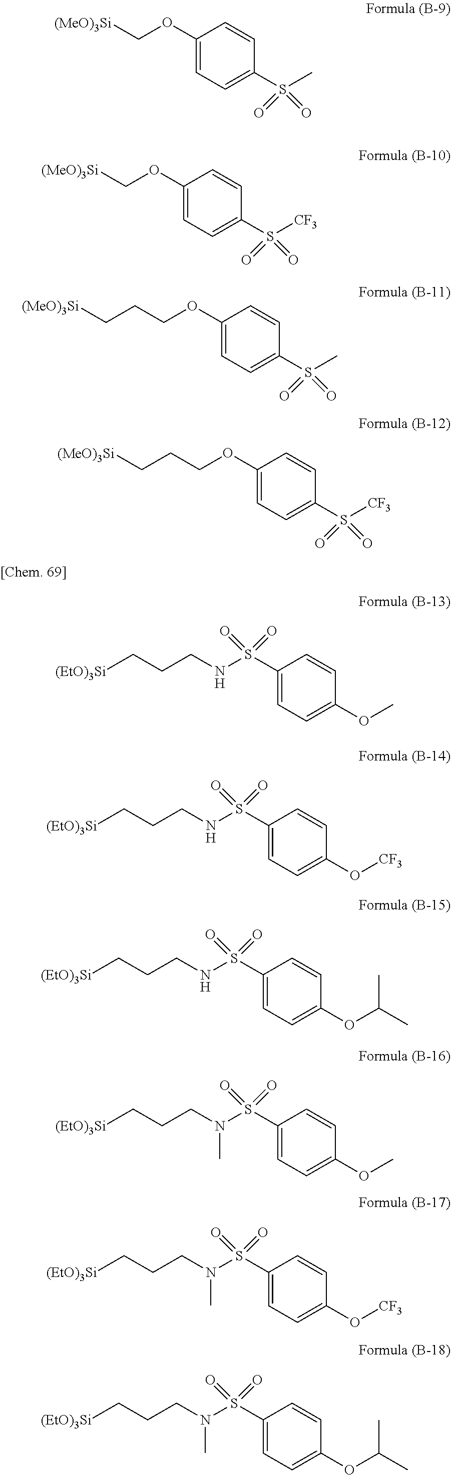

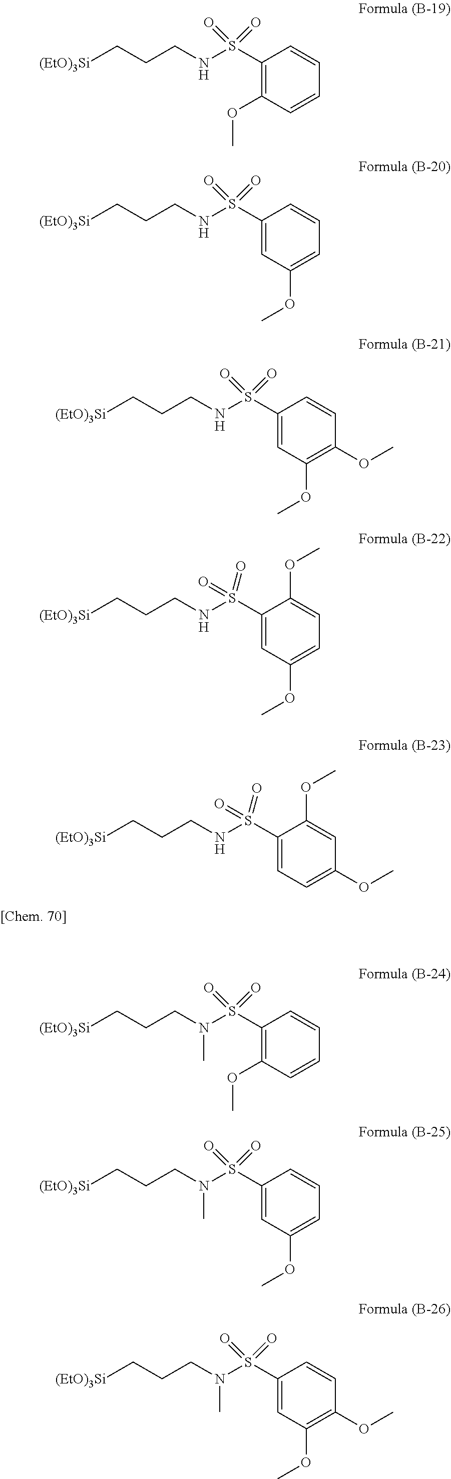

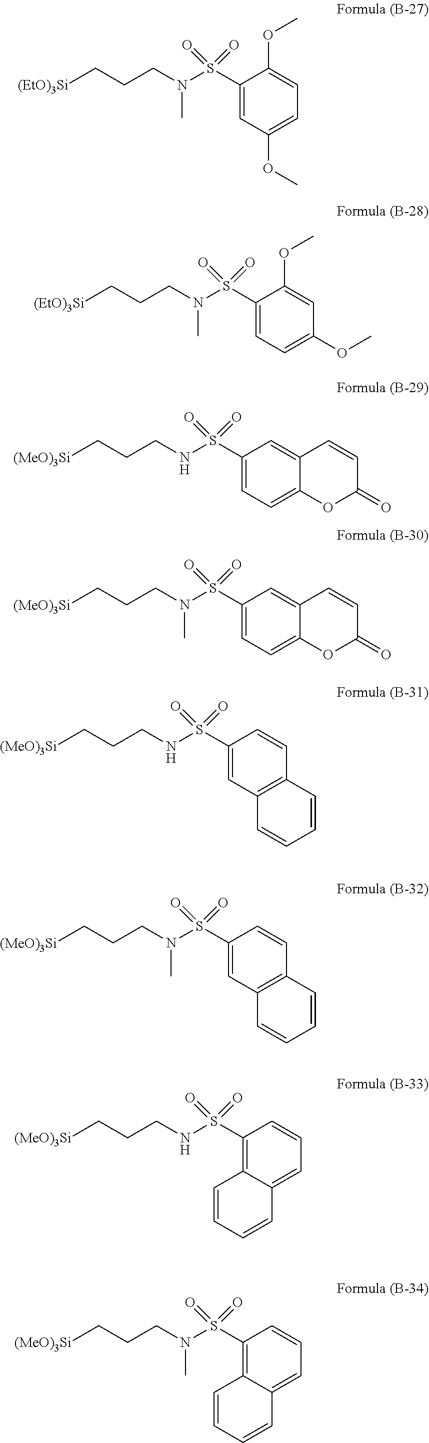

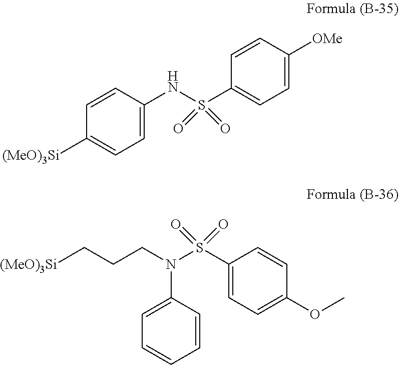

### <<Silane Compound (Hydrolyzable Organosilane) Having Cyclic Urea Skeleton in Molecule>>

Examples of the hydrolyzable organosilane having a cyclic urea skeleton in the molecule include a hydrolyzable organosilane represented by the following formula (4-1).

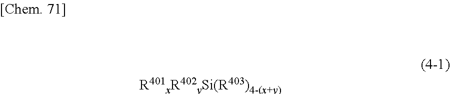

In formula (4-1), R⁴⁰¹'s are groups bonded to a silicon atom, and each independently represent a group represented by the following formula (4-2).

R⁴⁰² is a group bonded to a silicon atom, and represents an alkyl group which may be substituted, an aryl group which may be substituted, an aralkyl group which may be substituted, a halogenated alkyl group which may be substituted, a halogenated aryl group which may be substituted, a halogenated aralkyl group which may be substituted, an alkoxyalkyl group which may be substituted, an alkoxyaryl group which may be substituted, an alkoxyaralkyl group which may be substituted, or an alkenyl group which may be substituted, or represents an organic group having an epoxy group, an organic group having an acryloyl group, an organic group having a methacryloyl group, an organic group having a mercapto group, or an organic group having a cyano group, or a combination of two or more thereof.

R⁴⁰³'s are groups or atoms bonded to a silicon atom, and each independently represent an alkoxy group, an aralkyloxy group, an acyloxy group, or a halogen atom.

x is 1 or 2, y is 0 or 1, and x+y≤2 is satisfied.

Specific examples of the alkyl group, the aryl group, the aralkyl group, the halogenated alkyl group, the halogenated aryl group, the halogenated aralkyl group, the alkoxyalkyl group, the alkoxyaryl group, the alkoxyaralkyl group, the alkenyl group, the organic group having an epoxy group, the organic group having an acryloyl group, the organic group having a methacryloyl group, the organic group having a mercapto group, and the organic group having a cyano group of R⁴⁰², and the alkoxy group, the aralkyloxy group, the acyloxy group, and the halogen atom of R⁴⁰³, and the substituent thereof, a suitable number of carbon atoms thereof, and the like include the same ones as described above for R¹ and R².

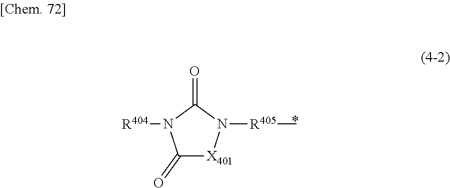

In formula (4-2), R⁴⁰⁴'s each independently represent a hydrogen atom, an alkyl group which may be substituted, an alkenyl group which may be substituted, an organic group having an epoxy group, or an organic group having a sulfonyl group, and R⁴⁰⁵'s each independently represent an alkylene group, a hydroxyalkylene group, a sulfide bond (—S—), an ether bond (—O—), or an ester bond (—CO—O— or —O—CO—). * represents a bond.

Specific examples of the alkyl group which may be substituted, the alkenyl group which may be substituted, and the organic group having an epoxy group of R⁴⁰⁴, and a suitable number of carbon atoms thereof and the like include the same ones as described above for R¹. In addition, the alkyl group which may be substituted of R⁴⁰⁴ is preferably an alkyl group in which a terminal hydrogen atom is substituted with a vinyl group, and specific examples thereof include an allyl group, a 2-vinylethyl group, a 3-vinylpropyl group, and a 4-vinylbutyl group.

The organic group having a sulfonyl group is not particularly limited as long as it contains a sulfonyl group, and examples thereof include an alkylsulfonyl group which may be substituted, an arylsulfonyl group which may be substituted, an aralkylsulfonyl group which may be substituted, a halogenated alkylsulfonyl group which may be substituted, a halogenated arylsulfonyl group which may be substituted, a halogenated aralkylsulfonyl group which may be substituted, an alkoxyalkylsulfonyl group which may be substituted, an alkoxyarylsulfonyl group which may be substituted, an alkoxyaralkylsulfonyl group which may be substituted, and an alkenylsulfonyl group which may be substituted.

Specific examples of the alkyl group, the aryl group, the aralkyl group, the halogenated alkyl group, the halogenated aryl group, the halogenated aralkyl group, the alkoxyalkyl group, the alkoxyaryl group, the alkoxyaralkyl group, and the alkenyl group in these groups, and the substituent thereof, and a suitable number of carbon atoms thereof and the like include the same ones as described above for R¹.

The alkylene group is a divalent group derived by further removing one hydrogen atom from the alkyl group, and may be linear, branched, or cyclic, and specific examples of such an alkylene group include the same ones as described above. The number of carbon atoms in the alkylene group is not particularly limited, but is preferably 40 or less, more preferably 30 or less, still more preferably 20 or less, and even more preferably 10 or less.

The alkylene group of R⁴⁰⁵ may have one or two or more selected from a sulfide bond, an ether bond, and an ester bond at the end or in the middle, preferably in the middle.

Specific examples of the alkylene group include linear alkylene groups such as a methylene group, an ethylene group, a trimethylene group, a tetramethylene group, a pentamethylene group, a hexamethylene group, a heptamethylene group, an octamethylene group, a nonamethylene group, and a decamethylene group, branched alkylene groups such as a methylethylene group, a 1-methyltrimethylene group, a 2-methyltrimethylene group, a 1,1-dimethylethylene group, a 1-methyltetramethylene group, a 2-methyltetramethylene group, a 1,1-dimethyltrimethylene group, a 1,2-dimethyltrimethylene group, a 2,2-dimethyltrimethylene group, and a 1-ethyltrimethylene group, cyclic alkylene groups such as a 1,2-cyclopropanediyl group, a 1,2-cyclobutanediyl group, a 1,3-cyclobutanediyl group, a 1,2-cyclohexanediyl group, and a 1,3-cyclohexanediyl group, and alkylene groups containing an ether group or the like such as —CH₂OCH₂—, —CH₂CH₂OCH₂—, —CH₂CH₂OCH₂CH₂—, —CH₂CH₂CH₂OCH₂CH₂—, —CH₂CH₂OCH₂CH₂CH₂—, —CH₂CH₂CH₂OCH₂CH₂CH₂—, —CH₂SCH₂—, —CH₂CH₂SCH₂—, —CH₂CH₂SCH₂CH₂—, —CH₂CH₂CH₂SCH₂CH₂—, —CH₂CH₂SCH₂CH₂CH₂—, —CH₂CH₂CH₂SCH₂CH₂CH₂—, and —CH₂OCH₂CH₂SCH₂—, but are not limited thereto.

The hydroxyalkylene group is one in which at least one of the hydrogen atoms of the above-mentioned alkylene group is replaced with a hydroxy group, and specific examples thereof include a hydroxymethylene group, a 1-hydroxyethylene group, a 2-hydroxyethylene group, a 1,2-dihydroxyethylene group, a 1-hydroxytrimethylene group, a 2-hydroxytrimethylene group, a 3-hydroxytrimethylene group, a 1-hydroxytetramethylene group, a 2-hydroxytetramethylene group, a 3-hydroxytetramethylene group, a 4-hydroxytetramethylene group, a 1,2-dihydroxytetramethylene group, a 1,3-dihydroxytetramethylene group, a 1,4-dihydroxytetramethylene group, a 2,3-dihydroxytetramethylene group, a 2,4-dihydroxytetramethylene group, and a 4,4-dihydroxytetramethylene group, but are not limited thereto.

In formula (4-2), X₄₀₁'s each independently represent any of the groups represented by the following formulae (4-3) to (4-5), and the carbon atom of the ketone group in the following formulae (4-4) and (4-5) is bonded to the nitrogen atom to which R⁴⁰⁵ in formula (4-2) is bonded.

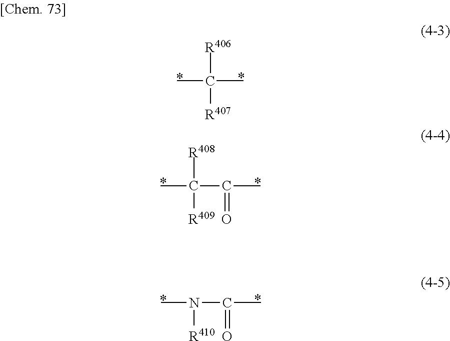

In formulae (4-3) to (4-5), R⁴⁰⁶ to R⁴¹⁰ each independently represent a hydrogen atom, an alkyl group which may be substituted, an alkenyl group which may be substituted, or an organic group having an epoxy group or a sulfonyl group. Specific examples of the alkyl group which may be substituted, the alkenyl group which may be substituted, and the organic group having an epoxy group or a sulfonyl group, and a suitable number of carbon atoms thereof and the like include the same ones as described above for R¹. Specific examples of the organic group having a sulfonyl group, and a suitable number of carbon atoms thereof and the like include the same ones as described above for R⁴⁰⁴. * represents a bond.

Among them, from the viewpoint of realizing excellent lithographic characteristics with good reproducibility, X₄₀₁ is preferably a group represented by formula (4-5).

From the viewpoint of realizing excellent lithographic characteristics with good reproducibility, at least one of R⁴⁰⁴ and R⁴⁰⁶ to R⁴¹⁰ is preferably an alkyl group in which a terminal hydrogen atom is substituted with a vinyl group.

As the hydrolyzable organosilane represented by formula (4-1), a commercially available product may be used, and the hydrolyzable organosilane can also be synthesized by a known method described in WO 2011/102470 A and the like.

Hereinafter, specific examples of the hydrolyzable organosilane represented by formula (4-1) include silanes represented by the following formulae (4-1-1) to (4-1-29), but are not limited thereto.

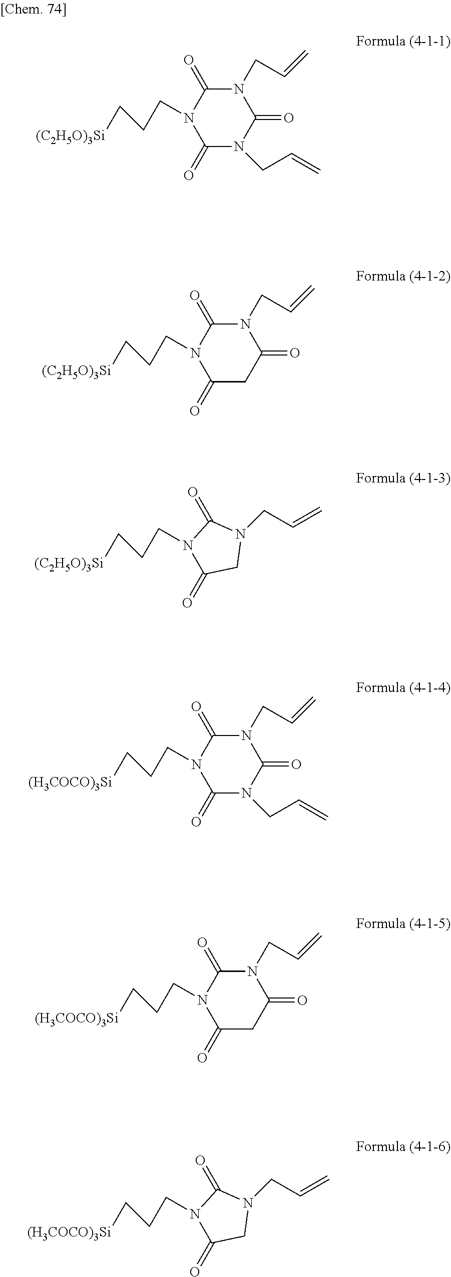

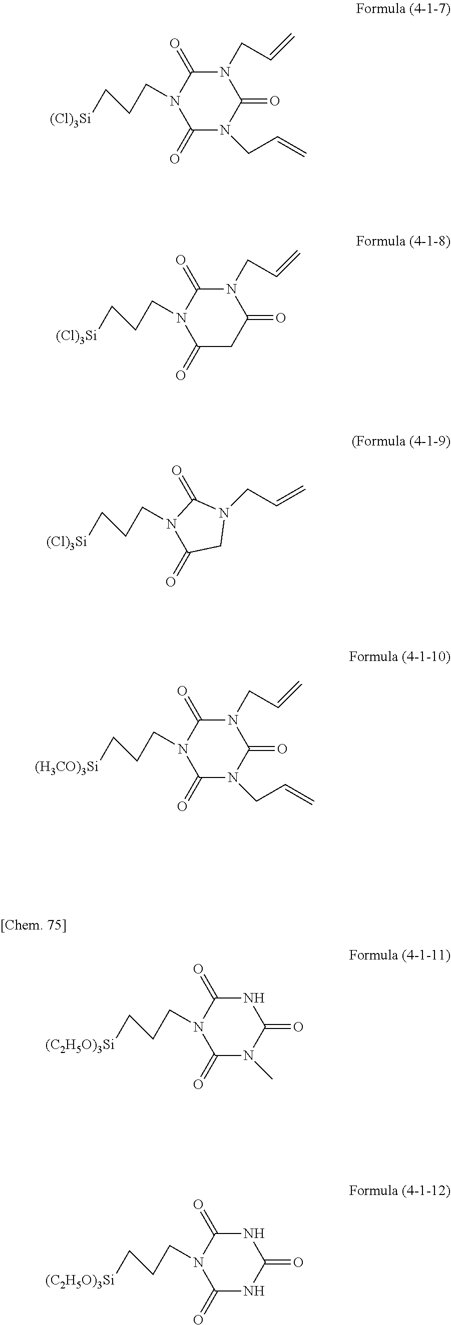

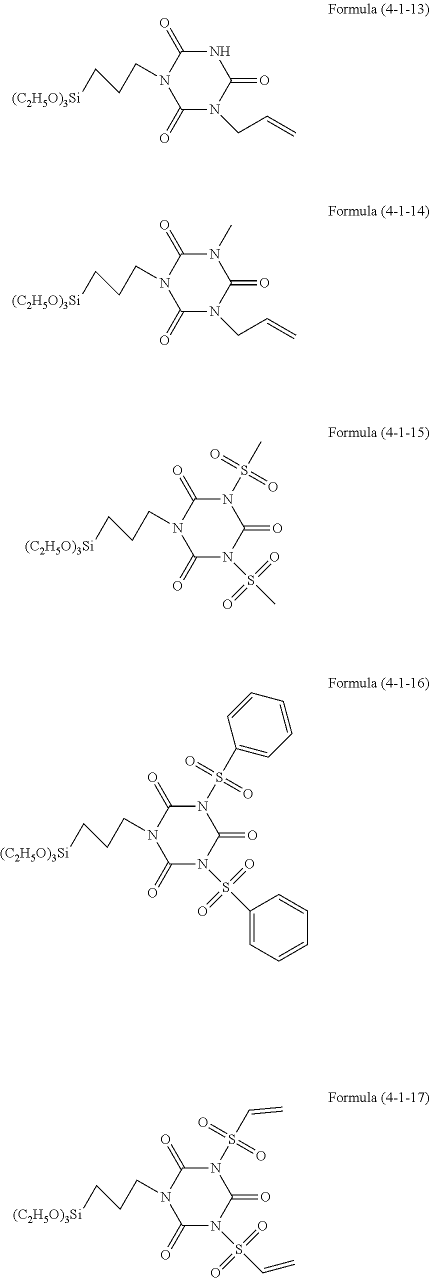

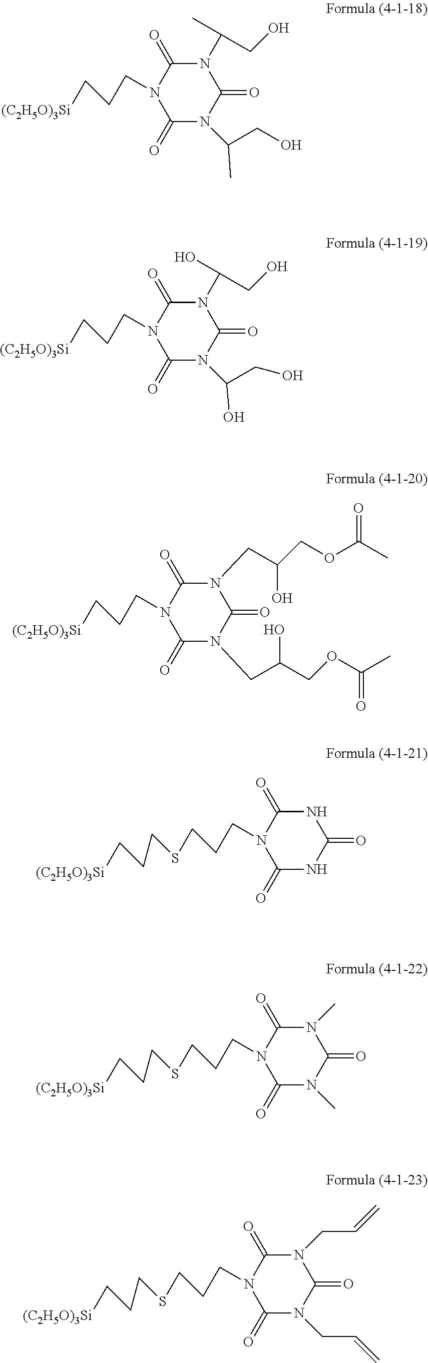

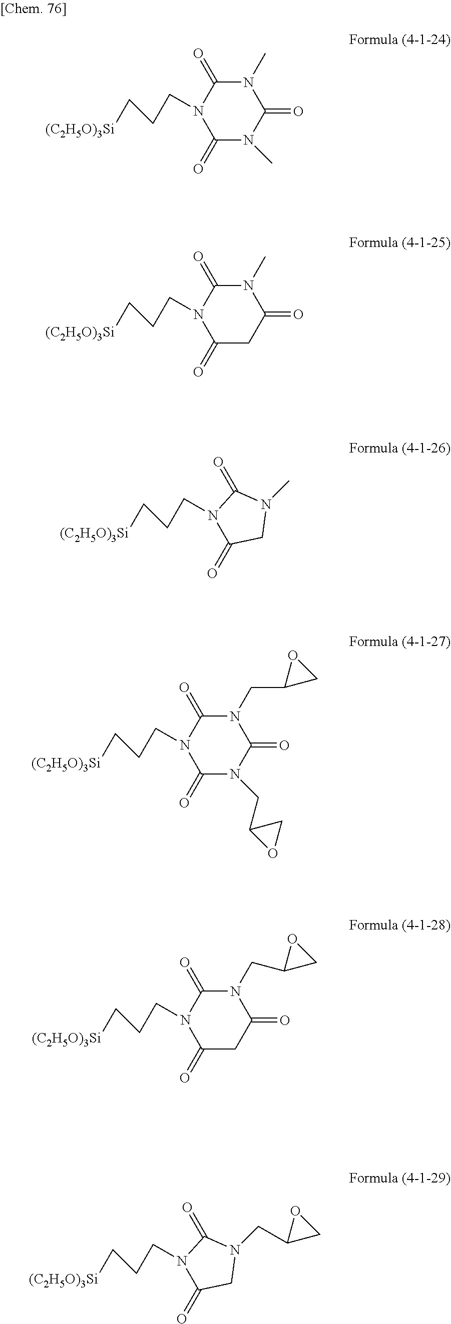

The polysiloxane [A] can be a hydrolysis condensate of a hydrolyzable silane containing another silane compound other than those exemplified above as long as the effect of the present invention is not impaired.

As described above, as the polysiloxane [A], a modified polysiloxane in which at least some silanol groups are modified can be used. For example, a polysiloxane modified product in which some silanol groups are alcohol-modified or a polysiloxane modified product in which some silanol groups are acetal-protected can be used.

Examples of the polysiloxane as the modified product include, in the hydrolysis condensate of a hydrolyzable silane described above, a reaction product obtained by a reaction between at least some silanol groups of the condensate and a hydroxy group of an alcohol, a dehydration reaction product between the condensate and an alcohol, and a modified product obtained by protecting at least some silanol groups of the condensate with an acetal group.

As the alcohol, a monohydric alcohol can be used, and examples thereof include methanol, ethanol, 2-propanol, 1-butanol, 2-butanol, isobutyl alcohol, tert-butyl alcohol, 1-pentanol, 2-pentanol, 3-pentanol, 1-heptanol, 2-heptanol, tert-amyl alcohol, neopentyl alcohol, 2-methyl-1-propanol, 2-methyl-1-butanol, 3-methyl-1-butanol, 3-methyl-3-pentanol, cyclopentanol, 1-hexanol, 2-hexanol, 3-hexanol, 2,3-dimethyl-2-butanol, 3,3-dimethyl-1-butanol, 3,3-dimethyl-2-butanol, 2-diethyl-1-butanol, 2-methyl-1-pentanol, 2-methyl-2-pentanol, 2-methyl-3-pentanol, 3-methyl-1-pentanol, 3-methyl-2-pentanol, 3-methyl-3-pentanol, 4-methyl-1-pentanol, 4-methyl-2-pentanol, 4-methyl-3-pentanol, and cyclohexanol.

For example, an alkoxy group-containing alcohol such as 3-methoxybutanol, ethylene glycol monomethyl ether, ethylene glycol monoethyl ether, diethylene glycol monomethyl ether, diethylene glycol monoethyl ether, propylene glycol monomethyl ether (1-methoxy-2-propanol), propylene glycol monoethyl ether (1-ethoxy-2-propanol), or propylene glycol monobutyl ether (1-butoxy-2-propanol) can be used.

In the reaction between the silanol group of the condensate and the hydroxy group of the alcohol, a polysiloxane and an alcohol are brought into contact with each other and allowed to react at a temperature of 40 to 160° C., for example, 60° C., for 0.1 to 48 hours, for example, 24 hours, to obtain a modified polysiloxane whose silanol group is capped. At this time, the alcohol as the capping agent can be used as a solvent in the composition containing the polysiloxane.

A dehydration reaction product of a polysiloxane formed of a hydrolysis condensate of a hydrolyzable silane and an alcohol can be produced by allowing the polysiloxane to react with an alcohol in the presence of an acid as a catalyst, capping a silanol group with the alcohol, and removing water generated by dehydration to the outside of the reaction system.

As the acid, an organic acid having an acid dissociation constant (pka) of −1 to 5, preferably 4 to 5 can be used. Examples of the acid include trifluoroacetic acid, maleic acid, benzoic acid, isobutyric acid, and acetic acid, and among them, benzoic acid, isobutyric acid, acetic acid, and the like can be exemplified.

As the acid, an acid having a boiling point of 70 to 160° C. can be used, and examples thereof include trifluoroacetic acid, isobutyric acid, acetic acid, and nitric acid.

As described above, the acid preferably has a physical property of an acid dissociation constant (pka) of 4 to 5 or a boiling point of 70 to 160° C. That is, one having a low acidity or one having a low boiling point even if the acidity is high can be used.

As the acid, either property can be used from the properties of the acid dissociation constant and the boiling point.

For acetal protection of the silanol group of the condensate, a vinyl ether, for example, a vinyl ether represented by the following formula (5) can be used, and a partial structure represented by the following formula (6) can be introduced into the polysiloxane by a reaction therebetween.

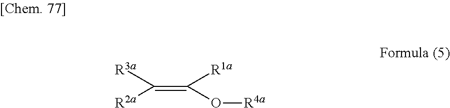

In formula (5), R^{1a}, R^{2a}, and R^{3a} each represent a hydrogen atom or an alkyl group having 1 to 10 carbon atoms, R^{4a} represents an alkyl group having 1 to 10 carbon atoms, and R^{2a} and R^{4a} may be bonded to each other to form a ring. Examples of the alkyl group include the examples described above.

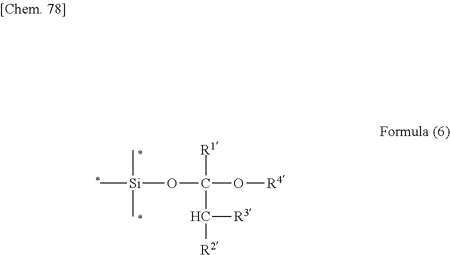

In formula (6), R^{1′}, R^{2′}, and R^{3′} each represent a hydrogen atom or an alkyl group having 1 to 10 carbon atoms, R^{4′} represents an alkyl group having 1 to 10 carbon atoms, and R^{2′} and R^{4′} may be bonded to each other to form a ring. In formula (6), * represents a bond to an adjacent atom. Examples of the adjacent atom include an oxygen atom of a siloxane bond, an oxygen atom of a silanol group, and a carbon atom derived from R¹ of formula (1). Examples of the alkyl group include the examples described above.

Examples of the vinyl ether represented by formula (5) include aliphatic vinyl ether compounds such as methyl vinyl ether, ethyl vinyl ether, isopropyl vinyl ether, n-butyl vinyl ether, 2-ethylhexyl vinyl ether, tert-butyl vinyl ether, and cyclohexyl vinyl ether, and cyclic vinyl ether compounds such as 2,3-dihydrofuran, 4-methyl-2,3-dihydrofuran, and 3,4-dihydro-2H-pyran. In particular, ethyl vinyl ether, propyl vinyl ether, butyl vinyl ether, ethylhexyl vinyl ether, cyclohexyl vinyl ether, 3,4-dihydro-2H-pyran, or 2,3-dihydrofuran can be preferably used.

The acetal protection of the silanol group can be performed using a polysiloxane, a vinyl ether, and an aprotic solvent such as propylene glycol monomethyl ether acetate, ethyl acetate, dimethylformamide, tetrahydrofuran, or 1,4-dioxane as a solvent, and using a catalyst such as pyridium p-toluenesulfonic acid, trifluoromethanesulfonic acid, p-toluenesulfonic acid, methanesulfonic acid, hydrochloric acid, or sulfuric acid.

The alcohol capping and the acetal protection of the silanol group may be performed simultaneously with hydrolysis and condensation of a hydrolyzable silane described later.

In a preferred embodiment of the present invention, the polysiloxane [A] contains at least one of a hydrolysis condensate of a hydrolyzable silane including a hydrolyzable silane represented by formula (1), and optionally a hydrolyzable silane represented by formula (2), and other hydrolyzable silanes, and a modified product thereof.

In a preferred embodiment, the polysiloxane [A] contains a dehydration reaction product of a hydrolysis condensate and an alcohol.

The weight average molecular weight of the hydrolysis condensate of a hydrolyzable silane (which may also include a modified product) can be set to, for example, 500 to 1,000,000. From the viewpoint of, for example, preventing precipitation or the like of the hydrolysis condensate in the composition, the weight average molecular weight can be preferably set to 500,000 or less, more preferably 250,000 or less, and still more preferably 100,000 or less, and from the viewpoint of, for example, achieving both storage stability and coatability, the weight average molecular weight can be preferably set to 700 or more, and more preferably 1,000 or more.

The weight average molecular weight is a molecular weight obtained in terms of polystyrene by GPC analysis. The GPC analysis can be performed using, for example, a GPC apparatus (trade name: HLC-8220GPC, manufactured by Tosoh Corporation), a GPC column (trade name: Shodex (registered trademark) KF803L, KF802, KF801, manufactured by Showa Denko K.K.), at a column temperature of 40° C., with tetrahydrofuran as an eluent (elution solvent), at a flow amount (flow rate) of 1.0 mL/min, with polystyrene (Shodex (registered trademark) manufactured by Showa Denko K.K.) as a standard sample.

The hydrolysis condensate of a hydrolyzable silane is obtained by hydrolyzing and condensing the above-mentioned silane compound (hydrolyzable silane).

The above-mentioned silane compound (hydrolyzable silane) contains an alkoxy group, an aralkyloxy group, an acyloxy group, or a halogen atom that is directly bonded to a silicon atom, that is, an alkoxysilyl group, an aralkyloxysilyl group, an acyloxysilyl group, or a halogenated silyl group (hereinafter, referred to as a hydrolyzable group).

For the hydrolysis of such a hydrolyzable group, usually 0.1 to 100 mol, for example, 0.5 to 100 mol, preferably 1 to 10 mol of water is used per mole of the hydrolyzable group.

At the time of hydrolysis and condensation, a hydrolysis catalyst may be used for the purpose of promoting the reaction, or hydrolysis and condensation may be performed without using a hydrolysis catalyst. When a hydrolysis catalyst is used, usually 0.0001 to 10 mol, preferably 0.001 to 1 mol of the hydrolysis catalyst can be used per mole of the hydrolyzable group.

The reaction temperature at the time of performing hydrolysis and condensation is usually in a range of room temperature or higher and a reflux temperature at normal pressure of an organic solvent that can be used for hydrolysis or lower, and can be set to, for example, 20 to 110° C. or 20 to 80° C.

As for the hydrolysis, hydrolysis may be performed completely, that is, all hydrolyzable groups may be changed to silanol groups, or hydrolysis may be performed partially, that is, unreacted hydrolyzable groups may be left.

Examples of the hydrolysis catalyst that can be used in hydrolysis and condensation include a metal chelate compound, an organic acid, an inorganic acid, an organic base, and an inorganic base.

Examples of the metal chelate compound as the hydrolysis catalyst include titanium chelate compounds such as triethoxy·mono(acetylacetonate)titanium, tri-n-propoxy·mono(acetylacetonate)titanium, tri-i-propoxy·mono(acetylacetonate)titanium, tri-n-butoxy·mono(acetylacetonate)titanium, tri-sec-butoxy·mono(acetylacetonate)titanium, tri-t-butoxy·mono(acetylacetonate)titanium, diethoxy·bis(acetylacetonate)titanium, di-n-propoxy·bis(acetylacetonate)titanium, di-i-propoxy·bis(acetylacetonate)titanium, di-n-butoxy·bis(acetylacetonate)titanium, di-sec-butoxy·bis(acetylacetonate)titanium, di-t-butoxy·bis(acetylacetonate)titanium, monoethoxy·tris(acetylacetonate)titanium, mono-n-propoxy·tris(acetylacetonate)titanium, mono-i-propoxy·tris(acetylacetonate)titanium, mono-n-butoxy·tris(acetylacetonate)titanium, mono-sec-butoxy·tris(acetylacetonate)titanium, mono-t-butoxy·tris(acetylacetonate)titanium, tetrakis(acetylacetonate)titanium, triethoxy·mono(ethylacetoacetate)titanium, tri-n-propoxy·mono(ethylacetoacetate)titanium, tri-i-propoxy·mono(ethylacetoacetate)titanium, tri-n-butoxy·mono(ethylacetoacetate)titanium, tri-sec-butoxy·mono(ethylacetoacetate)titanium, tri-t-butoxy·mono(ethylacetoacetate)titanium, diethoxy·bis(ethylacetoacetate)titanium, di-n-propoxy·bis(ethylacetoacetate)titanium, di-i-propoxy·bis(ethylacetoacetate)titanium, di-n-butoxy·bis(ethylacetoacetate)titanium, di-sec-butoxy·bis(ethylacetoacetate)titanium, di-t-butoxy·bis(ethylacetoacetate)titanium, monoethoxy·tris(ethylacetoacetate)titanium, mono-n-propoxy·tris(ethylacetoacetate)titanium, mono-i-propoxy·tris(ethylacetoacetate)titanium, mono-n-butoxy·tris(ethylacetoacetate)titanium, mono-sec-butoxy·tris(ethylacetoacetate)titanium, mono-t-butoxy·tris(ethylacetoacetate)titanium, tetrakis(ethylacetoacetate)titanium, mono(acetylacetonate)tris(ethylacetoacetate)titanium, bis(acetylacetonate)bis(ethylacetoacetate)titanium, and tris(acetylacetonate)mono(ethylacetoacetate) titanium; zirconium chelate compounds such as triethoxy·mono(acetylacetonate)zirconium, tri-n-propoxy·mono(acetylacetonate)zirconium, tri-i-propoxy·mono(acetylacetonate)zirconium, tri-n-butoxy·mono(acetylacetonate)zirconium, tri-sec-butoxy·mono(acetylacetonate)zirconium, tri-t-butoxy·mono(acetylacetonate)zirconium, diethoxy·bis(acetylacetonate)zirconium, di-n-propoxy·bis(acetylacetonate)zirconium, di-i-propoxy·bis(acetylacetonate)zirconium, di-n-butoxy·bis(acetylacetonate)zirconium, di-sec-butoxy·bis(acetylacetonate)zirconium, di-t-butoxy·bis(acetylacetonate)zirconium, monoethoxy·tris(acetylacetonate)zirconium, mono-n-propoxy·tris(acetylacetonate)zirconium, mono-i-propoxy·tris(acetylacetonate)zirconium, mono-n-butoxy·tris(acetylacetonate)zirconium, mono-sec-butoxy·tris(acetylacetonate)zirconium, mono-t-butoxy·tris(acetylacetonate)zirconium, tetrakis(acetylacetonate)zirconium, triethoxy·mono(ethylacetoacetate)zirconium, tri-n-propoxy·mono(ethylacetoacetate)zirconium, tri-i-propoxy·mono(ethylacetoacetate)zirconium, tri-n-butoxy·mono(ethylacetoacetate)zirconium, tri-sec-butoxy·mono(ethylacetoacetate)zirconium, tri-t-butoxy·mono(ethylacetoacetate)zirconium, diethoxy·bis(ethylacetoacetate)zirconium, di-n-propoxy·bis(ethylacetoacetate)zirconium, di-i-propoxy·bis(ethylacetoacetate)zirconium, di-n-butoxy·bis(ethylacetoacetate)zirconium, di-sec-butoxy·bis(ethylacetoacetate)zirconium, di-t-butoxy·bis(ethylacetoacetate)zirconium, monoethoxy·tris(ethylacetoacetate)zirconium, mono-n-propoxy·tris(ethylacetoacetate)zirconium, mono-i-propoxy·tris(ethylacetoacetate)zirconium, mono-n-butoxy·tris(ethylacetoacetate)zirconium, mono-sec-butoxy·tris(ethylacetoacetate)zirconium, mono-t-butoxy·tris(ethylacetoacetate)zirconium, tetrakis(ethylacetoacetate)zirconium, mono(acetylacetonate)tris(ethylacetoacetate)zirconium, bis(acetylacetonate)bis(ethylacetoacetate)zirconium, and tris(acetylacetonate)mono(ethylacetoacetate)zirconium; and aluminum chelate compounds such as tris(acetylacetonate) aluminum and tris(ethylacetoacetate) aluminum, but are not limited thereto.

Examples of the organic acid as the hydrolysis catalyst include acetic acid, propionic acid, butanoic acid, pentanoic acid, hexanoic acid, heptanoic acid, octanoic acid, nonanoic acid, decanoic acid, oxalic acid, maleic acid, methylmalonic acid, adipic acid, sebacic acid, gallic acid, butyric acid, mellitic acid, arachidonic acid, 2-ethylhexanoic acid, oleic acid, stearic acid, linoleic acid, linolenic acid, salicylic acid, benzoic acid, p-aminobenzoic acid, p-toluenesulfonic acid, benzenesulfonic acid, monochloroacetic acid, dichloroacetic acid, trichloroacetic acid, trifluoroacetic acid, formic acid, malonic acid, sulfonic acid, phthalic acid, fumaric acid, citric acid, and tartaric acid, but are not limited thereto.

Examples of the inorganic acid as the hydrolysis catalyst include hydrochloric acid, nitric acid, sulfuric acid, hydrofluoric acid, and phosphoric acid, but are not limited thereto.

Examples of the organic base as the hydrolysis catalyst include pyridine, pyrrole, piperazine, pyrrolidine, piperidine, picoline, trimethylamine, triethylamine, monoethanolamine, diethanolamine, dimethylmonoethanolamine, monomethyldiethanolamine, triethanolamine, diazabicyclooctane, diazabicyclononane, diazabicycloundecene, tetramethylammonium hydroxide, tetraethylammonium hydroxide, tetrapropylammonium hydroxide, tetrabutylammonium hydroxide, trimethylphenylammonium hydroxide, benzyltrimethylammonium hydroxide, and benzyltriethylammonium hydroxide, but are not limited thereto.

Examples of the inorganic base as the hydrolysis catalyst include ammonia, sodium hydroxide, potassium hydroxide, barium hydroxide, and calcium hydroxide, but are not limited thereto.

Among these catalysts, a metal chelate compound, an organic acid, and an inorganic acid are preferable, and one type of these may be used alone or two or more types thereof may be used in combination.

Among them, in the present invention, nitric acid can be suitably used as the hydrolysis catalyst. Use of nitric acid can improve the storage stability of the reaction solution after hydrolysis and condensation, and can particularly prevent a change in the molecular weight of the hydrolysis condensate. The stability of the hydrolysis condensate in a liquid has been found to depend on the pH of the solution. As a result of intensive studies, it has been found that the pH of the solution falls in a stable region by using an appropriate amount of nitric acid.

In addition, as described above, nitric acid can also be used when a modified product of the hydrolysis condensate is obtained, for example, when a silanol group is capped with an alcohol, and therefore is also preferable from the viewpoint of being able to contribute to both reactions of hydrolysis and condensation of a hydrolyzable silane and alcohol capping of the hydrolysis condensate.

When hydrolysis and condensation are performed, an organic solvent may be used as a solvent, and specific examples thereof include aliphatic hydrocarbon-based solvents such as n-pentane, i-pentane, n-hexane, i-hexane, n-heptane, i-heptane, 2,2,4-trimethylpentane, n-octane, i-octane, cyclohexane, and methylcyclohexane; aromatic hydrocarbon-based solvents such as benzene, toluene, xylene, ethylbenzene, trimethylbenzene, methylethylbenzene, n-propylbenzene, i-propylbenzene, diethylbenzene, i-butylbenzene, triethylbenzene, di-i-propylbenzene, and n-amylnaphthalene; monoalcohol-based solvents such as methanol, ethanol, n-propanol, i-propanol, n-butanol, i-butanol, sec-butanol, t-butanol, n-pentanol, i-pentanol, 2-methylbutanol, sec-pentanol, t-pentanol, 3-methoxybutanol, n-hexanol, 2-methylpentanol, sec-hexanol, 2-ethylbutanol, n-heptanol, sec-heptanol, 3-heptanol, n-octanol, 2-ethylhexanol, sec-octanol, n-nonyl alcohol, 2,6-dimethyl-4-heptanol, n-decanol, sec-undecyl alcohol, trimethylnonyl alcohol, sec-tetradecyl alcohol, sec-heptadecyl alcohol, phenol, cyclohexanol, methylcyclohexanol, 3,3,5-trimethylcyclohexanol, benzyl alcohol, phenylmethylcarbinol, diacetone alcohol, and cresol; polyhydric alcohol-based solvents such as ethylene glycol, propylene glycol, 1,3-butylene glycol, 2,4-pentanediol, 2-methyl-2,4-pentanediol, 2,5-hexanediol, 2,4-heptanediol, 2-ethyl-1,3-hexanediol, diethylene glycol, dipropylene glycol, triethylene glycol, tripropylene glycol, and glycerin; ketone-based solvents such as acetone, methyl ethyl ketone, methyl-n-propyl ketone, methyl-n-butyl ketone, diethyl ketone, methyl-1-butyl ketone, methyl-n-pentyl ketone, ethyl-n-butyl ketone, methyl-n-hexyl ketone, di-i-butyl ketone, trimethylnonanone, cyclohexanone, methylcyclohexanone, 2,4-pentanedione, acetonylacetone, diacetone alcohol, acetophenone, and fenchon; ether-based solvents such as ethyl ether, i-propyl ether, n-butyl ether, n-hexyl ether, 2-ethylhexyl ether, ethylene oxide, 1,2-propylene oxide, dioxolane, 4-methyldioxolane, dioxane, dimethyldioxane, ethylene glycol monomethyl ether, ethylene glycol monoethyl ether, ethylene glycol diethyl ether, ethylene glycol mono-n-butyl ether, ethylene glycol mono-n-hexyl ether, ethylene glycol monophenyl ether, ethylene glycol mono-2-ethyl butyl ether, ethylene glycol dibutyl ether, diethylene glycol monomethyl ether, diethylene glycol monoethyl ether, diethylene glycol diethyl ether, diethylene glycol mono-n-butyl ether, diethylene glycol di-n-butyl ether, diethylene glycol mono-n-hexyl ether, ethoxy triglycol, tetraethylene glycol di-n-butyl ether, propylene glycol monomethyl ether (1-methoxy-2-propanol), propylene glycol monoethyl ether (1-ethoxy-2-propanol), propylene glycol monopropyl ether, propylene glycol monobutyl ether, propylene glycol monomethyl ether acetate (1-methoxy-2-propanol monoacetate), dipropylene glycol monomethyl ether, dipropylene glycol monoethyl ether, dipropylene glycol monopropyl ether, dipropylene glycol monobutyl ether, tripropylene glycol monomethyl ether, tetrahydrofuran, and 2-methyltetrahydrofuran; ester-based solvents such as diethyl carbonate, methyl acetate, ethyl acetate, γ-butyrolactone, γ-valerolactone, n-propyl acetate, i-propyl acetate, n-butyl acetate, i-butyl acetate, sec-butyl acetate, n-pentyl acetate, sec-pentyl acetate, 3-methoxybutyl acetate, methylpentyl acetate, 2-ethylbutyl acetate, 2-ethylhexyl acetate, benzyl acetate, cyclohexyl acetate, methylcyclohexyl acetate, n-nonyl acetate, methyl acetoacetate, ethyl acetoacetate, ethylene glycol monomethyl ether acetate, ethylene glycol monoethyl ether acetate, diethylene glycol monomethyl ether acetate, diethylene glycol monoethyl ether acetate, diethylene glycol mono-n-butyl ether acetate, propylene glycol monomethyl ether acetate, propylene glycol monoethyl ether acetate, propylene glycol monopropyl ether acetate, propylene glycol monobutyl ether acetate, dipropylene glycol monomethyl ether acetate, dipropylene glycol monoethyl ether acetate, glycol diacetate, methoxytriglycol acetate, ethylene glycol diacetate, triethylene glycol methyl ether acetate, ethyl propionate, n-butyl propionate, i-amyl propionate, diethyl oxalate, di-n-butyl oxalate, methyl lactate, ethyl lactate, n-butyl lactate, n-amyl lactate, diethyl malonate, dimethyl phthalate, and diethyl phthalate; nitrogen-containing solvents such as N-methylformamide, N,N-dimethylformamide, N,N-diethylformamide, acetamide, N-methylacetamide, N,N-dimethylacetamide, N-methylpropionamide, and N-methyl-2-pyrrolidone; and sulfur-containing solvents such as dimethyl sulfide, diethyl sulfide, thiophene, tetrahydrothiophene, dimethyl sulfoxide, sulfolane, and 1,3-propane sultone, but are not limited thereto. One type of these solvents can be used alone, or two or more types thereof can be used in combination.

After completion of the hydrolysis and condensation reaction, the reaction solution is left as it is or diluted or concentrated, and then neutralized, and treated using an ion exchange resin, whereby the hydrolysis catalyst such as an acid or a base used for hydrolysis and condensation can be removed. In addition, before or after such a treatment, an alcohol or water as a by-product, the hydrolysis catalyst used, and the like can be removed from the reaction solution by distillation under reduced pressure or the like.

The thus obtained hydrolysis condensate (hereinafter, also referred to as polysiloxane) is obtained in the form of a polysiloxane varnish dissolved in an organic solvent, and can be used as it is for preparing the silicon-containing resist underlayer film-forming composition. That is, the reaction solution can be used as it is (or diluted) for the preparation of the silicon-containing resist underlayer film-forming composition, and at this time, the hydrolysis catalyst used for hydrolysis and condensation, a by-product, and the like may remain in the reaction solution as long as the effect of the present invention is not impaired. For example, the hydrolysis catalyst or nitric acid used at the time of alcohol capping of a silanol group may remain in the polymer varnish solution in an amount of about 100 ppm to 5,000 ppm.

The obtained polysiloxane varnish may be subjected to solvent substitution or may be appropriately diluted with a solvent. If the storage stability of the obtained polysiloxane varnish is not poor, the organic solvent can be distilled off to set the concentration of the film-forming component to 100%. The film-forming component refers to a component obtained by removing the solvent component from all components of the composition.

The organic solvent used for solvent substitution, dilution, or the like of the polysiloxane varnish may be the same as or different from the organic solvent used for the hydrolysis and condensation reaction of the hydrolyzable silane. The dilution solvent is not particularly limited, and one type or two or more types can be arbitrarily selected and used.

### <Component [B]>

The component [B] is sulfuric acid, a polyfunctional sulfonic acid, or a salt thereof. One type thereof can be used alone, or two or more types thereof can be used in combination.

The polyfunctional sulfonic acid in the present invention is a compound having two or more sulfo groups (—SO₃H).

As described above, the present inventors have found that a resist underlayer film capable of increasing the sensitivity of a resist can be formed by incorporating sulfuric acid, a polyfunctional sulfonic acid, or a salt thereof as the component [B] in a silicon-containing resist underlayer-forming composition containing a polysiloxane.

As shown in examples described later, even when a monofunctional sulfonic acid (a compound having one sulfo group (—SO₃H)) is used in place of the component [B], the effect of the present invention cannot be obtained.

The effect of the present invention is remarkable when a metal-containing resist is used. The present inventors consider the reason as follows. Sulfuric acid, a polyfunctional sulfonic acid, and a salt thereof are coordinated to a metal of a metal-containing resist to promote curing of the resist. As a result, the sensitivity of the resist is improved.

The number of sulfo groups of the polyfunctional sulfonic acid is not particularly limited, but is preferably 2 to 6, and more preferably 2 to 4. The number of sulfo groups is usually represented by an integer.

The molecular weight of the polyfunctional sulfonic acid is not particularly limited, but is preferably 176 to 1,000, and more preferably 176 to 500. The molecular weight of 176 is a molecular weight of methane disulfonic acid.

As the polyfunctional sulfonic acid, for example, a compound represented by the following formula (A) is preferable.

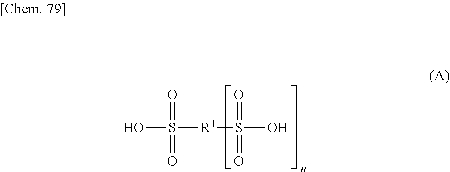

In formula (A), n represents an integer of 1 to 3, and R¹ represents an n+1-valent organic group having 1 to 15 carbon atoms.

The n+1-valent organic group having 1 to 15 carbon atoms in R¹ may have a hydrogen atom, an oxygen atom, a nitrogen atom, a sulfur atom, or the like in addition to a carbon atom.

The molecular weight of the n+1-valent organic group having 1 to 15 carbon atoms in R¹ is not particularly limited, but is preferably 12 to 200.

n may be 1, 2, or 3.

Examples of the polyfunctional sulfonic acid include the following compounds.

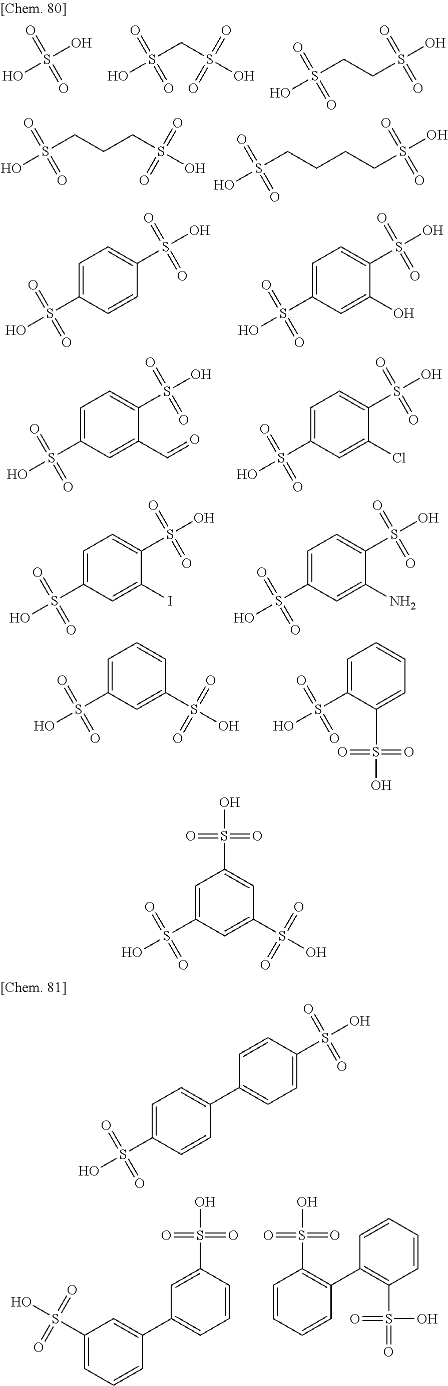

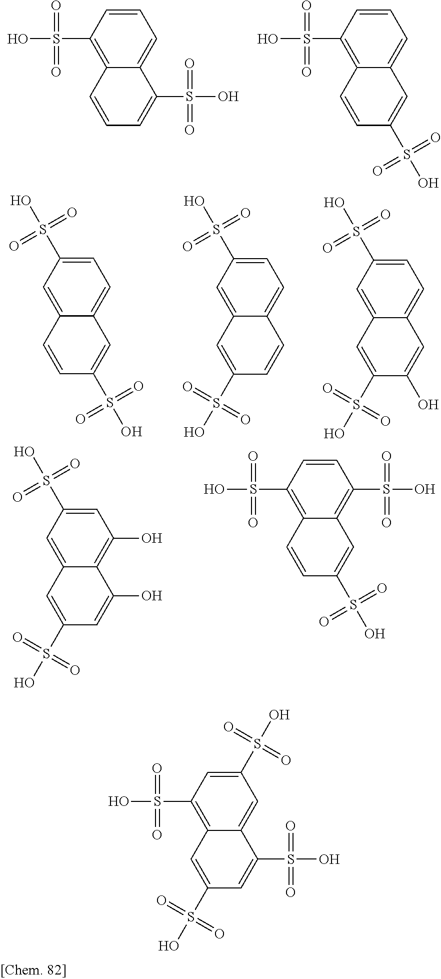

A salt of the sulfuric acid, the polyfunctional sulfonic acid, or the salt thereof are not particularly limited, and examples thereof include an ammonium salt, an imidazolium salt, a pyridinium salt, a sulfonium salt, a phosphonium salt, and an iodonium salt.

In these salts, it is not necessary that all sulfo groups are anionized, and it is sufficient that at least one sulfo group is anionized.

These salts may be, for example, salts as shown in the following specific examples. That is, at least one sulfo group of the two or more sulfo groups of the polyfunctional sulfonic acid may be anionized to form a salt.

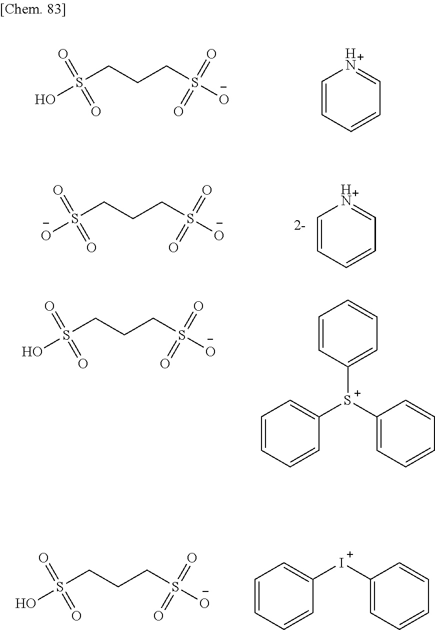

Even when these salts do not have a sulfo group (—SO₃H) in the state of a salt, the sulfo group is generated, for example, by irradiation with light or an electron beam or by heat.

Examples of the ammonium salt include N,N-dimethyl-N-benzylammonium and N,N-diethyl-N-benzylammonium.

Examples of the imidazolium salt include a salt of an imidazole and a polyfunctional sulfonic acid. Examples of the imidazole include imidazole, benzimidazole, 2-methylimidazole, 4-methylimidazole, 2-phenylimidazole, 4-phenylimidazole, 2-phenyl-4-methylimidazole, 2-methyl-4-phenylimidazole, 2-methylbenzimidazole, and 2-phenylbenzimidazole.

Examples of the pyridinium salt include a salt of a pyridine and a polyfunctional sulfonic acid. Examples of the pyridine include pyridine, picoline, and 4-methylpyridine.

Examples of the sulfonium salt include an aromatic sulfonium salt. Examples of the aromatic sulfonium salt include a triphenylsulfonium salt, a (2-ethoxy-1-methyl-2-oxoethyl)methyl-2-naphthalenylsulfonium salt, a 4-(methoxycarbonyloxy)phenylbenzylmethylsulfonium salt, a 4-acetoxyphenyldimethylsulfonium salt, a 4-hydroxyphenylbenzylmethylsulfonium salt, a 4-hydroxyphenyl(o-methylbenzyl)methylsulfonium salt, a 4-hydroxyphenyl(α-naphthylmethyl)methylsulfonium salt, and a diphenyl-4-(phenylthio)phenylsulfonium salt.

Examples of the phosphonium salt include an ethyltriphenylphosphonium salt and a tetrabutylphosphonium salt.

Examples of the iodonium salt include an aromatic iodonium salt. Examples of the aromatic iodonium salt include a diphenyliodonium salt, a 4-methylphenyl-4-(1-methylethyl)phenyliodonium salt, a bis(4-t-butylphenyl)iodonium salt, and a bis(dodecylphenyl)iodonium salt.

The content of the component [B] in the silicon-containing resist underlayer film-forming composition can be set to preferably 0.05 to 20 parts by mass, more preferably 0.1 to 15 parts by mass, and still more preferably 0.5 to 10 parts by mass with respect to 100 parts by mass of the polysiloxane [A] from the viewpoint of more sufficiently obtaining the effect of the present invention.

### <Component [C]: Solvent>

A solvent as the component [C] can be used without particular limitation as long as it is a solvent capable of dissolving and mixing the component [A] and the component [B] and if necessary, other components contained in the silicon-containing resist underlayer film-forming composition.

The solvent [C] is preferably an alcohol-based solvent, more preferably an alkylene glycol monoalkyl ether which is an alcohol-based solvent, and still more preferably a propylene glycol monoalkyl ether. Since these solvents are also capping agents for a silanol group of a polysiloxane, it is possible to prepare a silicon-containing resist underlayer film-forming composition from a solution obtained by preparing the polysiloxane [A] without requiring solvent substitution or the like.

Examples of the alkylene glycol monoalkyl ether include ethylene glycol monomethyl ether, ethylene glycol monoethyl ether, ethylene glycol monopropyl ether, ethylene glycol monobutyl ether, propylene glycol monomethyl ether (1-methoxy-2-propanol), propylene glycol monoethyl ether (1-ethoxy-2-propanol), methyl isobutyl carbinol, and propylene glycol monobutyl ether.

Specific examples of another solvent [C] include methyl cellosolve acetate, ethyl cellosolve acetate, propyrene glycol propylene glycol monomethyl ether acetate (1-methoxy-2-propanol monoacetate), propylene glycol monoethyl ether acetate, propylene glycol monopropyl ether acetate, propylene glycol monobutyl ether acetate, toluene, xylene, methyl ethyl ketone, cyclopentanone, cyclohexanone, ethyl 2-hydroxypropionate, ethyl 2-hydroxy-2-methylpropionate, ethyl ethoxyacetate, ethyl hydroxyacetate, methyl 2-hydroxy-3-methylbutanoate, methyl 3-methoxypropionate, ethyl 3-methoxypropionate, ethyl 3-ethoxypropionate, methyl 3-ethoxypropionate, methyl pyruvate, ethyl pyruvate, ethylene glycol monomethyl ether acetate, ethylene glycol monoethyl ether acetate, ethylene glycol monopropyl ether acetate, ethylene glycol monobutyl ether acetate, diethylene glycol dimethyl ether, diethylene glycol diethyl ether, diethylene glycol dipropyl ether, diethylene glycol dibutyl ether, propylene glycol monomethyl ether, propylene glycol dimethyl ether, propylene glycol diethyl ether, propylene glycol dipropyl ether, propylene glycol dibutyl ether, ethyl lactate, propyl lactate, isopropyl lactate, butyl lactate, isobutyl lactate, methyl formate, ethyl formate, propyl formate, isopropyl formate, butyl formate, isobutyl formate, amyl formate, isoamyl formate, methyl acetate, ethyl acetate, amyl acetate, isoamyl acetate, hexyl acetate, methyl propionate, ethyl propionate, propyl propionate, isopropyl propionate, butyl propionate, isobutyl propionate, methyl butyrate, ethyl butyrate, propyl butyrate, isopropyl butyrate, butyl butyrate, isobutyl butyrate, ethyl hydroxyacetate, ethyl 2-hydroxy-2-methylpropionate, methyl 3-methoxy-2-methylpropionate, methyl 2-hydroxy-3-methyl butyrate, ethyl methoxyacetate, ethyl ethoxyacetate, methyl 3-methoxypropionate, ethyl 3-ethoxypropionate, ethyl 3-methoxypropionate, 3-methoxybutyl acetate, 3-methoxypropyl acetate, 3-methyl-3-methoxybutyl acetate, 3-methyl-3-methoxybutyl propionate, 3-methyl-3-methoxybutyl butyrate, methyl acetoacetate, toluene, xylene, methyl ethyl ketone, methyl propyl ketone, methyl butyl ketone, 2-heptanone, 3-heptanone, 4-heptanone, cyclohexanone, N,N-dimethylformamide, N-methylacetamide, N,N-dimethylacetamide, N-methyl-2-pyrrolidone, 4-methyl-2-pentanol, and γ-butyrolactone, and as the solvent, one type can be used alone or two or more types can be used in combination.

The silicon-containing resist underlayer film-forming composition of the present invention may contain water as the solvent. When water is contained as the solvent, the content thereof can be set to, for example, 30 mass % or less, preferably 20 mass % or less, and more preferably 15 mass % or less with respect to the total mass of the solvent contained in the composition.

### <Component [D]: Curing Catalyst>

The silicon-containing resist underlayer film-forming composition can be a composition containing no curing catalyst, but preferably contains a curing catalyst (component [D]).

When the silicon-containing resist underlayer film-forming composition contains both the component [B] and the component [D], the effect of the present invention by containing the component [B] can be more sufficiently obtained.

As the curing catalyst, an ammonium salt, a phosphine, a phosphonium salt, a sulfonium salt, an iodonium salt, an oxonium salt, or the like can be used. The following salts described as an example of the curing catalyst may be added in the form of a salt or may form a salt in the composition (one that is added as a separate compound at the time of addition and forms a salt in the system).

Examples of the ammonium salt include a quaternary ammonium salt having a structure represented by formula (D-1):

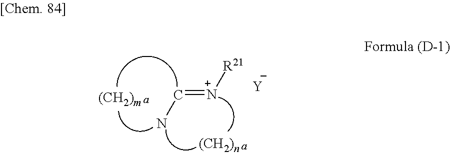

wherein m^{a} represents an integer of 2 to 11, n^{a} represents an integer of 2 to 3, R²¹ represents an alkyl group, an aryl group, or an aralkyl group, and Y⁻ represents an anion;
a quaternary ammonium salt having a structure represented by formula (D-2):

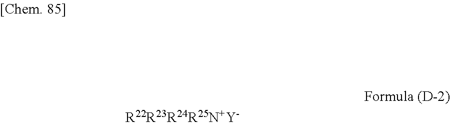

wherein R²², R²³, R²⁴, and R²⁵ each independently represent an alkyl group, an aryl group, or an aralkyl group, Y⁻ represents an anion, and R²², R²³, R²⁴, and R²⁵ are each bonded to the nitrogen atom;
a quaternary ammonium salt having a structure represented by formula (D-3):

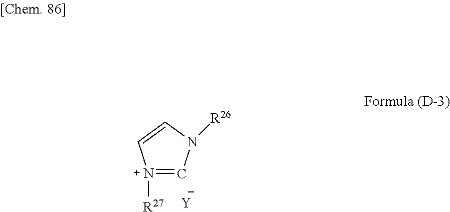

wherein R²⁶ and R²⁷ each independently represent an alkyl group, an aryl group, or an aralkyl group, and Y⁻ represents an anion;
a quaternary ammonium salt having a structure represented by formula (D-4):

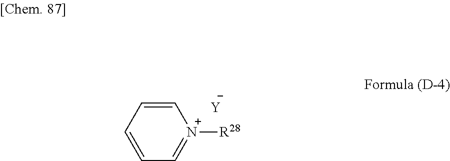

wherein R²⁸ represents an alkyl group, an aryl group, or an aralkyl group, and Y⁻ represents an anion;
a quaternary ammonium salt having a structure represented by formula (D-5):

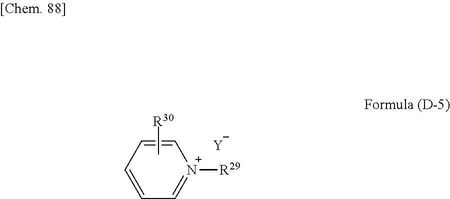

wherein R²⁹ and R³⁰ each independently represent an alkyl group, an aryl group, or an aralkyl group, and Y⁻ represents an anion; and
a tertiary ammonium salt having a structure represented by formula (D-6)

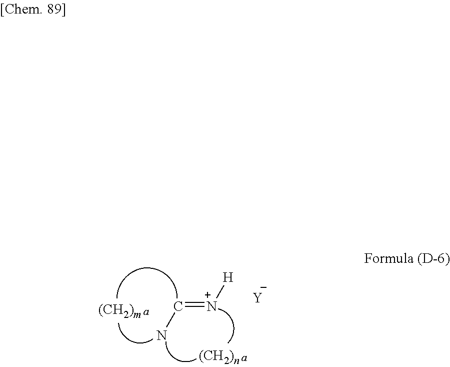

wherein m^{a} represents an integer of 2 to 11, n^{a} represents an integer of 2 to 3, and Y⁻ represents an anion.

Examples of the phosphonium salt include a quaternary phosphonium salt represented by formula (D-7):

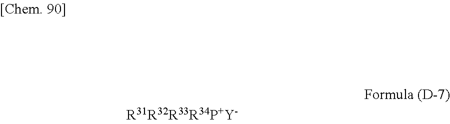

wherein R³¹, R³², R³³, and R³⁴ each independently represent an alkyl group, an aryl group, or an aralkyl group, Y⁻ represents an anion, and R³¹, R³², R³³, and R³⁴ are each bonded to the phosphorus atom.

Examples of the sulfonium salt include a tertiary sulfonium salt represented by formula (D-8):

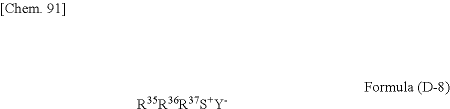

wherein R³⁵, R³⁶, and R³⁷ each independently represent an alkyl group, an aryl group, or an aralkyl group, Y⁻ represents an anion, and R³⁵, R³⁶, and R³⁷ are each bonded to the sulfur atom.

The compound of formula (D-1) is a quaternary ammonium salt derived from an amine, m^{a} represents an integer of 2 to 11, and n^{a} represents an integer of 2 to 3. R²¹ of this quaternary ammonium salt represents, for example, an alkyl group having 1 to 18, preferably 2 to 10 carbon atoms, an aryl group having 6 to 18 carbon atoms, or an aralkyl group having 7 to 18 carbon atoms, and examples thereof include linear alkyl groups such as an ethyl group, a propyl group, or a butyl group, a benzyl group, a cyclohexyl group, a cyclohexylmethyl group, and a dicyclopentadienyl group. Examples of the anion (Y⁻) include halide ions such as a chlorine ion (Cl⁻), a bromine ion (Br⁻), and an iodine ion (I⁻), and acid groups such as carboxylate (—COO—), sulfonate (—SO₃⁻), and alcoholate (—O⁻).

The compound of formula (D-2) is a quaternary ammonium salt represented by R²²R²³R²⁴R²⁵N⁺Y⁻. R²², R²³, R²⁴, and R²⁵ of this quaternary ammonium salt are, for example, an alkyl group having 1 to 18 carbon atoms such as an ethyl group, a propyl group, a butyl group, a cyclohexyl group, and a cyclohexylmethyl group, an aryl group having 6 to 18 carbon atoms such as a phenyl group, or an aralkyl group having 7 to 18 carbon atoms such as a benzyl group. Examples of the anion (Y⁻) include halide ions such as a chlorine ion (Cl⁻), a bromine ion (Br⁻), and an iodine ion (I⁻), and acid groups such as carboxylate (—COO—), sulfonate (—SO₃⁻), and alcoholate (—O⁻). This quaternary ammonium salt can be obtained as a commercially available product, and examples thereof include tetramethylammonium acetate, tetrabutylammonium acetate, triethylbenzylammonium chloride, triethylbenzylammonium bromide, trioctylmethylammonium chloride, tributylbenzylammonium chloride, and trimethylbenzylammonium chloride.

The compound of formula (D-3) is a quaternary ammonium salt derived from a 1-substituted imidazole, the number of carbon atoms of R²⁶ and R²⁷ is, for example, 1 to 18, and the total number of carbon atoms of R²⁶ and R²⁷ is preferably 7 or more. Examples of R²⁶ include alkyl groups such as a methyl group, an ethyl group, and a propyl group, aryl groups such as a phenyl group, and aralkyl groups such as a benzyl group, and examples of R²⁷ include aralkyl groups such as a benzyl group, and alkyl groups such as an octyl group and an octadecyl group. Examples of the anion (Y⁻) include halide ions such as a chlorine ion (Cl⁻), a bromine ion (Br⁻), and an iodine ion (I⁻), and acid groups such as carboxylate (—COO—), sulfonate (—SO₃⁻), and alcoholate (—O⁻). This compound can also be obtained as a commercially available product, but can be produced by allowing an imidazole-based compound such as 1-methylimidazole or 1-benzylimidazole to react with an aralkyl halide, an alkyl halide, or an aryl halide such as benzyl bromide, methyl bromide, or benzene bromide.

The compound of formula (D-4) is a quaternary ammonium salt derived from pyridine, and R²⁸ is, for example, an alkyl group having 1 to 18 carbon atoms, preferably 4 to 18 carbon atoms, an aryl group having 6 to 18 carbon atoms, or an aralkyl group having 7 to 18 carbon atoms, and examples thereof include a butyl group, an octyl group, a benzyl group, and a lauryl group. Examples of the anion (Y⁻) include halide ions such as a chlorine ion (Cl⁻), a bromine ion (Br⁻), and an iodine ion (I⁻), and acid groups such as carboxylate (—COO—), sulfonate (—SO₃⁻), and alcoholate (—O⁻). This compound can also be obtained as a commercially available product, but can be produced, for example, by allowing pyridine to react with an alkyl halide or an aryl halide such as lauryl chloride, benzyl chloride, benzyl bromide, methyl bromide, or octyl bromide. Examples of the compound include N-laurylpyridinium chloride and N-benzylpyridinium bromide.

The compound of formula (D-5) is a quaternary ammonium salt derived from a substituted pyridine represented by picoline or the like, and R²⁹ is, for example, an alkyl group having 1 to 18 carbon atoms, preferably 4 to 18 carbon atoms, an aryl group having 6 to 18 carbon atoms, or an aralkyl group having 7 to 18 carbon atoms, and examples thereof include a methyl group, an octyl group, a lauryl group, and a benzyl group. R³⁰ is, for example, an alkyl group having 1 to 18 carbon atoms, an aryl group having 6 to 18 carbon atoms, or an aralkyl group having 7 to 18 carbon atoms, and for example, when the compound represented by formula (D-5) is a quaternary ammonium derived from picoline, R³⁰ is a methyl group. Examples of the anion (Y⁻) include halide ions such as a chlorine ion (Cl⁻), a bromine ion (Br⁻), and an iodine ion (I⁻), and acid groups such as carboxylate (—COO—), sulfonate (—SO₃⁻), and alcoholate (—O⁻). This compound can also be obtained as a commercially available product, but can be produced, for example, by allowing a substituted pyridine such as picoline to react with an alkyl halide or an aryl halide such as methyl bromide, octyl bromide, lauryl chloride, benzyl chloride, or benzyl bromide. Examples of the compound include N-benzylpicolinium chloride, N-benzylpicolinium bromide, and N-laurylpicolinium chloride.

The compound of formula (D-6) is a tertiary ammonium salt derived from an amine, m^{a} represents an integer of 2 to 11, and n^{a} represents an integer of 2 or 3. Examples of the anion (Y⁻) include halide ions such as a chlorine ion (Cl⁻), a bromine ion (Br⁻), and an iodine ion (I⁻), and acid groups such as carboxylate (—COO—), sulfonate (—SO₃⁻), and alcoholate (—O⁻). The present compound can be produced by a reaction of an amine with a weak acid such as a carboxylic acid or phenol. Examples of the carboxylic acid include formic acid and acetic acid, and when formic acid is used, the anion (Y⁻) is (HCOO⁻), and when acetic acid is used, the anion (Y⁻) is (CH₃COO⁻). When phenol is used, the anion (Y⁻) is (C₆H₅O⁻).

The compound of formula (D-7) is a quaternary phosphonium salt having a structure of R³¹R³²R³³R³⁴P⁺Y⁻. R³¹, R³², R³³, and R³⁴ are, for example, an alkyl group having 1 to 18 carbon atoms such as an ethyl group, a propyl group, a butyl group, or cyclohexylmethyl, an aryl group having 6 to 18 carbon atoms such as a phenyl group, or an aralkyl group having 7 to 18 carbon atoms such as a benzyl group, and preferably, three of four substituents of R³¹ to R³⁴ are an unsubstituted phenyl group or a substituted phenyl group, and for example, a phenyl group or a tolyl group can be exemplified, and the remaining one is an alkyl group having 1 to 18 carbon atoms, an aryl group having 6 to 18 carbon atoms, or an aralkyl group having 7 to 18 carbon atoms. Examples of the anion (Y⁻) include halide ions such as a chlorine ion (Cl⁻), a bromine ion (Br⁻), and an iodine ion (I⁻), and acid groups such as carboxylate (—COO—), sulfonate (—SO₃⁻), and alcoholate (—O⁻). This compound can be obtained as a commercial product, and examples thereof include tetraalkylphosphonium halides such as a tetra-n-butylphosphonium halide and a tetra-n-propylphosphonium halide, trialkylbenzylphosphonium halides such as a triethylbenzylphosphonium halide, triphenylmonoalkylphosphonium halides such as a triphenylmethylphosphonium halide and a triphenylethylphosphonium halide, a triphenylbenzylphosphonium halide, a tetraphenylphosphonium halide, a tritolylmonoarylphosphonium halide, and a tritolylmonoalkylphosphonium halide (in the above, the halogen atom is a chlorine atom or a bromine atom). In particular, triphenylmonoalkylphosphonium halides such as a triphenylmethylphosphonium halide and a triphenylethylphosphonium halide, triphenylmonoarylphosphonium halides such as a triphenylbenzylphosphonium halide, tritolylmonoarylphosphonium halides such as a tritolylmonophenylphosphonium halide, and tritolylmonoalkylphosphonium halides such as a tritolylmonomethylphosphonium halide (in the above, the halogen atom is a chlorine atom or a bromine atom) are preferable.

Examples of the phosphine include primary phosphines such as methylphosphine, ethylphosphine, propylphosphine, isopropylphosphine, isobutylphosphine, and phenylphosphine, secondary phosphines such as dimethylphosphine, diethylphosphine, diisopropylphosphine, diisoamylphosphine, and diphenylphosphine, and tertiary phosphines such as trimethylphosphine, triethylphosphine, triphenylphosphine, methyldiphenylphosphine, and dimethylphenylphosphine.

The compound of formula (D-8) is a tertiary sulfonium salt having a structure of R³⁵R³⁶R³⁷S⁺Y⁻. R³⁵, R³⁶, and R³⁷ are, for example, an alkyl group having 1 to 18 carbon atoms such as an ethyl group, a propyl group, a butyl group, or cyclohexylmethyl, an aryl group having 6 to 18 carbon atoms such as a phenyl group, or an aralkyl group having 7 to 18 carbon atoms such as a benzyl group, and preferably, two of three substituents of R³⁵ to R³⁷ are an unsubstituted phenyl group or a substituted phenyl group, and for example, a phenyl group or a tolyl group can be exemplified, and the remaining one is an alkyl group having 1 to 18 carbon atoms, an aryl group having 6 to 18 carbon atoms, or an aralkyl group having 7 to 18 carbon atoms. Examples of the anion (Y⁻) include halide ions such as a chlorine ion (Cl⁻), a bromine ion (Br⁻), and an iodine ion (I⁻), and acid groups such as carboxylate (—COO—), sulfonate (—SO₃⁻), alcoholate (—O⁻), a maleate anion, and a nitrate anion. This compound can be obtained as a commercially available product, and examples thereof include trialkylsulfonium halides such as a tri-n-butylsulfonium halide and a tri-n-propylsulfonium halide, dialkylbenzylsulfonium halides such as a diethylbenzylsulfonium halide, diphenylmonoalkylsulfonium halides such as a diphenylmethylsulfonium halide and a diphenylethylsulfonium halide, a triphenylsulfonium halide (in the above, the halogen atom is a chlorine atom or a bromine atom), trialkylsulfonium carboxylates such as tri-n-butylsulfonium carboxylate and tri-n-propylsulfonium carboxylate, dialkylbenzylsulfonium carboxylates such as diethylbenzylsulfonium carboxylate, diphenylmonoalkylsulfonium carboxylates such as diphenylmethylsulfonium carboxylate and diphenylethylsulfonium carboxylate, and triphenylsulfonium carboxylate. Further, a triphenylsulfonium halide and triphenylsulfonium carboxylate can be preferably used.

In addition, a nitrogen-containing silane compound can be added as a curing catalyst. Examples of the nitrogen-containing silane compound include imidazole ring-containing silane compounds such as N-(3-triethoxysilypropyl)-4,5-dihydroimidazole.

The content of the curing catalyst [D] in the silicon-containing resist underlayer film-forming composition can be set to preferably 0.01 to 30 parts by mass, more preferably 0.01 to 25 parts by mass, and still more preferably 0.01 to 20 parts by mass with respect to 100 parts by mass of the polysiloxane [A] from the viewpoint of more sufficiently obtaining the effect of the present invention.

The mass ratio of the curing catalyst (component [D]) and the component [B] ([D]:[B]) in the silicon-containing resist underlayer film-forming composition can be set to preferably 0.1:1.0 to 1.0:0.1, more preferably 0.2:1.0 to 1.0:0.1, and still more preferably 0.5:1.0 to 1.0:0.15 from the viewpoint of more sufficiently obtaining the effect of the present invention.

### <Component [E]: Nitric Acid>

The silicon-containing resist underlayer film-forming composition preferably contains nitric acid [E].

Nitric acid [B] may be added at the time of preparing the silicon-containing resist underlayer film-forming composition, but in the production of the polysiloxane described above, nitric acid is used as a hydrolysis catalyst or at the time of alcohol capping of a silanol group, and nitric acid remaining in the polysiloxane varnish can also be treated as the nitric acid [E].

The blending amount (residual nitric acid amount) of the nitric acid [B] can be set to, for example, 0.0001 mass % to 1 mass %, or 0.001 mass % to 0.1 mass %, or 0.005 mass % to 0.05 mass % based on the total mass of the silicon-containing resist underlayer film-forming composition.

### <Component [F]: Amine, Hydroxide>

The silicon-containing resist underlayer film-forming composition preferably contains at least one selected from an amine and a hydroxide [F] from the viewpoint of more sufficiently obtaining the effect of the present invention.

Examples of the amine include ammonia; primary amines such as monomethanolamine, monoethanolamine, monopropanolamine, methylamine, ethylamine, propylamine, and butylamine; secondary amines such as dimethylamine, ethylmethylamine, and diethylamine; tertiary amines such as trimethylamine, triethylamine, tripropylamine, dimethylethylamine, methyldiisopropylamine, diisopropylethylamine, diethylethanolamine, and triethanolamine; amines such as ethylenediamine and tetramethylethylenediamine; cyclic amines such as pyridine and morpholine.

Examples of the hydroxide include an inorganic alkali hydroxide and an organic alkali hydroxide.

Examples of the inorganic alkali hydroxide include sodium hydroxide and potassium hydroxide.

Examples of the organic alkali hydroxide include a tetraalkylammonium hydroxide, a triarylsulfonium hydroxide, and a diaryliodonium hydroxide. Examples of the tetraalkylammonium hydroxide include tetramethylammonium hydroxide, tetraethylammonium hydroxide, and tetrabutylammonium hydroxide. Examples of the triarylsulfonium hydroxide include triphenylsulfonium hydroxide and tris(t-butylphenyl)sulfonium hydroxide. Examples of the diaryliodonium hydroxide include diphenyliodonium hydroxide and bis(t-butylphenyl)iodonium hydroxide.

The content of the component [F] in the silicon-containing resist underlayer film-forming composition can be set to preferably 0.05 to 20 parts by mass, more preferably 0.1 to 15 parts by mass, and still more preferably 0.5 to 10 parts by mass with respect to 100 parts by mass of the polysiloxane [A].

### <Other Additives>

In the silicon-containing resist underlayer film-forming composition, various additives can be blended depending on the use of the composition.

Examples of the additive include known additives blended in a material (composition) for forming various films that can be used for producing a semiconductor device, such as a resist underlayer film, an antireflection film, and a pattern inversion film, such as a crosslinking agent, a crosslinking catalyst, a stabilizer (such as an organic acid, water, or an alcohol), an organic polymer, an acid generator, a surfactant (such as a nonionic surfactant, an anionic surfactant, a cationic surfactant, a silicon-based surfactant, a fluorine-based surfactant, or a UV-curable surfactant), a pH adjusting agent, a metal oxide, a rheology modifier, and an adhesion aid.

Hereinafter, various additives will be exemplified, but the additives are not limited thereto.

### <<Stabilizer>>

The stabilizer may be added for the purpose of, for example, stabilizing the hydrolysis condensate of a hydrolyzable silane mixture, and as a specific example thereof, an organic acid, water, an alcohol, or a combination thereof can be added.

Examples of the organic acid include oxalic acid, malonic acid, methylmalonic acid, succinic acid, maleic acid, malic acid, tartaric acid, phthalic acid, citric acid, glutaric acid, lactic acid, and salicylic acid. Among them, oxalic acid and maleic acid are preferable. When the organic acid is added, the addition amount thereof is 0.1 to 5.0 mass % with respect to the mass of the hydrolysis condensate of a hydrolyzable silane mixture. These organic acids can also serve as pH adjusting agents.

As the water, pure water, ultrapure water, ion-exchanged water, or the like can be used, and when water is used, the addition amount thereof can be set to 1 to 20 parts by mass with respect to 100 parts by mass of the silicon-containing resist underlayer film-forming composition.

The alcohol is preferably one that is easily scattered by heating after application, and examples thereof include methanol, ethanol, propanol, i-propanol, and butanol. When the alcohol is added, the addition amount thereof can be set to 1 to 20 parts by mass with respect to 100 parts by mass of the silicon-containing resist underlayer film-forming composition.

### <<Organic Polymer>>

The organic polymer added to the silicon-containing resist underlayer film-forming composition can adjust the dry etching rate (the amount of reduction in film thickness per unit time), the attenuation coefficient, the refractive index, and the like of the film (resist underlayer film) formed from the composition. The organic polymer is not particularly limited, and is appropriately selected from various organic polymers (a polycondensation polymer and an addition polymerization polymer) according to the purpose of addition.

Specific examples thereof include addition polymerization polymers and polycondensation polymers such as polyester, polystyrene, polyimide, an acrylic polymer, a methacrylic polymer, polyvinyl ether, phenol novolac, naphthol novolac, polyether, polyamide, and polycarbonate.

In the present invention, an organic polymer containing an aromatic ring or a heteroaromatic ring such as a benzene ring, a naphthalene ring, an anthracene ring, a triazine ring, a quinoline ring, or a quinoxaline ring, which functions as a light absorption site, can also be suitably used when such a function is required. Specific examples of such an organic polymer include addition polymerization polymers containing, as a structural unit thereof, an addition polymerizable monomer such as benzyl acrylate, benzyl methacrylate, phenyl acrylate, naphthyl acrylate, anthryl methacrylate, anthrylmethyl methacrylate, styrene, hydroxystyrene, benzyl vinyl ether, or N-phenyl maleimide, and polycondensation polymers such as phenol novolac and naphthol novolac, but are not limited thereto.

When an addition polymerization polymer is used as the organic polymer, the polymer may be either a homopolymer or a copolymer.

An addition polymerizable monomer is used in the production of the addition polymerization polymer, and specific examples of such an addition polymerizable monomer include acrylic acid, methacrylic acid, an acrylic ester compound, a methacrylic ester compound, an acrylamide compound, a methacrylamide compound, a vinyl compound, a styrene compound, a maleimide compound, maleic anhydride, and acrylonitrile, but are not limited thereto.

Specific examples of the acrylic ester compound include methyl acrylate, ethyl acrylate, n-hexyl acrylate, i-propyl acrylate, cyclohexyl acrylate, benzyl acrylate, phenyl acrylate, anthrylmethyl acrylate, 2-hydroxyethyl acrylate, 3-chloro-2-hydroxypropyl acrylate, 2-hydroxypropyl acrylate, 2,2,2-trifluoroethyl acrylate, 2,2,2-trichloroethyl acrylate, 2-bromoethyl acrylate, 4-hydroxybutyl acrylate, 2-methoxyethyl acrylate, tetrahydrofurfuryl acrylate, 2-methyl-2-adamantyl acrylate, 5-acryloyloxy-6-hydroxynorbornene-2-carboxylic-6-lactone, 3-acryloxypropyl triethoxysilane, and glycidyl acrylate, but are not limited thereto.

Specific examples of the methacrylic ester compound include methyl methacrylate, ethyl methacrylate, n-hexyl methacrylate, i-propyl methacrylate, cyclohexyl methacrylate, benzyl methacrylate, phenyl methacrylate, anthrylmethyl methacrylate, 2-hydroxyethyl methacrylate, 2-hydroxypropyl methacrylate, 2,2,2-trifluoroethyl methacrylate, 2,2,2-trichloroethyl methacrylate, 2-bromoethyl methacrylate, 4-hydroxybutyl methacrylate, 2-methoxyethyl methacrylate, tetrahydrofurfuryl methacrylate, 2-methyl-2-adamantyl methacrylate, 5-methacryloyloxy-6-hydroxynorbornene-2-carboxylic-6-lactone, 3-methacryloxypropyl triethoxysilane, glycidyl methacrylate, 2-phenylethyl methacrylate, hydroxyphenyl methacrylate, and bromophenyl methacrylate, but are not limited thereto.

Specific examples of the acrylamide compound include acrylamide, N-methylacrylamide, N-ethylacrylamide, N-benzylacrylamide, N-phenylacrylamide, N,N-dimethylacrylamide, and N-anthrylacrylamide, but are not limited thereto.

Specific examples of the methacrylamide compound include methacrylamide, N-methylmethacrylamide, N-ethylmethacrylamide, N-benzylmethacrylamide, N-phenylmethacrylamide, N,N-dimethylmethacrylamide, and N-anthrylmethacrylamide, but are not limited thereto.

Specific examples of the vinyl compound include vinyl alcohol, 2-hydroxyethyl vinyl ether, methyl vinyl ether, ethyl vinyl ether, benzyl vinyl ether, vinyl acetic acid, vinyl trimethoxysilane, 2-chloroethyl vinyl ether, 2-methoxyethyl vinyl ether, vinyl naphthalene, and vinyl anthracene, but are not limited thereto.

Specific examples of the styrene compound include styrene, hydroxystyrene, chlorostyrene, bromostyrene, methoxystyrene, cyanostyrene, and acetylstyrene, but are not limited thereto.

Examples of the maleimide compound include maleimide, N-methylmaleimide, N-phenylmaleimide, N-cyclohexylmaleimide, N-benzylmaleimide, and N-hydroxyethylmaleimide, but are not limited thereto.

When a polycondensation polymer is used as the polymer, examples of such a polymer include a polycondensation polymer of a glycol compound and a dicarboxylic acid compound. Examples of the glycol compound include diethylene glycol, hexamethylene glycol, and butylene glycol. Examples of the dicarboxylic acid compound include succinic acid, adipic acid, terephthalic acid, and maleic anhydride. In addition, examples thereof include polyesters, polyamides, and polyimides such as polypyrromellitimide, poly(p-phenylene terephthalamide), polybutylene terephthalate, and polyethylene terephthalate, but are not limited thereto.

When the organic polymer contains a hydroxy group, the hydroxy group can undergo a crosslinking reaction with a hydrolysis condensate or the like.

The weight average molecular weight of the organic polymer can be usually set to 1,000 to 1,000,000. When an organic polymer is blended, the weight average molecular weight thereof can be set to, for example, 3,000 to 300,000, or 5,000 to 300,000, or 10,000 to 200,000 from the viewpoint of sufficiently obtaining the effect of the function as a polymer and preventing precipitation in the composition.

As such an organic polymer, one type can be used alone, or two or more types can be used in combination.

When the silicon-containing resist underlayer film-forming composition contains an organic polymer, the content thereof is appropriately determined in consideration of the function of the organic polymer and the like, and thus cannot be generally defined, but usually can be set in the range of 1 to 200 mass % with respect to the mass of the polysiloxane [A], and can be set to, for example, 100 mass % or less, preferably 50 mass % or less, and more preferably 30 mass % or less from the viewpoint of preventing precipitation in the composition and the like, and can be set to, for example, 5 mass % or more, preferably 10 mass % or more, and more preferably 30 mass % or more from the viewpoint of sufficiently obtaining the effect and the like.

### <<Acid Generator>>

Examples of the acid generator include a thermal acid generator and a photoacid generator, and a photoacid generator can be preferably used.

Examples of the photoacid generator include onium salt compounds such as a sulfonium salt, a phosphonium salt, an ammonium salt, an iodonium salt, and an oxonium salt, a sulfonimide compound, and a disulfonyldiazomethane compound, but are not limited thereto. The photoacid generator can also function as a curing catalyst depending on the type thereof, for example, a nitrate, a carboxylate such as a maleate, and a hydrochloride in the onium salt compound described later.

Examples of the thermal acid generator include tetramethylammonium nitrate, but are not limited thereto.

Specific examples of the onium salt compound include iodonium salt compounds such as diphenyliodonium hexafluorophosphate, diphenyliodonium trifluoromethanesulfonate, diphenyliodonium nonafluoro-n-butanesulfonate, diphenyliodonium perfluoro-n-octanesulfonate, diphenyliodonium camphor sulfonate, bis(4-t-butylphenyl)iodonium camphor sulfonate, and bis(4-t-butylphenyl)iodonium trifluoromethanesulfonate, and sulfonium salt compounds such as triphenylsulfonium hexafluoroantimonate, triphenylsulfonium nonafluoro-n-butanesulfonate, triphenylsulfonium camphor sulfonate, triphenylsulfonium trifluoromethanesulfonate, triphenylsulfonium nitrate, triphenylsulfonium trifluoroacetate, triphenylsulfonium maleate, and triphenylsulfonium chloride, but are not limited thereto.

Specific examples of the sulfonimide compound include N-(trifluoromethanesulfonyloxy)succinimide, N-(nonafluoro-n-butanesulfonyloxy)succinimide, N-(camphorsulfonyloxy)succinimide, and N-(trifluoromethanesulfonyloxy)naphthalimide, but are not limited thereto.

Specific examples of the disulfonyl diazomethane compound include bis(trifluoromethylsulfonyl)diazomethane, bis(cyclohexylsulfonyl)diazomethane, bis(phenylsulfonyl)diazomethane, bis(p-toluenesulfonyl)diazomethane, bis(2,4-dimethylbenzenesulfonyl)diazomethane, and methylsulfonyl-p-toluenesulfonyl diazomethane, but are not limited thereto.

When the silicon-containing resist underlayer film-forming composition contains an acid generator, the content thereof is appropriately determined in consideration of the type of the acid generator and the like, and thus cannot be generally defined, but is usually in the range of 0.01 to 5 mass % with respect to the mass of the polysiloxane [A], and is preferably 3 mass % or less, more preferably 1 mass % or less from the viewpoint of preventing precipitation of the acid generator in the composition and the like, and is preferably 0.1 mass % or more, more preferably 0.5 mass % or more from the viewpoint of sufficiently obtaining the effect and the like.

As the acid generator, one type can be used alone or two or more types can be used in combination, and a photoacid generator and a thermal acid generator may be used in combination.

### <<Surfactant>>

The surfactant is effective for preventing generation of a pinhole, a striation, or the like when the silicon-containing resist underlayer film-forming composition is applied to a substrate. Examples of the surfactant include a nonionic surfactant, an anionic surfactant, a cationic surfactant, a silicon-based surfactant, a fluorine-based surfactant, and a UV-curable surfactant. More specific examples thereof include nonionic surfactants such as polyoxyethylene alkyl ethers such as polyoxyethylene lauryl ether, polyoxyethylene stearyl ether, polyoxyethylene cetyl ether, and polyoxyethylene oleyl ether, polyoxyethylene alkyl aryl ethers such as polyoxyethylene octylphenol ether and polyoxyethylene nonylphenol ether, polyoxyethylene-polyoxypropylene block copolymers, sorbitan fatty acid esters such as sorbitan monolaurate, sorbitan monopalmitate, sorbitan monostearate, sorbitan monooleate, sorbitan trioleate, and sorbitan tristearate, and polyoxyethylene sorbitan fatty acid esters such as polyoxyethylene sorbitan monolaurate, polyoxyethylene sorbitan monopalmitate, polyoxyethylene sorbitan monostearate, polyoxyethylene sorbitan trioleate, and polyoxyethylene sorbitan tristearate, fluorine-based surfactants such as trade names EFTOP (registered trademark) EF301, EF303, and EF352 (manufactured by Mitsubishi Materials Electronic Chemicals Co., Ltd. (former Tochem Products)), trade names MEGAFACE (registered trademark) F171, F173, R-08, R-30, R-30N, and R-40 LM (manufactured by DIC Corporation), Fluorad FC430 and FC431 (manufactured by 3M Japan Limited), trade name AsahiGuard (registered trademark) AG710 (manufactured by AGC Inc.), and Surflon (registered trademark) 5-382, SC101, SC102, SC103, SC104, SC105, and SC106 (manufactured by AGC SEIMI CHEMICAL CO., LTD.), and organosiloxane polymer KP341 (manufactured by Shin-Etsu Chemical Co., Ltd.), but are not limited thereto.

As the surfactant, one type can be used alone, or two or more types can be used in combination.

When the silicon-containing resist underlayer film-forming composition contains a surfactant, the content thereof is usually 0.0001 to 5 mass %, and can be set to preferably 0.001 to 4 mass %, more preferably 0.01 to 3 mass % with respect to the mass of the polysiloxane [A].

### <<Rheology Modifier>>

The rheology modifier is added mainly for the purpose of improving the fluidity of the silicon-containing resist underlayer film-forming composition, and particularly in the baking step, for the purpose of improving the film thickness uniformity of the film to be formed and enhancing the filling property of the composition into a hole. Specific examples thereof include phthalic acid derivatives such as dimethyl phthalate, diethyl phthalate, di-i-butyl phthalate, dihexyl phthalate, and butyl i-decyl phthalate, adipic acid derivatives such as di-n-butyl adipate, di-i-butyl adipate, di-i-octyl adipate, and octyl decyl adipate, maleic acid derivatives such as di-n-butyl malate, diethyl malate, and dinonyl malate, oleic acid derivatives such as methyl olate, butyl olate, and tetrahydrofurfuryl olate, and stearic acid derivatives such as n-butyl stearate and glyceryl stearate.

When these rheology modifiers are used, the addition amount thereof is usually less than 30 mass % with respect to all film-forming components of the silicon-containing resist underlayer film-forming composition.

### <<Adhesion Aid>>

The adhesion aid is added mainly for the purpose of improving adhesion between the substrate or the resist and a film (resist underlayer film) formed from the silicon-containing resist underlayer film-forming composition, and particularly for the purpose of suppressing or preventing peeling of the resist in development. Specific examples include chlorosilanes such as trimethylchlorosilane, dimethylvinylchlorosilane, methyldiphenylchlorosilane, and chloromethyldimethylchlorosilane, alkoxysilanes such as trimethylmethoxysilane, dimethyldiethoxysilane, methyldimethoxysilane, and dimethylvinylethoxysilane, silazanes such as hexamethyldisilazane, N,N′-bis(trimethylsilyl)urea, dimethyltrimethylsilylamine, and trimethylsilyl imidazole, other silanes such as γ-chloropropyltrimethoxysilane, γ-aminopropyltriethoxysilane, and γ-glycidoxypropyltrimethoxysilane, heterocyclic compounds such as benzotriazole, benzimidazole, indazole, imidazole, 2-mercaptobenzimidazole, 2-mercaptobenzothiazole, 2-mercaptobenzoxazole, urazole, thiouracil, mercaptoimidazole, and mercaptopyrimidine, ureas such as 1,1-dimethylurea and 1,3-dimethylurea, and thiourea compounds.

When these adhesion aids are used, the addition amount thereof is usually less than 5 mass %, preferably less than 2 mass % with respect to the film-forming components of the silicon-containing resist underlayer film-forming composition.

### <<pH Adjusting Agent>>

In addition, examples of the pH adjusting agent include acids having one or two or more carboxylic acid groups such as the organic acid mentioned above as the stabilizer, and others. When the pH adjusting agent is used, the addition amount thereof can be set to 0.01 to 20 parts by mass, 0.01 to 10 parts by mass, or 0.01 to 5 parts by mass with respect to 100 parts by mass of the polysiloxane [A].

### <<Metal Oxide>>

Examples of the metal oxide that can be added to the silicon-containing resist underlayer film-forming composition include an oxide of one type or a combination of two or more types among metals such as tin (Sn), titanium (Ti), aluminum (Al), zirconium (Zr), zinc (Zn), niobium (Nb), tantalum (Ta), and tungsten (W), and metalloids such as boron (B), silicon (Si), germanium (Ge), arsenic (As), antimony (Sb), and tellurium (Te), but are not limited thereto.

The concentration of the film-forming component in the silicon-containing resist underlayer film-forming composition can be set to, for example, 0.01 to 50 mass %, 0.01 to 30 mass %, 0.01 to 25 mass %, or 0.01 to 20.0 mass % with respect to the total mass of the composition.

The content of the polysiloxane [A] in the film-forming component is usually 20 mass % to 100 mass %, but from the viewpoint of obtaining the effect of the present invention with good reproducibility, the lower limit thereof is preferably 50 mass %, more preferably 60 mass %, still more preferably 70 mass %, and even more preferably 80 mass %, the upper limit thereof is preferably 99 mass %, and the rest can be additives described later.

In addition, the silicon-containing resist underlayer film-forming composition preferably has a pH of 1 to 5, and more preferably has a pH of 2 to 4.

In the present invention, filtration may be performed using a submicrometer-order filter or the like at a stage in the middle of producing the silicon-containing resist underlayer film-forming composition or after mixing all the components. Although the material type of the filter used at this time is not limited, for example, a polyethylene filter, a nylon filter, a fluororesin filter, a polyimide filter, or the like can be used.

The silicon-containing resist underlayer film-forming composition of the present invention can be suitably used as a composition for forming a resist underlayer film used in a lithography process.

### (Resist Underlayer Film, Semiconductor Processing Substrate, Pattern Forming Method, and Method for Producing Semiconductor Element)

The resist underlayer film of the present invention is a cured product of the silicon-containing resist underlayer film-forming composition of the present invention.

The semiconductor processing substrate of the present invention includes, for example, the silicon-containing resist underlayer film of the present invention.

The method for producing a semiconductor element of the present invention includes steps of:
forming an organic underlayer film on a substrate;
forming a resist underlayer film on the organic underlayer film using the silicon-containing resist underlayer film-forming composition of the present invention; and
forming a metal-containing resist film on the resist underlayer film.

The pattern forming method of the present invention includes, for example, steps of:
forming an organic underlayer film on a semiconductor substrate;
forming a resist underlayer film on the organic underlayer film by applying and baking the silicon-containing resist underlayer film-forming composition of the present invention;
forming a metal-containing resist film on the resist underlayer film;
exposing and developing the metal-containing resist film to obtain a resist pattern;
etching the resist underlayer film using the resist pattern as a mask; and
etching the organic underlayer film using the patterned resist underlayer film as a mask.

Hereinafter, as one aspect of the present invention, a semiconductor processing substrate, a pattern forming method, and a method for producing a semiconductor element using the silicon-containing resist underlayer film of the present invention or the silicon-containing resist underlayer film-forming composition of the present invention will be described.

First, the silicon-containing resist underlayer film-forming composition of the present invention is applied onto a substrate used for producing a precision integrated circuit element [for example, a semiconductor substrate such as a silicon wafer coated with a silicon oxide film, a silicon nitride film, or a silicon oxynitride film, a silicon nitride substrate, a quartz substrate, a glass substrate (including alkali-free glass, low-alkali glass, and crystallized glass), a glass substrate on which an indium tin oxide (ITO) film or an indium zinc oxide (IZO) film is formed, a plastic (polyimide, PET, or the like) substrate, a low dielectric constant material (low-k material)-coated substrate, a flexible substrate, or the like] by an appropriate application method such as a spinner or a coater, and then baked using a heating means such as a hot plate to form a cured product of the composition, thereby forming a resist underlayer film. Hereinafter, in the present description, the resist underlayer film refers to the silicon-containing resist underlayer film of the present invention or a film formed from the silicon-containing resist underlayer film-forming composition of the present invention.

The baking conditions are appropriately selected from a baking temperature of 40° C. to 400° C., or 80° C. to 250° C., and a baking time of 0.3 minutes to 60 minutes. Preferably, the baking temperature is 150° C. to 250° C., and the baking time is 0.5 minutes to 2 minutes.

The film thickness of the resist underlayer film formed here is, for example, 10 nm to 1,000 nm, or 20 nm to 500 nm, or 50 nm to 300 nm, or 100 nm to 200 nm, or 10 to 150 nm.

As the silicon-containing resist underlayer film-forming composition to be used at the time of forming the resist underlayer film, a silicon-containing resist underlayer film-forming composition filtered through a nylon filter can be used. Here, the silicon-containing resist underlayer film-forming composition filtered through a nylon filter refers to a composition that has been filtered through a nylon filter at a stage in the middle of producing the silicon-containing resist underlayer film-forming composition or after mixing all the components.

One aspect of the present invention is an aspect in which an organic underlayer film is formed on a substrate and then a resist underlayer film is formed thereon, but can be an aspect in which an organic underlayer film is not provided in some cases.

The organic underlayer film used here is not particularly limited, and can be arbitrarily selected and used from those conventionally used in a lithography process.

By adopting an aspect in which an organic underlayer film is provided on a substrate, a resist underlayer film is provided thereon, and a metal-containing resist film described later is provided thereon, the pattern width of the metal-containing resist film is narrowed, and even when the metal-containing resist film is thinly covered in order to prevent pattern collapse, the substrate can be processed by selecting an appropriate etching gas described later. For example, the resist underlayer film can be processed using a fluorine-based gas having a sufficiently high etching rate with respect to the metal-containing resist film as an etching gas, the organic underlayer film can be processed using an oxygen-based gas having a sufficiently high etching rate with respect to the resist underlayer film as an etching gas, and the substrate can be processed using a fluorine-based gas having a sufficiently high etching rate with respect to the organic underlayer film as an etching gas.

Examples of the substrate and the coating method that can be used at this time include the same ones as described above.

Subsequently, for example, a layer of a metal-containing resist material (metal-containing resist film) is formed on the resist underlayer film. The metal-containing resist film can be formed by a known method, that is, by applying a coating type resist material (metal-containing resist film-forming composition), which is a metal-containing resist, on the resist underlayer film and baking the coating type resist material.

The film thickness of the metal-containing resist film is, for example, 5 nm to 10,000 nm, or 5 nm to 1,000 nm, or 5 nm to 40 nm.

The metal-containing resist is also called a metal oxide resist (metal oxide resist (MOR)), and typical examples thereof include a tin oxide-based resist.

Examples of the metal oxide resist material include a coating composition containing a metal oxo-hydroxo network having an organic ligand through a metal carbon bond and/or a metal carboxylate bond described in JP 2019-113855 A.

In an example of a metal-containing resist, a peroxo ligand is used as a radiation-sensitive stabilizing ligand. The details of the peroxo-based metal oxo-hydroxo compound are described, for example, in Patent Literature described in paragraph [0011] of JP 2019-532489 A. Examples of the patent literature include U.S. Pat. No. 9,176,377 B2, US 2013/0224652 A1, U.S. Pat. No. 9,310,684 B2, US 2016/0116839 A1, and U.S. Ser. No. 15/291,738 A.

Subsequently, the metal-containing resist film formed on the resist underlayer film is exposed through a predetermined mask (reticle). For the exposure, a KrF excimer laser (wavelength: 248 nm), an ArF excimer laser (wavelength: 193 nm), an F₂ excimer laser (wavelength: 157 nm), EUV (wavelength: 13.5 nm), an electron beam, or the like can be used.

After the exposure, post exposure bake may be performed as necessary. The post exposure bake is performed under conditions appropriately selected from a heating temperature of 70° C. to 250° C. and a heating time of 0.3 minutes to 10 minutes.

In the present invention, an organic solvent can be used as a developer, and development is performed with the developer (solvent) after exposure. As a result, for example, when a metal-containing negative resist film is used, the metal-containing resist film in an unexposed portion is removed, and a pattern of the metal-containing resist film is formed.

Examples of the developer (organic solvent) include methyl acetate, butyl acetate, ethyl acetate, isopropyl acetate, amyl acetate, isoamyl acetate, ethyl methoxyacetate, ethyl ethoxyacetate, propylene glycol monomethyl ether acetate, ethylene glycol monoethyl ether acetate, ethylene glycol monopropyl ether acetate, ethylene glycol monobutyl ether acetate, ethylene glycol monophenyl ether acetate, diethylene glycol monomethyl ether acetate, diethylene glycol monopropyl ether acetate, diethylene glycol monoethyl ether acetate, diethylene glycol monophenyl ether acetate, diethylene glycol monobutyl ether acetate, diethylene glycol monoethyl ether acetate, 2-methoxybutyl acetate, 3-methoxybutyl acetate, 4-methoxybutyl acetate, 3-methyl-3-methoxybutyl acetate, 3-ethyl-3-methoxybutyl acetate, propylene glycol monomethyl ether acetate, propylene glycol monoethyl ether acetate, propylene glycol monopropyl ether acetate, 2-ethoxybutyl acetate, 4-ethoxybutyl acetate, 4-propoxybutyl acetate, 2-methoxypentyl acetate, 3-methoxypentyl acetate, 4-methoxypentyl acetate, 2-methyl-3-methoxypentyl acetate, 3-methyl-3-methoxypentyl acetate, 3-methyl-4-methoxypentyl acetate, 4-methyl-4-methoxypentyl acetate, propylene glycol diacetate, methyl formate, ethyl formate, butyl formate, propyl formate, ethyl lactate, butyl lactate, propyl lactate, ethyl carbonate, propyl carbonate, butyl carbonate, methyl pyruvate, ethyl pyruvate, propyl pyruvate, butyl pyruvate, methyl acetoacetate, ethyl acetoacetate, methyl propionate, ethyl propionate, propyl propionate, isopropyl propionate, methyl 2-hydroxypropionate, ethyl 2-hydroxypropionate, methyl-3-methoxypropionate, ethyl-3-methoxypropionate, ethyl-3-ethoxypropionate, and propyl-3-methoxypropionate. Further, a surfactant or the like can also be added to these developers. As conditions for development, the temperature is appropriately selected from 5° C. to 50° C., and the time is appropriately selected from 10 seconds to 600 seconds.

The resist underlayer film (intermediate layer) is removed using the pattern of the metal-containing resist film (upper layer) formed in this manner as a protective film, and then the organic underlayer film (lower layer) is removed using a film including the patterned metal-containing resist film and the patterned resist underlayer film (intermediate layer) as a protective film. Finally, the substrate is processed using the patterned resist underlayer film (intermediate layer) and the patterned organic underlayer film (lower layer) as protective films.

Removal (patterning) of the resist underlayer film (intermediate layer) performed using the pattern of the metal-containing resist film (upper layer) as the protective film is performed by dry etching, and a gas such as tetrafluoromethane (CF₄), perfluorocyclobutane (C₄F₈), perfluoropropane (C₃F₈), trifluoromethane, carbon monoxide, argon, oxygen, nitrogen, sulfur hexafluoride, difluoromethane, nitrogen trifluoride, chlorine trifluoride, chlorine, trichloroborane, or dichloroborane can be used.

A halogen-based gas is preferably used for dry etching of the resist underlayer film. In dry etching using a halogen-based gas, it is basically difficult to remove the metal-containing resist film. On the other hand, the resist underlayer film rich in silicon atoms is quickly removed with a halogen-based gas. Therefore, a decrease in the film thickness of the metal-containing resist film due to dry etching of the resist underlayer film can be prevented. As a result, the metal-containing resist film can be used as a thin film. Therefore, the dry etching of the resist underlayer film is preferably performed with a fluorine-based gas, and examples of the fluorine-based gas include tetrafluoromethane (CF₄), perfluorocyclobutane (C₄F₈), perfluoropropane (C₃F₈), trifluoromethane, and difluoromethane (CH₂F₂), but are not limited thereto.

When the organic underlayer film is provided between the substrate and the resist underlayer film, the organic underlayer film (lower layer) is preferably removed (patterned) by dry etching with an oxygen-based gas (oxygen gas, oxygen/carbonyl sulfide (COS) mixed gas, or the like), which is subsequently performed using a film including the patterned resist underlayer film (intermediate layer) as a protective film (together with the patterned metal-containing resist film (upper layer) when it remains). This is because it is difficult to remove the resist underlayer film of the present invention rich in silicon atoms by dry etching with an oxygen-based gas.

Thereafter, the processing (patterning) of the (semiconductor) substrate performed using the patterned resist underlayer film (intermediate layer) and, if desired, the patterned organic underlayer film (lower layer) as protective films is preferably performed by dry etching with a fluorine-based gas.

Examples of the fluorine-based gas include tetrafluoromethane (CF₄), perfluorocyclobutane (C₄F₈), perfluoropropane (C₃F₈), trifluoromethane, and difluoromethane (CH₂F₂).

After the removal (patterning) of the organic underlayer film or after the processing (patterning) of the substrate, the resist underlayer film may be removed. The resist underlayer film may be removed by dry etching or wet etching (wet method).

The dry etching of the resist underlayer film is preferably performed with a fluorine-based gas as mentioned in the patterning, and examples thereof include tetrafluoromethane (CF₄), perfluorocyclobutane (C₄F₈), perfluoropropane (C₃F₈), trifluoromethane, and difluoromethane (CH₂F₂), but are not limited thereto.

Examples of a chemical liquid used for wet etching of the resist underlayer film include alkaline solutions such as dilute fluorinated acid (hydrofluoric acid), buffered fluorinated acid (mixed solution of HF and NH₄F), an aqueous solution containing hydrochloric acid and hydrogen peroxide (SC-2 chemical liquid), an aqueous solution containing sulfuric acid and hydrogen peroxide (SPM chemical liquid), an aqueous solution containing fluorinated acid and hydrogen peroxide (FPM chemical liquid), and an aqueous solution containing ammonia and hydrogen peroxide (SC-1 chemical liquid). Examples of the alkaline solution include, in addition to the ammonia hydrogen peroxide obtained by mixing ammonia, aqueous hydrogen peroxide, and water (SC-1 chemical liquid), an aqueous solution containing 1 to 99 mass % of ammonia, tetramethylammonium hydroxide (TMAH), tetraethylammonium hydroxide, tetrapropylammonium hydroxide, tetrabutylammonium hydroxide, choline hydroxide, benzyltrimethylammonium hydroxide, benzyltriethylammonium hydroxide, DBU (diazabicycloundecene), DBN (diazabicyclononene), hydroxylamine, 1-butyl-1-methylpyrrolidinium hydroxide, 1-propyl-1-methylpyrrolidinium hydroxide, 1-butyl-1-methylpiperidinium hydroxide, 1-propyl-1-methylpiperidinium hydroxide, mepiquat hydroxide, trimethylsulfonium hydroxide, a hydrazine, an ethylenediamine, or guanidine. These chemical liquids can also be used in admixture.

An organic antireflection film can be formed on the resist underlayer film before the metal-containing resist film is formed. The antireflection film composition to be used is not particularly limited, and for example, the antireflection film composition can be arbitrarily selected and used from those conventionally used in a lithography process, and the antireflection film can be formed by a commonly used method, for example, coating and baking using a spinner and a coater.

In addition, the substrate to which the silicon-containing resist underlayer film-forming composition is applied may have an organic or inorganic antireflection film formed by a CVD method or the like on the surface thereof, and the resist underlayer film can be formed thereon. When the organic underlayer film is formed on the substrate and then the resist underlayer film of the present invention is formed thereon, the substrate to be used may have an organic or inorganic antireflection film formed by a CVD method or the like on the surface thereof.

The resist underlayer film formed from the silicon-containing resist underlayer film-forming composition may also absorb light depending on the wavelength of the light used in a lithography process. In such a case, it is possible to function as an antireflection film having an effect of preventing reflected light from the substrate.

Furthermore, the resist underlayer film can also be used as a layer for preventing interaction between the substrate and the metal-containing resist film, a layer having a function of preventing an adverse effect on the substrate of a material used for the metal-containing resist film or a substance generated at the time of exposure to the metal-containing resist film, a layer having a function of preventing diffusion of a substance generated from the substrate to the metal-containing resist film at the time of heating and baking, a barrier layer for reducing the poisoning effect of the metal-containing resist film by the semiconductor substrate dielectric layer, or the like.

The resist underlayer film can be applied to a substrate on which via holes used in a dual damascene process are formed, and can be used as a hole-filling material (filling material) capable of filling the holes without gaps. In addition, it can also be used as a planarizing material for planarizing the surface of a semiconductor substrate having irregularities.

In addition, the resist underlayer film of the present invention serves as an underlayer film for an EUV metal-containing resist film and, for example, can prevent reflection of exposure light undesirable for EUV exposure (wavelength 13.5 nm), for example, UV (ultraviolet) light or DUV (deep ultraviolet) light (ArF light and KrF light) from the substrate or the interface without intermixing with the EUV metal-containing resist film, in addition to the function as a hard mask. Therefore, in order to form an underlayer antireflection film of an EUV metal-containing resist film, the silicon-containing resist underlayer film-forming composition of the present invention can be suitably used. That is, reflection can be efficiently prevented as an underlayer of an EUV metal-containing resist film. When the resist underlayer film is used as an EUV resist underlayer film, the process can be performed in the same manner as an underlayer film for a photoresist.

When the semiconductor processing substrate including the resist underlayer film of the present invention described above and a semiconductor substrate is used, the semiconductor substrate can be suitably processed.

In addition, according to the method for producing a semiconductor element, the method including a step of forming an organic underlayer film, a step of forming a resist underlayer film on the organic underlayer film using the silicon-containing resist underlayer film-forming composition of the present invention, and a step of forming a metal-containing resist film on the resist underlayer film, a high-precision semiconductor substrate can be processed with good reproducibility, and it is expected that a semiconductor element can be stably produced.

### EXAMPLES

Hereinafter, the present invention will be described more specifically with reference to synthesis examples and examples, but the present invention is not limited to only the following examples.

In examples, devices and conditions used for analyzing physical properties of a sample are as follows.

### (1) Measurement of Molecular Weight

The molecular weight of a polysiloxane used in the present invention is a molecular weight obtained in terms of polystyrene by GPC analysis.

Measurement was performed under GPC measurement conditions using a GPC apparatus (trade name: HLC-8220GPC, manufactured by Tosoh Corporation), a GPC column (trade name: Shodex (registered trademark) KF803L, KF802, KF801, manufactured by Showa Denko K.K.), a column temperature of 40° C., with tetrahydrofuran as an eluent (elution solvent), at a flow amount (flow rate) of 1.0 mL/min, with polystyrene (manufactured by Showa Denko K.K.) as a standard sample.

### (2) ¹H-NMR

Evaluation was performed using a nuclear magnetic resonance apparatus ¹H-NMR (400 MHz) manufactured by JEOL, and d6-Acetone as a solvent.

Evaluation was performed using e.

### [1] Synthesis of Polymer (Hydrolysis Condensate)

A 300 ml flask was charged with 20.8 g of tetraethoxysilane, 7.6 g of methyltriethoxysilane, and 52.9 g of propylene glycol monoethyl ether, and while the resulting mixed solution was stirred with a magnetic stirrer, 8.4 g of a 0.2 M nitric acid aqueous solution was added dropwise thereto.

After the dropwise addition, the flask was transferred to an oil bath adjusted to 60° C. and the mixture was refluxed for 20 hours. Thereafter, ethanol and water as reaction by-products were distilled off under reduced pressure and the residue was concentrated to obtain a hydrolysis condensate (polymer) aqueous solution.

Further, propylene glycol monoethyl ether was added thereto, and the concentration was adjusted so that the solvent ratio of 100% of propylene glycol monoethyl ether was 20 mass % in terms of solid residue at 150° C., followed by filtration through a nylon filter (pore size: 0.1 μm). The obtained polymer contained a structure represented by the following formula (E1), and the weight average molecular weight thereof was Mw: 2,300 in terms of polystyrene by GPC.

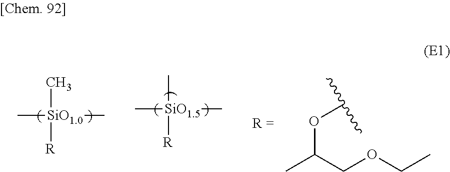

### Synthesis Example 2

A 300 ml flask was charged with 20.8 g of tetraethoxysilane, 5.1 g of methyltriethoxysilane, 2.8 g of phenyltrimethoxysilane, and 53.4 g of propylene glycol monoethyl ether, and while the resulting mixed solution was stirred with a magnetic stirrer, 8.4 g of a 0.2 M nitric acid aqueous solution was added dropwise thereto.

After the dropwise addition, the flask was transferred to an oil bath adjusted to 60° C. and the mixture was refluxed for 20 hours. Thereafter, ethanol, methanol, and water as reaction by-products were distilled off under reduced pressure and the residue was concentrated to obtain a hydrolysis condensate (polymer) aqueous solution.

Further, propylene glycol monoethyl ether was added thereto, and the concentration was adjusted so that the solvent ratio of 100% of propylene glycol monoethyl ether was 20 mass % in terms of solid residue at 150° C., followed by filtration through a nylon filter (pore size: 0.1 μm). The obtained polymer contained a structure represented by the following formula (E2), and the weight average molecular weight thereof was Mw: 2,700 in terms of polystyrene by GPC.

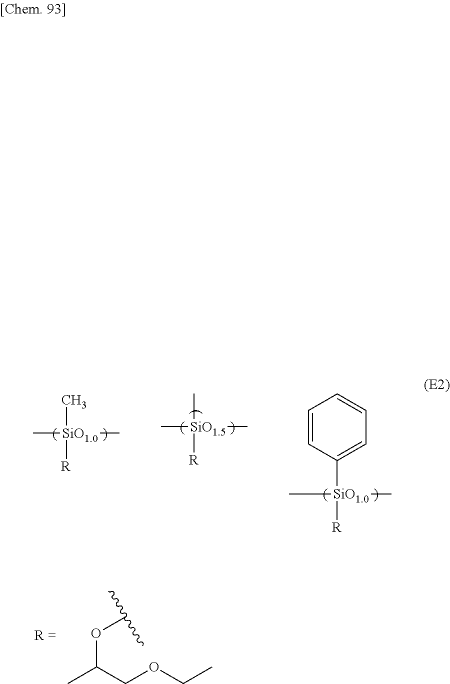

### Synthesis Example 3

A 300 ml flask was charged with 20.8 g of tetraethoxysilane, 5.1 g of methyltriethoxysilane, 3.7 g of 5-(triethoxysilyl)-2-norbornene, and 53.4 g of propylene glycol monoethyl ether, and while the resulting mixed solution was stirred with a magnetic stirrer, 8.4 g of a 0.2 M nitric acid aqueous solution was added dropwise thereto.

After the dropwise addition, the flask was transferred to an oil bath adjusted to 60° C. and the mixture was refluxed for 20 hours. Thereafter, ethanol and water as reaction by-products were distilled off under reduced pressure and the residue was concentrated to obtain a hydrolysis condensate (polymer) aqueous solution.

Further, propylene glycol monoethyl ether was added thereto, and the concentration was adjusted so that the solvent ratio of 100% of propylene glycol monoethyl ether was 20 mass % in terms of solid residue at 150° C., followed by filtration through a nylon filter (pore size: 0.1 μm). The obtained polymer contained a structure represented by the following formula (E3), and the weight average molecular weight thereof was Mw: 2,200 in terms of polystyrene by GPC.

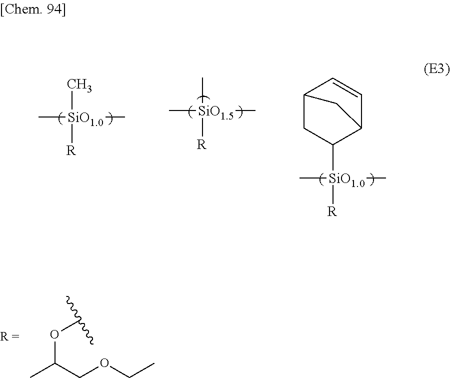

### Synthesis Example 4

A 300 ml flask was charged with 20.8 g of tetraethoxysilane, 5.1 g of methyltriethoxysilane, 5.9 g of diallyl isocyanurate propyltriethoxysilane, and 59.1 g of propylene glycol monoethyl ether, and while the resulting mixed solution was stirred with a magnetic stirrer, 8.4 g of a 0.2 M nitric acid aqueous solution was added dropwise thereto.

After the dropwise addition, the flask was transferred to an oil bath adjusted to 60° C. and the mixture was refluxed for 20 hours. Thereafter, ethanol and water as reaction by-products were distilled off under reduced pressure and the residue was concentrated to obtain a hydrolysis condensate (polymer) aqueous solution.

Further, propylene glycol monoethyl ether was added thereto, and the concentration was adjusted so that the solvent ratio of 100% of propylene glycol monoethyl ether was 20 mass % in terms of solid residue at 150° C., followed by filtration through a nylon filter (pore size: 0.1 μm). The obtained polymer contained a structure represented by the following formula (E4), and the weight average molecular weight thereof was Mw: 2,300 in terms of polystyrene by GPC.

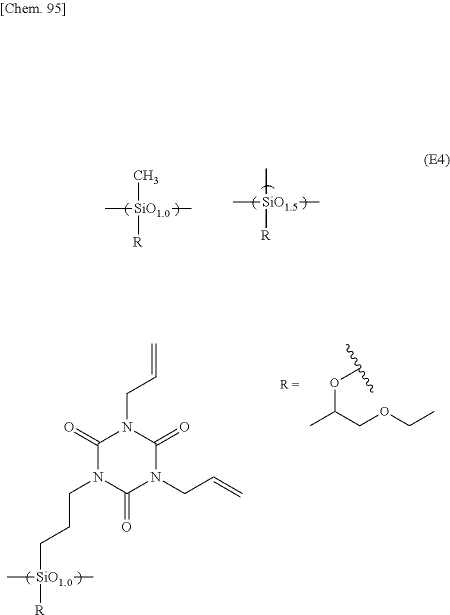

### [2] Preparation of Silicon-Containing Resist Underlayer Film-Forming Composition

The polysiloxane (polymer) obtained in the above synthesis example, an acid (additive 1), a curing catalyst (additive 2), sulfuric acid, a sulfonic acid compound, or a salt thereof (additive 3), and a solvent were mixed in the ratio shown in Table 1, and the mixture was filtered through a 0.1 μm fluororesin filter to prepare each silicon-containing resist underlayer film-forming composition. Each addition amount in Table 1 is shown in parts by mass.

The composition was prepared such that the hydrolysis condensate (polymer) was a solution containing the condensate obtained in synthesis example. However, the addition ratio of the polymer in Table 1 is not the addition amount of the polymer solution but the addition amount of the polymer itself.

The meanings of the abbreviations in Table 1 are as follows.

### <Solvent>

DIW: ultrapure water
PGEE: propylene glycol monoethyl ether
PGME: propylene glycol monomethyl ether

### <Additive 1>

MA: maleic acid

### <Additive 2>

TPSNO3: triphenylsulfonium nitrate

### <Additive 3>

PrDSA: 1,3-propanedisulfonic acid
BiPhDSA: 4,4-biphenyldisulfonic acid
NaphDSA: 1,5-naphthalenedisulfonic acid
SA: Sulfuric acid
TPS-PrDSA: triphenylsulfonium 1,3-propane disulfonate
MSA: methanesulfonic acid
PTSA: p-toluenesulfonic acid

TABLE 1

| | | Additive | Additive | Additive | | | |
|---|---|---|---|---|---|---|---|
| | Polymer | 1 | 2 | 3 | Solvent | | |
| Example 1 | Synthesis | MA | TPSN03 | PrDSA | PGEE | PGME | DIW |
| | Example 1 | | | | | | |
| (parts by mass) | 0.5 | 0.005 | 0.025 | 0.015 | 80 | 8 | 12 |
| Example 2 | Synthesis | MA | TPSN03 | BiPhDSA | PGEE | PGME | DIW |
| | Example 1 | | | | | | |
| (parts by mass) | 0.5 | 0.005 | 0.025 | 0.015 | 80 | 8 | 12 |
| Example 3 | Synthesis | MA | TPSN03 | NaphDSA | PGEE | PGME | DIW |
| | Example 1 | | | | | | |
| (parts by mass) | 0.5 | 0.005 | 0.025 | 0.015 | 80 | 8 | 12 |
| Example 4 | Synthesis | MA | TPSN03 | SA | PGEE | PGME | DIW |
| | Example 1 | | | | | | |
| (parts by mass) | 0.5 | 0.005 | 0.025 | 0.015 | 80 | 8 | 12 |
| Example 5 | Synthesis | MA | TPSN03 | TPS-PrDSA | PGEE | PGME | DIW |
| | Example 1 | | | | | | |
| (parts by mass) | 0.5 | 0.005 | 0.025 | 0.015 | 80 | 8 | 12 |
| Example 6 | Synthesis | MA | TPSN03 | PrDSA | PGEE | PGME | DIW |
| | Example 2 | | | | | | |
| (parts by mass) | 0.5 | 0.005 | 0.025 | 0.015 | 80 | 8 | 12 |
| Example 7 | Synthesis | MA | TPSN03 | PrDSA | PGEE | PGME | DIW |
| | Example 3 | | | | | | |
| (parts by mass) | 0.5 | 0.005 | 0.025 | 0.015 | 80 | 8 | 12 |
| Example 8 | Synthesis | MA | TPSN03 | PrDSA | PGEE | PGME | DIW |
| | Example 4 | | | | | | |
| (parts by mass) | 0.5 | 0.005 | 0.025 | 0.015 | 80 | 8 | 12 |
| Comparative | Synthesis | MA | TPSN03 | — | PGEE | PGME | DIW |
| Example 1 | Example 1 | | | | | | |
| (parts by mass) | 0.5 | 0.005 | 0.025 | — | 80 | 8 | 12 |
| Comparative | Synthesis | MA | TPSN03 | MSA | PGEE | PGME | DIW |
| Example 2 | Example 1 | | | | | | |
| (parts by mass) | 0.5 | 0.03 | 0.025 | 0.015 | 80 | 8 | 12 |
| Comparative | Synthesis | MA | TPSN03 | PTSA | PGEE | PGME | DIW |
| Example 3 | Example 1 | | | | | | |
| (parts by mass) | 0.5 | 0.03 | 0.025 | 0.015 | 80 | 8 | 12 |

* Examples 1 to 8 and Comparative Examples 1 to 3 further contain nitric acid contained in the polymer solution prepared in synthesis example.

### [3] Preparation of Organic Underlayer Film-Forming Composition

Carbazole (6.69 g, 0.040 mol, manufactured by Tokyo Chemical Industry Co., Ltd.), 9-fluorenone (7.28 g, 0.040 mol, manufactured by Tokyo Chemical Industry Co., Ltd.) and p-toluenesulfonic acid monohydrate (0.76 g, 0.0040 mol, manufactured by Tokyo Chemical Industry Co., Ltd.) were added to a 100 ml four-necked flask under nitrogen, and 1,4-dioxane (6.69 g, manufactured by Kanto Chemical Co., Inc.) was added and stirred, and then the temperature was raised to 100° C. to dissolve the mixture and initiate polymerization. After 24 hours, the mixture was allowed to cool to 60° C.

Chloroform (34 g, manufactured by Kanto Chemical Co., Inc.) was added to the cooled reaction mixture for dilution and the diluted mixture was added to methanol (168 g, manufactured by Kanto Chemical Co., Inc.) for precipitation.

The obtained precipitate was recovered by filtration, and the recovered solid was dried in a vacuum dryer at 80° C. for 24 hours to obtain 9.37 g of a desired polymer represented by formula (X) (hereinafter, abbreviated as PCzFL).

The ¹H-NMR measurement results of PCzFL were as follows.

¹H-NMR (400 MHz, DMSO-d₆): δ (ppm) 7.03-7.55 (br, 12H), δ7.61-8.10 (br, 4H), δ11.18 (br, 1H)

The weight average molecular weight Mw of PCzFL was 2,800 in terms of polystyrene by GPC, and the polydispersity Mw/Mn was 1.77.

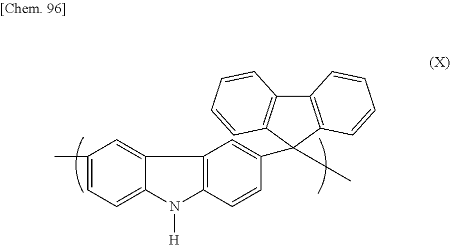

PCzFL (20 g), 3.0 g of tetramethoxymethyl glycoluril (Powder Link 1174 (trade name), manufactured by Nippon Cytec Industries (former Mitsui Cytec Ltd.)) as a crosslinking agent, 0.30 g of pyridinium p-toluenesulfonate as a catalyst, and 0.06 g of MEGAFACE R-30 (manufactured by DIC Corporation, trade name) as a surfactant were mixed, and the resulting mixture was dissolved in 88 g of propylene glycol monomethyl ether acetate to prepare a solution. Thereafter, the obtained solution was filtered using a polyethylene microfilter having a pore size of 0.10 μm, and further filtered using a polyethylene microfilter having a pore size of 0.05 μm to prepare an organic underlayer film-forming composition.

### [4] Solvent Resistance Test

The compositions prepared in Examples 1 to 8 and Comparative Examples 1 to 3 were each applied onto a silicon wafer using a spinner. Si-containing resist underlayer films were each formed by heating at 215° C. for 1 minute on a hot plate, and the film thickness of the obtained resist underlayer film was measured. The film thickness was about 10 nm.

Thereafter, a mixed solvent of propylene glycol monomethyl ether/propylene glycol monomethyl ether acetate (7/3 (V/V)) was applied onto each Si-containing resist underlayer film, and spin-dried. The film thickness of the underlayer film after application was measured, and the ratio (%) of the change in film thickness after application of the mixed solvent was calculated based on the film thickness (100%) before application of the mixed solvent. A film having a film thickness change ratio of 1% or less before and after application of the mixed solvent was evaluated as “good”, and a film having a film thickness change ratio of more than 1% was evaluated as “not cured”.

The obtained results are shown in Table 2.

TABLE 2

| | Solvent |
|---|---|
| | resistance |
| Example 1 | Good |
| Example 2 | Good |
| Example 3 | Good |
| Example 4 | Good |
| Example 5 | Good |
| Example 6 | Good |
| Example 7 | Good |
| Example 8 | Good |
| Comparative | Good |
| Example 1 | |
| Comparative | Good |
| Example 2 | |
| Comparative | Good |
| Example 3 | |

[5] Formation of Resist Pattern by EUV Exposure: Negative Development with Organic Solvent

The organic underlayer film-forming composition was applied onto a silicon wafer by spin coating, and heated on a hot plate at 215° C. for 1 minute to form an organic underlayer film (layer A) (film thickness: 90 nm).

The composition obtained in Example 1 was applied thereon by spin coating, and heated on a hot plate at 215° C. for 1 minute to form a resist underlayer film (B) layer (film thickness: 10 nm).

Further, a resist solution for EUV (tin oxide-based resist) was applied thereon by spin coating, and heated at 130° C. for 1 minute to form an EUV resist layer (C) layer, and thereafter, the layer was exposed using an EUV exposure apparatus (NXE3300B) manufactured by ASML under the conditions of NA=0.33, σ=0.67/0.90 (outer/inner), and Dipole. At the time of exposure, exposure was performed through a mask set so that the line width and the inter-line width (space width) of the EUV resist were 16 nm after the following development, that is, a 16 nm line-and-space (L/S)=1/1 dense line was formed.

After the exposure, the film was subjected to post exposure bake (PEB, 170° C. for 1 min), cooled to room temperature on a cooling plate, developed for 60 seconds using an organic solvent (propylene glycol monomethyl ether acetate), and rinsed to form a resist pattern.

In the same procedure, a resist pattern was formed using each of the compositions obtained in Examples 2 to 8 and Comparative Examples 1 to 3.

Using a CD-SEM (CG4100) manufactured by Hitachi High-Technologies Corporation, the exposure amount at the time of formation with a line dimension of 16 nm was measured and taken as sensitivity, and the dimension of 60 lines at this time was measured to determine a line width roughness (LWR). The results are shown in Table 3.

TABLE 3

| | Sensitivity | LWR |
|---|---|---|
| | (mJ/cm²) | (nm) |
| Example 1 | 64.2 | 3.5 |
| Example 2 | 66.1 | 3.6 |
| Example 3 | 66.2 | 3.6 |
| Example 4 | 64.0 | 3.6 |
| Example 5 | 66.9 | 3.5 |
| Example 6 | 65.1 | 3.6 |
| Example 7 | 62.6 | 3.3 |
| Example 8 | 64.8 | 3.5 |
| Comparative | 70.1 | 3.3 |
| Example 1 | | |
| Comparative | 69.8 | 3.3 |
| Example 2 | | |
| Comparative | 71.1 | 3.3 |
| Example 3 | | |

As shown in Table 3, it is found that when a polysiloxane film formed using a silicon-containing resist underlayer film-forming composition containing sulfuric acid, a polyfunctional sulfonic acid, or a salt thereof is used as a resist underlayer film, the sensitivity can be improved as compared with a silicon-containing resist underlayer film-forming composition (Comparative Example 1) containing no sulfuric acid, polyfunctional sulfonic acid, or salt thereof. On the other hand, in the compositions of Comparative Examples 2 and 3 having a monofunctional sulfonic acid, no improvement in sensitivity was observed.

1. A silicon-containing resist underlayer film-forming composition, comprising:
a component [A]: a polysiloxane;
a component [B]: sulfuric acid, a polyfunctional sulfonic acid, or a salt thereof; and
a component [C]: a solvent.

2. The silicon-containing resist underlayer film-forming composition according to claim 1, wherein the polyfunctional sulfonic acid is a compound represented by formula (A) below: 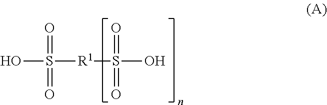
wherein n represents an integer of 1 to 3, and R¹ represents an n+1-valent organic group having 1 to 15 carbon atoms.

3. The silicon-containing resist underlayer film-forming composition according to claim 1, wherein the salt in the component [B] is any of an ammonium salt, an imidazolium salt, a pyridinium salt, a sulfonium salt, a phosphonium salt, and an iodonium salt.

4. The silicon-containing resist underlayer film-forming composition according to claim 1, wherein the polysiloxane as the component [A] is a polysiloxane-modified product in which some silanol groups are alcohol-modified or acetal-protected.

5. The silicon-containing resist underlayer film-forming composition according to claim 1, wherein the component [C] contains an alcohol-based solvent.

6. The silicon-containing resist underlayer film-forming composition according to claim 5, wherein the component [C] contains a propylene glycol monoalkyl ether.

7. The silicon-containing resist underlayer film-forming composition according to claim 1, further comprising a component [D]: a curing catalyst.

8. The silicon-containing resist underlayer film-forming composition according to claim 1, further comprising a component [E]: nitric acid.

9. The silicon-containing resist underlayer film-forming composition according to claim 1, wherein the component [C] contains water.

10. The silicon-containing resist underlayer film-forming composition according to claim 1, which is for forming a resist underlayer film for use in EUV lithography.

11. A silicon-containing resist underlayer film that is a cured product of the silicon-containing resist underlayer film-forming composition according to claim 1.

12. A semiconductor processing substrate, comprising:
a semiconductor substrate; and
the silicon-containing resist underlayer film according to claim 11.

13. A method for producing a semiconductor element, the method comprising:
forming an organic underlayer film on a substrate;
forming a resist underlayer film on the organic underlayer film using the silicon-containing resist underlayer film-forming composition according to claim 1; and
forming a metal-containing resist film on the resist underlayer film.

14. The method for producing a semiconductor element according to claim 13, wherein the metal-containing resist film is formed from a metal-containing resist for use in EUV lithography.

15. The method for producing a semiconductor element according to claim 13, wherein in the forming the resist underlayer film, a silicon-containing resist underlayer film-forming composition filtered through a nylon filter is used.

16. A pattern forming method, comprising:
forming an organic underlayer film on a semiconductor substrate;
forming a resist underlayer film on the organic underlayer film by applying and baking the silicon-containing resist underlayer film-forming composition according to claim 1;
forming a metal-containing resist film on the resist underlayer film;
exposing and developing the metal-containing resist film to obtain a resist pattern;
etching the resist underlayer film using the resist pattern as a mask; and
etching the organic underlayer film using the patterned resist underlayer film as a mask.

17. The pattern forming method according to claim 16, further comprising:
removing the resist underlayer film by a wet method using a chemical liquid after the etching the organic underlayer film.

18. The pattern forming method according to claim 16, wherein the metal-containing resist film is formed from a metal-containing resist for use in EUV lithography.
